(19) United States
(12) Patent Application Publication
(10) Pub. No.: US 2009/0293954 A1
(43) Pub. Date: Dec. 3, 2009

(54) Photoelectric Conversion Device And Method For Manufacturing The Same

(75) Inventor: Shunpei YAMAZAKI, Tokyo (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 12/437,954

(22) Filed: May 8, 2009

(30) Foreign Application Priority Data
May 30, 2008 (JP) 2008-143277
May 30, 2008 (JP) 2008-143301

(51) Int. Cl. H01L 31/0256; H01L 31/18; H01L 31/04

(52) U.S. Cl. 136/258; 438/61; 257/E31.003

(57) ABSTRACT

A photoelectric conversion device and a method for manufacturing the same are provided. The photoelectric conversion device includes a first semiconductor layer including a first impurity element over a substrate, a second semiconductor layer including an amorphous layer and a crystal over the first semiconductor layer, and a third semiconductor layer including a second impurity element over the second semiconductor layer. The crystal penetrates between the first semiconductor layer and the third semiconductor layer.

### BACKGROUND OF THE INVENTION

1. Field of the Invention

The present invention relates to a photoelectric conversion device including a semiconductor junction and a method for manufacturing the photoelectric conversion device.

2. Description of the Related Art

To deal with global environmental issues in recent years, the market has expanded for photoelectric conversion devices typified by solar cells such as residential photovoltaic systems. Bulk photoelectric conversion devices including single crystal silicon or polycrystalline silicon, which have high conversion efficiency, have already been put into practical use. The photoelectric conversion devices including single crystal or polycrystalline silicon are manufactured by cutting wafers out of large silicon ingots. However, since it takes a long time to manufacture large silicon ingots, the productivity is low. Further, since supply of raw materials of silicon itself is limited, the supply of silicon ingots is insufficient and cannot respond to the expansion of the market.

As the shortage of raw materials of silicon becomes obvious as above, thin film photoelectric conversion devices including silicon thin films are attracting attention. In the thin film photoelectric conversion devices, silicon thin films are formed over supporting substrates by a variety of chemical or physical growth methods. Therefore, it is said that resource saving and cost reduction are possible with the thin film photoelectric conversion devices as compared with the bulk photoelectric conversion devices.

Development has been conducted on photoelectric conversion devices including amorphous silicon thin films and in recent years, development on photoelectric conversion devices including microcrystalline silicon thin films are also in progress. For example, a method for manufacturing a silicon thin film solar cell, in which microcrystalline silicon is formed as crystalline silicon by the control of the pulse modulation of a high-frequency electric power in a high-frequency plasma CVD method has been disclosed (see, for example, Patent Document 1). Further, for example, a method in which the deposition rate is increased by forming a silicon-based thin film photoelectric conversion layer including a crystalline substance while the pressure in a reaction chamber is controlled in a low-temperature plasma CVD method has been disclosed (see, for example, Patent Document 2).

In addition, a method for manufacturing a solar cell, in which a crystalline semiconductor layer is obtained by introducing hydrogen ions to a crystalline semiconductor and cutting the crystalline semiconductor through thermal treatment has been disclosed (see, for example, Patent Document 3). The crystalline semiconductor to which ions of a predetermined element are added in a layer form is attached to a surface of a paste for forming an electrode, which is applied onto a substrate provided with an insulating layer, and then subjected to thermal treatment at 300° C. to 500° C., so that the crystalline semiconductor adheres to the electrode. Next, thermal treatment is performed at 500° C. to 700° C. on the crystalline semiconductor, so that a space is provided in a layer form in the region where the predetermined element is introduced and then, the crystalline semiconductor is split at the space due to thermal distortion, whereby a crystalline semiconductor layer is formed over the electrode. Further, an amorphous silicon layer is formed over the crystalline semiconductor layer; thus, a tandem solar cell is completed. In this method, a single crystal silicon solar cell serving as a first power generation layer is formed.
Patent Document 1: Japanese Published Patent Application No. 2005-50905.
Patent Document 2: Japanese Published Patent Application No. 2000-124489.
Patent Document 3: Japanese Published Patent Application No. H10-335683.

### SUMMARY OF THE INVENTION

As for photoelectric conversion devices including amorphous silicon thin films, the manufacturing process is simple and the cost reduction is possible. However, they are not popular because the photoelectric conversion efficiency thereof is lower than that of bulk photoelectric conversion devices and there is still a problem of photodegradation called Staebler-Wronski effect.

The photodegradation can be suppressed by the use of microcrystalline silicon instead of amorphous silicon. However, since microcrystalline silicon is formed into films with the use of a semiconductor source gas typified by silane diluted with a large amount of hydrogen gas, there is a problem of low deposition rate. Additionally, the light absorption coefficient of microcrystalline silicon is lower than that of amorphous silicon. Therefore, in the case of using a photoelectric conversion layer formed from microcrystalline silicon, the photoelectric conversion layer needs to be formed thicker than that formed from amorphous silicon. For these reasons, photoelectric conversion devices including microcrystalline silicon are inferior in productivity to those including amorphous silicon.

In Patent Document 1, crystalline silicon (microcrystalline silicon is used in Patent Document 1) is formed into a film with uniform crystallinity and quality by the control of the pulse modulation in a high-frequency plasma CVD method; however, crystalline silicon is not practical because the deposition rate is low as compared with formation from amorphous silicon. On the other hand, Patent Document 2 has improved the deposition rate but a silicon layer still needs to be several digit thicker than an amorphous silicon layer; therefore, the problem in productivity remains unsolved. As a result, at present, the improvement of productivity and the improvement in characteristics, such as an increase in efficiency, cannot be achieved at the same time and the popularity of photoelectric conversion devices including silicon thin films comes short of that of bulk photoelectric conversion devices.

Moreover, the method as disclosed in Patent Document 3, i.e., the method in which a single crystal silicon substrate and another substrate are attached to each other using a paste for forming an electrode as an adhesive has problems in the degree of adhesion at the bonded portion and change in quality (decrease in adhesive strength) of the paste for forming the electrode which functions as the adhesive. As a result, there has been a concern in reliability of a completed solar cell.

In view of the foregoing problems, an object of an embodiment of the present invention is to achieve, at the same time, the improvement in efficiency and productivity of photoelectric conversion devices. Another object of an embodiment of the present invention is to provide a method for manufacturing a highly-efficient photoelectric conversion device through a simple process. Another object of an embodiment of the present invention is to provide a photoelectric conversion device in which change in characteristics due to photodegradation or the like is prevented.

Another object of an embodiment of the present invention is to provide a photoelectric conversion device of resource-saving type which efficiently utilizes a semiconductor material.

An embodiment of the present invention is a photoelectric conversion device including a cell which has a semiconductor junction. The photoelectric conversion device includes an impurity semiconductor layer to which an impurity element imparting one conductivity type is added, an impurity semiconductor layer to which an impurity element imparting a conductivity type opposite to the one conductivity type is added, and a semiconductor layer including in an amorphous structure, crystals that penetrate between the impurity semiconductor layers.

The semiconductor layer is formed with use of plasma over the impurity semiconductor layer having one conductivity type formed from a microcrystalline semiconductor. The plasma is generated by introduction of a semiconductor source gas (typically, silane) and a dilution gas (typically, hydrogen gas) into a reaction space with the flow rate of the dilution gas to the semiconductor source gas being greater than or equal to 1 time and less than 10 times, preferably greater than or equal to 1 time and less than or equal to 6 times. Through this step, the impurity semiconductor layer formed from a microcrystalline semiconductor serves as seed crystals, so that the semiconductor film is formed so as to include crystals that have grown from the impurity semiconductor layer in a deposition direction of the semiconductor layer. By the control of the dilution amount of the semiconductor source gas, the crystals can be grown so as to penetrate between the impurity semiconductor layer having one conductivity type and the impurity semiconductor layer having a conductivity type opposite to the one conductivity. Then, the impurity semiconductor layer having a conductivity type opposite to the one conductivity type is formed over the semiconductor layer including the crystals. By the growth of the crystals up to the surface of the semiconductor layer, which is the interface between the semiconductor layer and the impurity semiconductor layer having the opposite conductivity type, the crystals can penetrate between the pair of impurity semiconductor layers.

According to an embodiment of the present invention, a photoelectric conversion device includes a cell having a semiconductor junction, and the cell includes a first impurity semiconductor layer including an impurity element imparting one conductivity type, a second impurity semiconductor layer including an impurity element imparting a conductivity type opposite to the one conductivity type, and a semiconductor layer including in an amorphous structure, crystals that penetrate between the first impurity semiconductor layer and the second impurity semiconductor layer.

According to an embodiment of the present invention, a photoelectric conversion device includes a stack of cells each having a semiconductor junction, and at least one cell includes a first impurity semiconductor layer including an impurity element imparting one conductivity type, a second impurity semiconductor layer including an impurity element imparting a conductivity type opposite to the one conductivity type, and a semiconductor layer including in an amorphous structure, crystals that penetrate between the first impurity semiconductor layer and the second impurity semiconductor layer.

According to an embodiment of the present invention, a photoelectric conversion device includes a stack of cells each having a semiconductor junction, and each cell includes a first impurity semiconductor layer including an impurity element imparting one conductivity type, a second impurity semiconductor layer including an impurity element imparting a conductivity type opposite to the one conductivity type, and a semiconductor layer including in an amorphous structure, crystals that penetrate between the first impurity semiconductor layer and the second impurity semiconductor layer In the photoelectric conversion device, the cells are arranged so that the proportions of the crystals in the semiconductor layers increase in order from a light incidence side, which means in order of increasing proportions of the crystals from the light incidence side.

In the above structure, the cells are disposed preferably so that the semiconductor layers including the crystals are arranged in order of increasing thickness from the light incidence side, that is, get thicker from the light incidence side.

The crystal preferably has a needle-like shape. The needle-like shape preferably includes a conical shape, a cylindrical shape, a polygonal conical shape, and a polygonal columnar shape in its category. In this specification, the crystal with such a shape is also referred to as a needle-like crystal. Further, a crystal successively existing between the impurity semiconductor layer to which an impurity element having one conductivity type is added and the impurity semiconductor layer to which an impurity element having a conductivity type opposite to the one conductivity type is added is also called a penetrating needle-like crystal (PNC).

In the above structure, the first impurity semiconductor layer is preferably an n-type microcrystalline semiconductor, the second impurity semiconductor layer is preferably a p-type microcrystalline semiconductor, and the crystals are preferably grown from the interface between the first impurity semiconductor layer and the semiconductor layer so that the crystals narrow upward.

According to an embodiment of the present invention, a method for manufacturing a photoelectric conversion device includes forming a first impurity semiconductor layer from a microcrystalline semiconductor including an impurity element imparting one conductivity type; forming over the first impurity semiconductor layer, a semiconductor layer including in an amorphous structure, crystals growing so as to narrow upward in a deposition direction of the semiconductor layer from the first impurity semiconductor layer with use of plasma generated by introduction of a semiconductor source gas and a dilution gas into a reaction chamber with a flow rate of the dilution gas to the semiconductor source gas being greater than or equal to I time and less than or equal to 6 times; and forming a second impurity semiconductor layer including an impurity element imparting a conductivity type opposite to the one conductivity over the semiconductor layer including the crystals that narrow upward. The crystals that narrow upward are formed penetrating between the first impurity semiconductor layer and the second impurity semiconductor layer.

In the semiconductor layer, penetrating crystals are grown in an amorphous structure. The crystals are grown so as to narrow upward from the interface between the semiconductor layer and the first impurity semiconductor layer to reach the second impurity semiconductor layer.

According to an embodiment of the present invention, a method for manufacturing a photoelectric conversion device includes forming a first electrode having a light-transmitting property over a substrate having a light-transmitting property; forming a first impurity semiconductor layer from a microcrystalline semiconductor including an impurity element imparting one conductivity type over the first electrode; forming over the first impurity semiconductor layer, a first semiconductor layer including in an amorphous structure, crystals that grow so as to narrow upward in a deposition direction of the semiconductor layer from the first impurity semiconductor layer with use of plasma generated by introduction of a semiconductor source gas and a dilution gas into a reaction chamber with a flow rate of the dilution gas to the semiconductor source gas being greater than or equal to I time and less than or equal to 6 times; forming over the first semiconductor layer, a second impurity semiconductor layer including an impurity element imparting a conductivity type opposite to that of the first impurity semiconductor layer; forming over the second impurity semiconductor layer, a third impurity semiconductor layer from a microcrystalline semiconductor including an impurity element imparting a conductivity type opposite to that of the second impurity semiconductor layer; forming over the third impurity semiconductor layer, a second semiconductor layer which includes in an amorphous structure, crystals that grow so as to narrow upward in a deposition direction of the semiconductor layer from the third impurity semiconductor layer and which has higher proportion of the crystals than the first semiconductor layer; forming over the second semiconductor layer, a fourth impurity semiconductor layer including an impurity element imparting a conductivity type opposite to that of the third impurity semiconductor layer; forming over the fourth impurity semiconductor layer, a fifth impurity semiconductor layer including an impurity element imparting a conductivity type opposite to that of the fourth impurity semiconductor layer; forming over the fifth impurity semiconductor layer, a third semiconductor layer which includes in an amorphous structure, crystals that grow so as to narrow upward in a deposition direction of the semiconductor layer from the fifth impurity semiconductor layer and which has a higher proportion of the crystals than the second semiconductor layer; forming over the third semiconductor layer, a sixth impurity semiconductor layer including an impurity element imparting a conductivity type opposite to that of the fifth impurity semiconductor layer; and forming a second electrode over the sixth impurity semiconductor layer.

In the above structure, penetrating crystals are grown in an amorphous structure in each of the first semiconductor layer, the second semiconductor layer, and the third semiconductor layer. The crystals in the first semiconductor layer are grown so as to narrow upward from the interface between the first semiconductor layer and the first impurity semiconductor layer to reach the second impurity semiconductor layer. The crystals in the second semiconductor layer are grown so as to narrow upward from the interface between the second semiconductor layer and the third impurity semiconductor layer to reach the fourth impurity semiconductor layer. The crystals in the third semiconductor layer are grown so as to narrow upward from the interface between the third semiconductor layer and the fifth impurity semiconductor layer to reach the sixth impurity semiconductor layer.

According to an embodiment of the present invention, a photoelectric conversion device including a semiconductor junction includes a cell having a single crystal semiconductor layer obtained by thinning a single crystal semiconductor substrate and a cell having a semiconductor layer including crystals that penetrate through an amorphous structure.

A single crystal semiconductor substrate, typically a single crystal silicon substrate is sliced so that the superficial portion thereof is separated to form a single crystal silicon layer, and then the single crystal silicon layer is fixed onto a substrate so as to serve as a layer which performs photoelectric conversion. Moreover, a cell having a semiconductor layer including in an amorphous structure, crystals that penetrate between a pair of impurity semiconductor layers bonded for forming an internal electric field is stacked over the single crystal silicon layer, whereby a stacked photoelectric conversion device is completed. A unit cell including a non-single-crystal semiconductor layer is stacked over a unit cell including a single crystal semiconductor layer.

The single crystal semiconductor substrate is sliced by any of the following methods: a method by which the substrate is irradiated with a predetermined element (typically, a hydrogen ion) accelerated by voltage to locally weaken the substrate and then thermal treatment or the like is performed on the substrate so that the substrate is divided, a method by which the substrate is irradiated with a laser beam that causes multiphoton absorption to locally weaken the substrate so that the substrate is divided, and the like.

The unit cell including a non-single-crystal semiconductor layer stacked over the unit cell including a single crystal semiconductor layer is formed by a chemical vapor deposition method, typically a plasma CVD method. Over the impurity semiconductor layer having one conductivity type formed from a microcrystalline semiconductor layer, the semiconductor layer is formed with use of plasma generated by introduction of a semiconductor source gas and a dilution gas into a reaction space with a flow rate of the dilution gas to the semiconductor source gas being greater than or equal to 1 time and less than 10 times, preferably greater than or equal to 1 time and less than or equal to 6 times. Through this step, the impurity semiconductor layer formed from a microcrystalline semiconductor serves as seed crystals, so that the semiconductor layer is formed so as to include in an amorphous structure, crystals that are grown from the impurity semiconductor layer in the deposition direction of the semiconductor layer. By the control of the dilution amount of the semiconductor source gas, the crystals can be grown so as to penetrate between the impurity semiconductor layer having one conductivity type and the impurity semiconductor layer having a conductivity type opposite to the one conductivity type. Then, the impurity semiconductor layer having a conductivity type opposite to the one conductivity type is formed over the semiconductor layer including the crystals. By the growth of the crystals up to the surface of the semiconductor layer which is the interface between the semiconductor layer and the impurity semiconductor layer having the opposite conductivity type, the crystals can penetrate between the pair of impurity semiconductor layers.

According to an embodiment of the present invention, a photoelectric conversion device includes a first electrode provided over a substrate having an insulating surface with an insulating layer interposed between the first electrode and the substrate; a first unit cell provided over the first electrode cell, which includes a single crystal semiconductor layer; a second unit cell provided over the first unit cell, which includes a first impurity semiconductor layer including an impurity element imparting one conductivity type, a second impurity semiconductor layer including an impurity element imparting a conductivity type opposite to the one conductivity type, and a non-single-crystal semiconductor layer including in an amorphous structure, crystals penetrating between the first impurity semiconductor layer and the second impurity semiconductor layer; and a second electrode provided over the second unit cell.

In the above structure, the crystal preferably has a needle-like shape.

In the above structure, preferably, the first unit cell includes an impurity semiconductor layer including an impurity element imparting one conductivity type on the insulating surface side in the single crystal semiconductor layer, and an impurity semiconductor layer including an impurity element imparting a conductivity type opposite to the one conductivity type and has a structure in which the impurity semiconductor layer including an impurity element having the opposite conductivity type is stacked over the single crystal semiconductor layer.

According to an embodiment of the present invention, a method for manufacturing a photoelectric conversion device includes forming a fragile layer in a region at a predetermined depth from one surface of a single crystal semiconductor substrate; forming a first impurity semiconductor layer by introducing an impurity element imparting one conductivity type to the one surface side of the single crystal semiconductor substrate; forming a first electrode over the one surface of the single crystal semiconductor substrate which is provided with the first impurity semiconductor layer; forming an insulating layer over the first electrode; disposing the insulating layer formed over the one surface of the single crystal semiconductor substrate and a substrate having an insulating surface so as to face each other and attaching them to each other; dividing the single crystal semiconductor substrate at the fragile layer, so that a single crystal semiconductor layer including the first impurity semiconductor layer is formed over the substrate having an insulating surface with the insulating layer and the first electrode interposed between the substrate and the single crystal semiconductor layer; forming a second impurity semiconductor layer including an impurity element imparting a conductivity type opposite to the one conductivity type on a surface of the single crystal semiconductor layer which is opposite to the surface provided with the first impurity semiconductor layer; forming over the second impurity semiconductor layer, a third impurity semiconductor layer from a microcrystalline semiconductor including an impurity element imparting a conductivity type opposite to that of the second impurity semiconductor layer; forming over the third impurity semiconductor layer, a non-single-crystal semiconductor layer including in an amorphous structure, crystals that grow so as to narrow upward in a deposition direction of the semiconductor layer from the third impurity semiconductor layer with use of plasma generated by introducing a semiconductor source gas and a dilution gas into a reaction chamber with a flow rate of the dilution gas to the semiconductor source gas being greater than or equal to 1 time and less than or equal to 6 times; forming over the non-single-crystal semiconductor layer, a fourth impurity semiconductor layer including an impurity element imparting a conductivity type opposite to that of the third impurity semiconductor layer; and forming a second electrode over the fourth impurity semiconductor layer. Note that the crystals that grow so as to narrow upward penetrate between the third impurity semiconductor layer and the fourth impurity semiconductor layer.

In the above structure, the crystals in the non-single-crystal semiconductor layer successively exist and penetrate between the third impurity semiconductor layer and the fourth impurity semiconductor layer and grow in an amorphous structure. The crystals in the non-single-crystal semiconductor layer preferably grow so as to narrow upward from the interface between the non-single-crystal semiconductor layer and the third impurity semiconductor layer.

A bonding plane between the substrate having an insulating surface and the insulating layer formed over the single crystal semiconductor substrate with the first electrode interposed between the insulating layer and the single crystal semiconductor substrate preferably has an average surface roughness of 0.5 nm or less.

In the above structure, silicon hydride, silicon fluoride, or silicon chloride is preferably used as the semiconductor source gas and hydrogen is preferably used as the dilution gas.

Note that the fragile layer in this specification refers to a region and its vicinity where the single crystal semiconductor substrate is divided into a thin plate single crystal semiconductor layer and a single crystal semiconductor substrate by a division step. The state of the fragile layer depends on a means for forming the fragile layer. For example, the fragile layer refers to a weakened region where the crystal structure is locally disordered. In some cases, a region ranging from the surface of the single crystal semiconductor substrate to the fragile layer is weakened to some extent; however, the fragile layer in this specification refers to a region which is to be divided later and the vicinity of the region.

The photoelectric conversion layer in this specification refers to a semiconductor layer which achieves a photoelectric effect (an internal photoelectric effect) and moreover to such a semiconductor layer and an impurity semiconductor layer which are bonded for forming an internal electric field. That is to say, the photoelectric conversion layer refers to a semiconductor layer in which a junction typified by a pn junction, a pin junction, or the like is formed.

Note that in this specification, the ordinal number such as “first”, “second”, “third”, or “fourth” is given for convenience to distinguish elements, and not given to limit the number, the arrangement, and the order of the steps.

According to an embodiment of the present invention, the semiconductor layer including in an amorphous structure, crystals penetrating between the impurity semiconductor layer having one conductivity type and the impurity semiconductor layer having a conductivity type opposite to the one conductivity type is formed as a photoelectric conversion layer. Therefore, the efficiency higher than that of a conventional photoelectric conversion device including amorphous silicon can be achieved. Further, with the semiconductor layer including in an amorphous structure, the crystals penetrating between the pair of impurity semiconductor layers bonded for forming an internal electric field, photodegradation or the like can be reduced and variation in characteristics can be suppressed as compared with a conventional photoelectric conversion device including amorphous silicon. The thickness of the photoelectric conversion layer can be the same or substantially the same as that of a photoelectric conversion device including amorphous silicon, and the productivity can be increased as compared with a conventional photoelectric conversion device including microcrystalline silicon. Thus, a photoelectric conversion device in which improvement is achieved in both characteristics and productivity can be provided.

Further, a plurality of cells is stacked, each of which has a semiconductor layer including in an amorphous structure, crystals penetrating between an impurity semiconductor layer having one conductivity type and an impurity semiconductor layer having a conductivity type opposite to the one conductivity type and which has a different proportion of the crystals in the semiconductor layer for each cell. Thus, the absorption wavelength range can be expanded to further increase the efficiency.

According to an embodiment of the present invention, a unit cell including a single crystal semiconductor layer as a photoelectric conversion layer and a unit cell including a non-single-crystal semiconductor layer formed over the unit cell including a single crystal semiconductor layer are provided. Thus, light in a wide wavelength range can be absorbed; therefore, an excellent photoelectric conversion characteristic can be obtained. When the upper unit cell includes a non-single-crystal semiconductor layer including in an amorphous structure, crystals penetrating between an impurity semiconductor layer having one conductivity type and an impurity semiconductor layer having a conductivity type opposite to the one conductivity type, higher efficiency than that of a conventional photoelectric conversion device including amorphous silicon can be achieved. Further, when the semiconductor layer including in an amorphous structure, crystals penetrating between the pair of impurity semiconductor layers bonded for forming an internal electric field is formed, photodegradation or the like can be reduced and variation in characteristics can be suppressed as compared with a conventional photoelectric conversion device including amorphous silicon. The thickness of the photoelectric conversion layer can be the same or substantially the same as that of a photoelectric conversion device including amorphous silicon, and the productivity can be increased as compared with a conventional photoelectric conversion device including microcrystalline silicon. Thus, a photoelectric conversion device in which improvement is achieved in both characteristics and productivity can be provided.

### BRIEF DESCRIPTION OF THE DRAWINGS

FIG. 1 is a schematic view of a cell according to an embodiment of the present invention.

FIG. 2 is a schematic view of a photoelectric conversion device according to an embodiment of the present invention.

FIG. 3 illustrates a plasma CVD apparatus which can be used for manufacture of a photoelectric conversion device according to an embodiment of the present invention.

FIG. 4 illustrates a structure of a multi-chamber plasma CVD apparatus provided with a plurality of reaction chambers.

FIGS. 5A and 5B are schematic views each illustrating a photoelectric conversion device according to an embodiment of the present invention.

FIGS. 6A to 6C are schematic views each illustrating a photoelectric conversion device according to an embodiment of the present invention.

FIGS. 7A to 7C are cross-sectional views of a process for manufacturing an integrated photoelectric conversion device.

FIG. 8 is a cross-sectional view of a process for manufacturing an integrated photoelectric conversion device.

FIGS. 9A to 9C are cross-sectional views of a process for manufacturing an integrated photoelectric conversion device.

FIG. 10 is a cross-sectional view of a process for manufacturing an integrated photoelectric conversion device.

FIG. 11 illustrates a photosensor device to which a photoelectric conversion layer according to an embodiment of the present invention is applied.

FIG. 12 is a schematic view of a photoelectric conversion device according to an embodiment of the present invention.

FIGS. 13A to 13C are cross-sectional views of a method for manufacturing a photoelectric conversion device according to an embodiment of the present invention.

FIGS. 14A to 14C are cross-sectional views of a method for manufacturing a photoelectric conversion device according to an embodiment of the present invention.

FIGS. 15A to 15C are cross-sectional views of a method for manufacturing a photoelectric conversion device according to an embodiment of the present invention.

FIGS. 16A and 16B are cross-sectional views of a method for manufacturing a photoelectric conversion device according to an embodiment of the present invention.

FIGS. 17A to 17C are schematic views each illustrating a photoelectric conversion device according to an embodiment of the present invention.

FIG. 18 is a top view of a process for manufacturing an integrated photoelectric conversion device.

FIG. 19 is a top view of a process for manufacturing an integrated photoelectric conversion device.

FIG. 20 is a top view of a process for manufacturing an integrated photoelectric conversion device.

FIGS. 21A to 21D are cross-sectional views of a process for manufacturing an integrated photoelectric conversion device.

FIGS. 22A to 22E are cross-sectional views of a process for manufacturing an integrated photoelectric conversion device.

### DETAILED DESCRIPTION OF THE INVENTION

Embodiments of the present invention are described below with reference to the drawings. However, the present invention is not limited to the description below and it is to be easily understood by those skilled in the art that various changes in modes and details thereof will be apparent without departing from the concept and the scope of the present invention. Therefore, the present invention should not be construed as being limited to the description of the embodiments below. Note that, in the structure of the present invention hereinafter described, reference numerals are used in common throughout the drawings.

### Embodiment 1

According to an embodiment of the present invention, a semiconductor layer which performs photoelectric conversion includes crystals in an amorphous structure and the crystals penetrate between a pair of impurity semiconductor layers bonded for forming an internal electric field. Embodiment 1 shows a photoelectric conversion device in which a plurality of unit cells is stacked. In the case of applying an embodiment of the present invention to a tandem or stack photoelectric conversion device, a semiconductor layer including in an amorphous structure, crystals penetrating between a pair of impurity semiconductor layers bonded for forming an internal electric field is used as a photoelectric conversion layer in at least one unit cell.

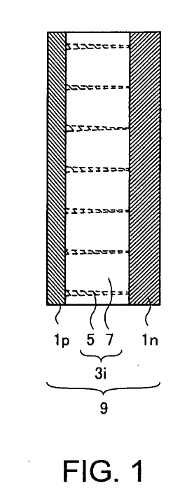

FIG. 1 is a schematic view of a unit cell according to an embodiment of the present invention. A unit cell according to an embodiment of the present invention has a structure in which a semiconductor layer 3i including in an amorphous structure 7, crystals 5 successively penetrating between an impurity semiconductor layer 1p having one conductivity type and an impurity semiconductor layer In having a conductivity type opposite to the one conductivity type is formed.

The crystals 5 are provided discretely in the semiconductor layer 3i of a unit cell 9 illustrated in FIG. 1. The crystals 5 grow in a deposition direction of the semiconductor layer 3i from the impurity semiconductor layer 1p to reach the impurity semiconductor layer 1n. The crystals 5 include a crystalline semiconductor such as a microcrystalline semiconductor, a polycrystalline semiconductor, or a single crystal semiconductor, and typically include crystalline silicon. The amorphous structure 7 includes an amorphous semiconductor, typically amorphous silicon. An amorphous semiconductor typified by amorphous silicon is of direct transition type and has a high light absorption coefficient. Therefore, in the semiconductor layer 3i where the crystals 5 exist in the amorphous structure 7, photogenerated carriers are produced easily in the amorphous structure 7 rather than in the crystals 5. Moreover, while the amorphous structure including amorphous silicon has a band gap of 1.6 eV to 1.8 eV, a crystal including crystalline silicon has a band gap of about 1.1 eV to 1.4 eV. Because of the relationship between these, the photogenerated carriers in the semiconductor layer 3i including the crystals 5 in the amorphous structure 7 diffuse or drift to move to the crystals. The crystals 5 serve as a carrier path for the photogenerated carriers. In such a structure, the photogenerated carriers flow more easily through the crystals 5 even though a light-induced defect is formed. Therefore, the photogenerated carriers are less likely to be trapped in the defect level of the semiconductor layer 3i. The crystals 5 penetrate between the impurity semiconductor layer 1p having one conductivity type and the impurity semiconductor layer 1n having a conductivity type opposite to the one conductivity type, whereby both electrons and holes, which are photogenerated carriers, are less likely to be trapped in the defect level and easily flow. In view of the above, variation in characteristics due to photodegradation which has been a problem can be reduced and a high photoelectric conversion characteristic can be maintained.

With the semiconductor layer 3i in which the crystals 5 exist in the amorphous structure 7, the layer can have regions divided for functions: for example, a region where mainly photogenerated carriers are produced and photoelectric conversion is performed and a region which mainly serve as a carrier path for the produced photogenerated carriers. In a conventional semiconductor layer for forming a photoelectric conversion layer, the photoelectric conversion and the carrier path are both achieved without separation and when one function is put before the other function, the other is degraded in some cases. However, by the separation of the functions as above, the both functions can be improved and the photoelectric conversion characteristic can be improved.

In the semiconductor layer 3i including the crystals 5 in the amorphous structure 7, the light absorption coefficient can be maintained by the amorphous structure 7. Accordingly, the thickness of the semiconductor layer 3i can be the same or substantially the same as that of a photoelectric conversion layer including an amorphous silicon thin film and the productivity can be improved as compared with a photoelectric conversion device including a microcrystalline silicon thin film.

The crystal 5 in the amorphous structure 7 in the semiconductor layer 3i preferably has a needle-like shape. Specifically, the crystal 5 preferably narrows upward so that the width of the crystal 5 decreases in a direction from one of the pair of impurity semiconductor layers (which is the impurity semiconductor layer 1p in FIG. 1) bonded for forming an internal electric field toward the other (which is the impurity semiconductor layer 1n in FIG. 1). Here, the needle-like shape includes a conical shape, a pyramidal shape, and a pillar-like shape. Specifically, as the pillar-like shape, a cylindrical shape and a prismatic columnar shape are given. As the pyramidal shape, a triangular pyramidal shape, a quadrangular pyramidal shape, a hexagonal pyramidal shape, and the like are given. As the prismatic columnar shape, a triangular prism, a quadrangular prism, a hexagonal prism, and the like are given. Alternatively, another polygonal pyramidal shape or another prism can be used. Further alternatively, a conical or pyramidal shape with a pointed vertex or a cylindrical or prismatic columnar shape with a sharp edge may be used. In the case of a polygonal pyramidal shape or a polygonal prism shape, each side may be equal to or different from each other in length.

One of the impurity semiconductor layer 1p having one conductivity type and the impurity semiconductor layer In having a conductivity type opposite to the one conductivity type is a p-type semiconductor layer and the other is an n-type semiconductor layer. The amorphous structure 7 of the semiconductor layer 3i including the crystals 5 is an i-type semiconductor layer. In the unit cell 9, a pin junction is formed by a stacked structure of the impurity semiconductor layer 1p having one conductivity type, the semiconductor layer 3i including the crystals 5 in the amorphous structure 7, and the impurity semiconductor layer 1n having a conductivity type opposite to the one conductivity type.

Next, a method for manufacturing the unit cell 9 is described. The semiconductor layer 3i including the crystals 5 in the amorphous structure 7 is formed over the impurity semiconductor layer 1p formed from a microcrystalline semiconductor. The semiconductor layer 3i is formed with use of plasma generated by introducing a semiconductor source gas and a dilution gas into a reaction space with the flow rate of the dilution gas to the semiconductor source gas being greater than or equal to 1 time and less than 10 times, preferably greater than or equal to 1 time and less than or equal to 6 times. By the control of the dilution rate of the semiconductor source gas and the control of the crystal structure of the lower layer (the impurity semiconductor layer 1p), the impurity semiconductor layer 1p serves as seed crystals, so that the semiconductor layer 3i can be formed in which the crystals 5 are grown in the amorphous structure 7 from the impurity semiconductor layer 1p. In an embodiment of the present invention, since the crystals 5 are grown so as to penetrate through the semiconductor layer 3i, complicated adjustment of the flow rate between the semiconductor source gas and the dilution gas is not necessary from the initial stage of the film formation to the end; thus, the fabrication is easy. The semiconductor layer 3i is formed under the conditions similar to those for forming an amorphous semiconductor film; therefore, the deposition rate is not extremely decreased, so that the productivity is not largely decreased. Needless to say, the deposition rate is higher than that in the case of forming a normal microcrystalline semiconductor layer; therefore, the productivity is improved.

The reaction gas for forming the semiconductor layer 3i is introduced into a reaction space while a predetermined pressure is kept, so that plasma, typically glow discharge plasma, is generated. Thus, a film (the semiconductor layer 3i) is formed over an object to be processed (over the impurity semiconductor layer 1p) disposed in the reaction space. When the reaction gas used at the initial stage of the formation of the semiconductor layer 3i has the dilution rate of the dilution gas to the semiconductor source gas which is greater than or equal to 1 time and less than 10 times, preferably greater than or equal to 1 time and less than or equal to 6 times, the impurity semiconductor layer 1p formed from a microcrystalline semiconductor serves as seed crystals so that crystal growth proceeds in a direction where the deposition is performed. When the deposition of the semiconductor layer 3i is performed from the beginning to the end without particularly adjusting the deposition condition in which the dilution rate of the dilution gas to the semiconductor source gas is greater than or equal to 1 time and less than 10 times, preferably greater than or equal to 1 time and less than or equal to 6 times, the crystals 5 penetrating to reach the surface of the semiconductor layer can be formed in the amorphous structure 7.

The semiconductor layer 3i can be formed using the reaction gas in which the semiconductor source gas typified by silane is diluted with the dilution gas typified by hydrogen in a plasma CVD apparatus. As the semiconductor source gas, silicon hydride typified by silane or disilane can be used. Note that instead of silicon hydride, silicon chloride such as SiH₂Cl₂, SiHCl₃, or SiCl₄, or silicon fluoride such as SiF₄ can be used. The dilution gas used for forming the semiconductor layer 3i is typified by hydrogen, and one or plural kinds of rare gas elements selected from helium, argon, krypton, and neon, may be used in addition to silicon hydride and hydrogen. The dilution rate of hydrogen to silicon hydride is greater than or equal to 1 time and less than 10 times, preferably greater than or equal to 1 time and less than or equal to 6 times at least in the initial stage of the deposition.

The semiconductor layer 3i is formed from an i-type semiconductor. Note that the i-type semiconductor in this specification is a semiconductor which includes an impurity element imparting p-type or n-type conductivity at a concentration of less than or equal to 1×10²⁰ cm⁻³, oxygen and nitrogen at a concentration of less than or equal to 9×10¹⁹ cm⁻³, and which has a photoconductivity 100 times or more to dark conductivity. This i-type semiconductor may include boron at 1 ppm to 1000 ppm. In other words, in some cases, the i-type semiconductor has weak n-type electric conductivity when an impurity element for control of a valence electron is not added intentionally. Thus, in the case where the i-type semiconductor is used for the semiconductor layer 3i, an impurity element imparting p-type conductivity may be added at the same time as or after the deposition of the semiconductor layer 3i. The impurity element imparting p-type conductivity is typically boron, and an impurity gas such as B₂H₆ or BF₃ may be mixed into a semiconductor source gas at a ratio of 1 to 1000 ppm. The concentration of boron may be, for example, 1×10¹⁴/cm³ to 6×10¹⁶/cm³.

The impurity semiconductor layer 1pbelow the semiconductor layer 3i is a semiconductor layer including an impurity element imparting one conductivity type and is formed from a microcrystalline semiconductor. As the impurity element imparting one conductivity type, there are an impurity element imparting n-type conductivity (typically, phosphorus, arsenic, and antimony which are Group 15 elements in the periodic table) and an impurity element imparting p-type conductivity (typically, boron and aluminum which are Group 13 elements in the periodic table). The impurity semiconductor layer 1p is formed from a microcrystalline semiconductor, such as microcrystalline silicon, microcrystalline silicon-germanium, or microcrystalline germanium. Here, the impurity semiconductor layer 1p is formed from microcrystalline silicon including phosphorus that is an impurity element imparting n-type conductivity.

The microcrystalline semiconductor in this specification refers to a semiconductor having an intermediate structure between an amorphous structure and a crystalline structure (which also means a single crystal structure or a polycrystalline structure). A microcrystalline semiconductor has a third state that is stable in terms of free energy. As an example, a microcrystalline semiconductor includes crystal grains each having a size of greater than or equal to 2 nm and less than or equal to 200 nm, preferably greater than or equal to 10 nm and less than or equal to 80 nm, more preferably greater than or equal to 20 nm and less than or equal to 50 nm. The Raman spectrum of microcrystalline silicon, which is a typical example of a microcrystalline semiconductor, is shifted to lower wave numbers than 520 /cm, which represents the Raman spectrum of single crystal silicon. That is, the peak of the Raman spectrum of microcrystalline silicon is within the range from 520 /cm, which represents single crystal silicon, to 480 /cm, which represents amorphous silicon. The semiconductor includes hydrogen or halogen of at least 1 at. % to terminate a dangling bond. Moreover, when a rare gas element such as helium, argon, krypton, or neon is included to further promote lattice distortion, a favorable microcrystalline semiconductor with high stability can be obtained. Such a microcrystalline semiconductor has lattice distortion which changes the optical characteristics of single crystal silicon from the indirect transition type into the direct transition type. At least 10% of lattice distortion makes the optical characteristics change into the direct transition type. When the distortion exits locally, the optical characteristics in which the direct transition and the indirect transition are mixed can be obtained. The description about a microcrystalline semiconductor film is disclosed in, for example, U.S. Pat. No. 4,409,134. In an embodiment of the present invention, the concept of the microcrystallne semiconductor is not restricted by only the aforementioned crystal size. Another semiconductor can be used instead of the microcrystalline semiconductor as long as the physical properties are similar to those of the microcrystalline semiconductor.

A microcrystalline semiconductor layer can be formed by a plasma CVD method using a semiconductor source gas and a dilution gas as a reaction gas with the mixture ratio that enables the formation of the microcrystalline semiconductor. Specifically, a reaction gas in which the semiconductor source gas typified by silane is diluted with hydrogen or the like is introduced into a reaction space while a predetermined pressure is kept, so that plasma typified by glow discharge plasma is generated; thus, a microcrystalline semiconductor layer can be formed over an object to be processed disposed in the reaction space. As the semiconductor source gas and the dilution gas, silicon hydride typified by silane or disilane, silicon fluoride, or silicon chloride and hydrogen may be used, respectively. Alternatively, one or plural kinds of rare gas elements selected from helium, argon, krypton, and neon may be used in addition to the semiconductor source gas and hydrogen. In that case, the flow rate of the dilution gas (for example, hydrogen) to the semiconductor source gas (for example, silicon hydride) is greater than or equal to 10 times and less than or equal to 200 times, preferably greater than or equal to 50 times and less than or equal to 150 times, more preferably 100 times. For example, the microcrystalline semiconductor layer can be formed using glow discharge plasma by dilution of the semiconductor source gas typified by silane with hydrogen or the like in a reaction chamber of a plasma CVD apparatus. The glow discharge plasma is generated by applying high-frequency power with a frequency of 1 to 20 MHz, typically 13.56 MHz, or high-frequency power with a frequency in the VHF band of greater than 30 MHz up to about 300 MHz, typically 27.12 MHz or 60 MHz. Alternatively, high-frequency power with a frequency greater than or equal to 1 GHz may be applied. A carbide gas such as CH₄ or C₂H₆ or a germanium gas such as GeH₄ or GeF₄ may be mixed into the semiconductor source gas so that the band gap is adjusted to be 1.5 to 2.4 eV or 0.9 to 1.1 eV.

The impurity semiconductor layer 1n formed over the semiconductor layer 3i is a semiconductor layer including an impurity element imparting one conductivity type. The impurity semiconductor layer In includes an impurity element imparting a conductivity type opposite to the one conductivity type and is formed from a microcrystalline semiconductor or an amorphous semiconductor which includes silicon, silicon-germanium, germanium, or the like. Here, the impurity semiconductor layer in is formed from microcrystalline silicon including boron that is an impurity element imparting p-type conductivity.

In this manner, the unit cell 9 having the semiconductor layer 3i which includes crystals penetrating between the pair of impurity semiconductor layers in the amorphous structure can be completed.

With at least one unit cell illustrated in FIG. 1, a photoelectric conversion device with an improved photoelectric conversion characteristic can be provided.

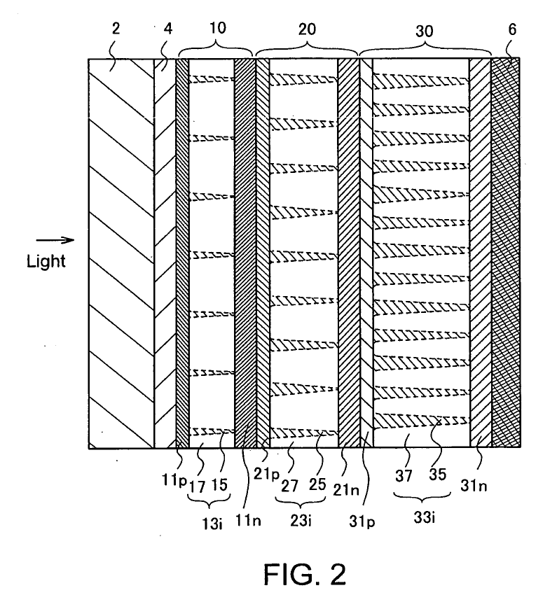

FIG. 2 illustrates a stacked photoelectric conversion device. The photoelectric conversion device illustrated in FIG. 2 has a structure in which a unit cell 10, a unit cell 20, a unit cell 30, and a second electrode 6 are arranged in this order from a substrate 2 side, and the substrate 2 is provided with a first electrode 4. In this example, light enters from the substrate 2 side. For convenience, the unit cell 10, the unit cell 20, and the unit cell 30 are referred to as a first unit cell, a second unit cell, and a third unit cell, respectively.

In the photoelectric conversion device illustrated in FIG. 2, at least one of the first unit cell 10, the second unit cell 20, and the third unit cell 30 has the structure of the unit cell 9 illustrated in FIG. 1. In this example, each of the first unit cell 10, the second unit cell 20, and the third unit cell 30 has the structure of the unit cell 9.

In FIG. 2, the first unit cell 10 includes a first semiconductor layer 13i between a first impurity semiconductor layer 11p having p-type conductivity and a second impurity semiconductor layer 11n having n-type conductivity. The first semiconductor layer 13i is an i-type semiconductor layer including crystals 15 in an amorphous structure 17. The crystals 15 penetrate through the first semiconductor layer 13i, between the first impurity semiconductor layer lip and the second impurity semiconductor layer 11n. In the first unit cell 10, a pin junction is formed by a stacked structure of the first impurity semiconductor layer 11p, the first semiconductor layer 13i, and the second impurity semiconductor layer 11n.

The second unit cell 20 includes a second semiconductor layer 23i between a third impurity semiconductor layer 21p having p-type conductivity and a fourth impurity semiconductor layer 21n having n-type conductivity. The second semiconductor layer 23i is an i-type semiconductor layer including crystals 25 in an amorphous structure 27. The crystals 25 penetrate through the second semiconductor layer 23i between the third impurity semiconductor layer 21p and the fourth impurity semiconductor layer 21n. In the second unit cell 20, a pin junction is formed by a stacked structure of the third impurity semiconductor layer 21p, the second semiconductor layer 23i, and the fourth impurity semiconductor layer 21n.

The third unit cell 30 includes a third semiconductor layer 33i between a fifth impurity semiconductor layer 31p having p-type conductivity and a sixth impurity semiconductor layer 31n having n-type conductivity. The third semiconductor layer 33i is an i-type semiconductor layer including crystals 35 in an amorphous structure 37. The crystals 35 penetrate through the third semiconductor layer 33i between the fifth impurity semiconductor layer 31p and the sixth impurity semiconductor layer 31n. In the third unit cell 30, a pin junction is formed by a stacked structure of the fifth impurity semiconductor layer 31p, the third semiconductor layer 33i, and the sixth impurity semiconductor layer 31n.

The semiconductor layer 3i illustrated in FIG. 1 can be used as each of the first semiconductor layer 13i, the second semiconductor layer 23i, and the third semiconductor layer 33i illustrated in FIG. 2. The impurity semiconductor layer 1p can be used as each of the first impurity semiconductor layer 11p, the third impurity semiconductor layer 21p, and the fifth impurity semiconductor layer 31p. The impurity semiconductor layer 1n can be used as each of the second impurity semiconductor layer 11n, the fourth impurity semiconductor layer 21n, and the sixth impurity semiconductor layer 31n.

Embodiment 1 shows an example in which the three unit cells are stacked and the semiconductor layer in each unit cell includes the crystals in the amorphous structure. In such a structure, the proportions of the crystals in the semiconductor layers (also referred to as the proportion of a volume of the crystals to a volume of the semiconductor layer) preferably increase in order from the unit cell on the light incidence side. For example, in FIG. 2, the proportion of the crystals is preferably as follows: the proportion of a volume of the crystals 15 to a volume of the first semiconductor layer 13i<the proportion of a volume of the crystals 25 to a volume of the second semiconductor layer 23i<the proportion of a volume of the crystals 35 to a volume of the third semiconductor layer 33i. This is because a lower proportion of the crystals means a higher proportion of amorphous structure which can easily absorb light in a short wavelength range and a higher proportion of the crystals means a higher proportion of crystalline structure which can easily absorb light in a long wavelength range. For example, while the amorphous structure including amorphous silicon has a band gap of 1.6 eV to 1.8 eV, a crystal including crystalline silicon has a band gap of about 1.1 eV to 1.4 eV. Light in a short wavelength range is easily absorbed in the amorphous structure with a relatively large band gap, whereas light in a long wavelength range is easily absorbed in the crystalline structure with a relatively small band gap. In the case of the aforementioned band gap, the smaller the proportion of the crystals is, the absorption by the amorphous structure gets dominant so that blue based light, which is light in a short wavelength range, is absorbed; the larger the proportion of the crystals is, the absorption by the crystalline structure gets dominant so that red based light, which is light in a long wavelength range, is absorbed. In the case of a stacked photoelectric conversion device in which a plurality of unit cells is stacked, the following structure is preferable for photoelectric conversion because solar light in a wide wavelength range can be effectively utilized: the unit cells are arranged so that the unit cell on the light incidence side absorbs the light in a short wavelength range and the unit cell which is disposed farthest from the light incidence side absorbs light in a long wavelength range.

Note that the higher the proportion of the crystals is, the film thickness necessary for light absorption increases; therefore, the unit cells are preferably arranged in order of increasing thickness of the semiconductor layer including crystals from the unit cell on the light incidence side.

Further, the crystals can form a path for photogenerated carriers and moreover perform photoelectric conversion with light in a long wavelength range.

In the photoelectric conversion device illustrated in FIG. 2, the substrate 2 side is a light incidence plane. It is preferable that the proportion of the crystals 25 in the second semiconductor layer 23i of the second unit cell 20 is higher than the proportion of the crystals 15 in the first semiconductor layer 13i of the first unit cell 10 and that the proportion of the crystals 35 in the third semiconductor layer 33i of the third unit cell 30 is higher than those two above. Here, the thickness of the first semiconductor layer 13i of the first unit cell 10 is thickness t₁ and the proportion of the crystals 15 thereof is proportion d₁. The thickness of the second semiconductor layer 23i of the second unit cell 20 is thickness t₂ and the proportion of the crystals 25 thereof is proportion d₂. The thickness of the third semiconductor layer 33i of the third unit cell 30 is thickness t₃ and the proportion of the crystals 35 thereof is proportion d₃. In the photoelectric conversion device illustrated in FIG. 2, d₁<d₂<d₃ is preferable. Moreover, t₁<t₂<t₃ is preferable. With these relations satisfied, light can be effectively absorbed and higher efficiency can be achieved.

As the substrate 2 in the photoelectric conversion device illustrated in FIG. 2, a variety of commercial glass plates such as soda-lime glass, lead glass, strengthened glass, or ceramic glass can be given. Further, a non-alkali glass substrate such as an aluminosilicate glass substrate or a barium borosilicate glass substrate, a quartz substrate, or a metal substrate such as a stainless steel substrate can be used. Here, a substrate having a light-transmitting property is used as the substrate 2 because the substrate 2 serves as the light incidence plane.

When the substrate 2 serves as the light incidence plane, the first electrode 4 is formed from a transparent conductive material such as indium oxide, indium oxide-tin oxide (ITO), or zinc oxide as a light-transmitting electrode and the second electrode 6 is formed from a conductive material such as aluminum, silver, titanium, or tantalum as a reflective electrode. When the second electrode 6 side is the light incidence plane, the first electrode 4 is formed from a conductive material such as aluminum, silver, titanium, or tantalum as a reflective electrode and the second electrode 6 is formed from a transparent conductive material. In the case of forming the reflective electrode, the surface of the electrode which is in contact with the photoelectric conversion layer is preferably uneven because the reflectivity increases.

Note that as the transparent conductive material, a conductive high molecular material (also referred to as conductive polymer) can be used instead of oxide metal such as indium oxide. As the conductive high molecular material, a π electron conjugated conductive high molecule can be used. For example, polyaniline and/or a derivative thereof, polypyrrole and/or a derivative thereof, polythiophene and/or a derivative thereof, and a copolymer of two or more kinds of those materials can be given.

The first unit cell 10 is formed over the first electrode 4. First, the first impurity semiconductor layer 11p is formed from a p-type microcrystalline semiconductor over the first electrode 4. Next, the first semiconductor layer 13i is formed over the first impurity semiconductor layer 11p with use of plasma generated using a reaction gas in which a semiconductor source gas (typically silane) is diluted with a dilution gas (typically hydrogen) with the flow rate of the dilution gas to the semiconductor source gas being greater than or equal to 1 time and less than 10 times, preferably greater than or equal to 1 time and less than or equal to 6 times. By the control of the dilution rate of the semiconductor source gas and the control of the crystal structure of the lower layer, the first semiconductor layer 13i can be formed in which the crystals 15 are provided discretely in the amorphous structure 17. The crystals 15 are grown so as to penetrate through the first semiconductor layer 13i. Then, the second impurity semiconductor layer 11n is formed from an n-type microcrystalline semiconductor (or an n-type amorphous semiconductor) over the first semiconductor layer 13i, whereby the first unit cell 10 is completed.

The second unit cell 20 is formed over the first unit cell 10. The third impurity semiconductor layer 21p is formed from a p-type microcrystalline semiconductor over the second impurity semiconductor layer 11n having n-type conductivity. Next, the second semiconductor layer 23i is formed over the third impurity semiconductor layer 21p with use of plasma generated using a reaction gas in which a semiconductor source gas (typically silane) is diluted with a dilution gas (typically hydrogen) with the flow rate of the dilution gas to the semiconductor source gas being greater than or equal to 1 time and less than 10 times, preferably greater than or equal to 1 time and less than or equal to 6 times. The crystals 25 are grown so as to penetrate through the second semiconductor layer 23i. Here, the dilution rate of the semiconductor source gas is controlled preferably so that the proportion of the crystals 25 in the second semiconductor layer 23i is higher than that of the crystals 15 in the first semiconductor layer 13i. It is also preferable to form the second semiconductor layer 23i to be thicker than the first semiconductor layer 13i. Then, the fourth impurity semiconductor layer 21n is formed from an n-type microcrystalline semiconductor (or an n-type amorphous semiconductor) over the second semiconductor layer 23i, whereby the second unit cell 20 is completed.

The third unit cell 30 is formed over the second unit cell 20. The fifth impurity semiconductor layer 31p is formed from a p-type microcrystalline semiconductor over the fourth impurity semiconductor layer 21n having n-type conductivity. Next, the third semiconductor layer 33i is formed over the fifth impurity semiconductor layer 31p with use of plasma generated using a reaction gas in which a semiconductor source gas (typically silane) is diluted with a dilution gas (typically hydrogen) with the flow rate of the dilution gas to the semiconductor source gas being greater than or equal to 1 time and less than 10 times, preferably greater than or equal to 1 time and less than or equal to 6 times. Moreover, the crystals 35 are grown so as to penetrate through the third semiconductor layer 33i. Here, the dilution rate of the semiconductor source gas is preferably controlled so that the proportion of the crystals 35 in the third semiconductor layer 33i is higher than that of the crystals 25 in the second semiconductor layer 23i. It is also preferable to form the third semiconductor layer 33i to be thicker than the second semiconductor layer 23i. Then, the sixth impurity semiconductor layer 3 in is formed from an n-type microcrystalline semiconductor (or an n-type amorphous semiconductor) over the third semiconductor layer 33i, whereby the third unit cell 30 is completed.

The second electrode 6 is formed over the third unit cell 30. The second electrode 6 is formed from a transparent conductive material or a conductive material as a reflective electrode, as aforementioned. Here, the second electrode 6 is formed from aluminum, silver, titanium, tantalum, or the like because the substrate side 2 is the light incidence plane. In this manner, the stacked photoelectric conversion device illustrated in FIG. 2 can be completed.

Note that in this example, the first impurity semiconductor layer 11p, the third impurity semiconductor layer 21p, and the fifth impurity semiconductor layer 31p are p-type semiconductor layers and the second impurity semiconductor layer 11n, the fourth impurity semiconductor layer 21n, and the sixth impurity semiconductor layer 31n are n-type semiconductor layers; however, the layers 11p, 21p, and 31p may be n-type semiconductor layers and the layers 11n, 21n, and 31n may be p-type semiconductor layers. Further, although the substrate 2 side is the light incidence plane in this example, the second electrode 6 side may be the light incidence plane. In the case where the substrate 2 side is not the light incidence plane, the substrate 2 may be a substrate which does not have a light-transmitting property, such as a metal substrate.

Embodiment 1 shows the example in which the crystals are included in the first semiconductor layer 13i of the first unit cell 10, the second semiconductor layer 23i of the second unit cell 20, and the third semiconductor layer 33i of the third unit cell 30; however, the crystals may be included in any one or two of them.

Further, Embodiment 1 shows the example in which a pn junction is formed between the stacked unit cells (for example, the second impurity semiconductor layer 11n of the first unit cell 10 and the third impurity semiconductor layer 21p of the second unit cell 20); however, an intermediate layer may be provided between the unit cells. For example, an intermediate layer is provided between the second impurity semiconductor layer 11n of the first unit cell 10 and the third impurity semiconductor layer 21p of the second unit cell 20. In addition, an intermediate layer may be provided between the fourth impurity semiconductor layer 21n of the second unit cell 20 and the fifth impurity semiconductor layer 31p of the third unit cell 30. The intermediate layer is preferably formed from zinc oxide, titanium oxide, magnesium zinc oxide, cadmium zinc oxide, cadmium oxide, an In—Ga—Zn—O based amorphous oxide semiconductor such as InGaO₃ZnO₅, or the like.

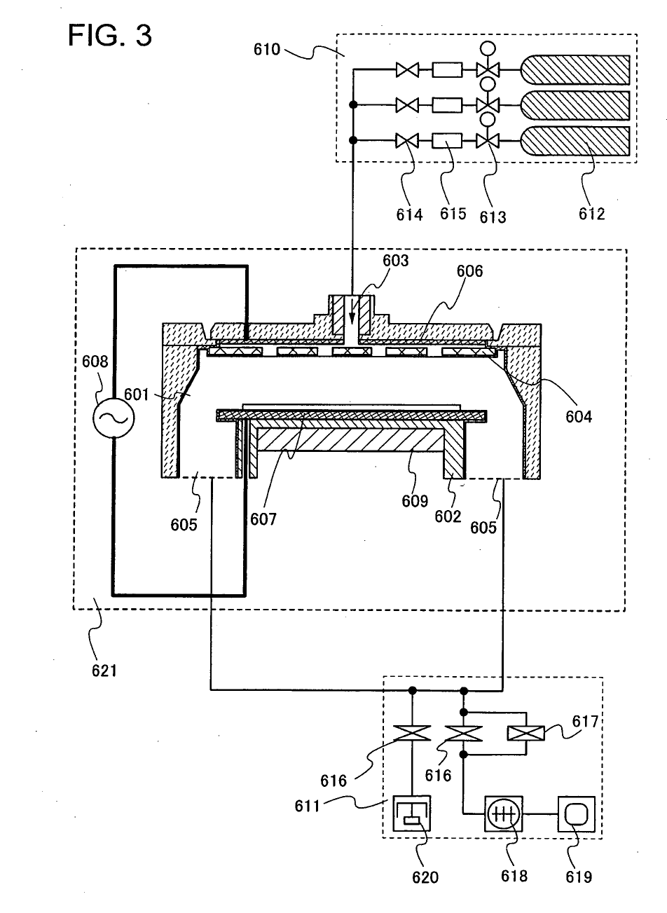

Next, FIG. 3 illustrates an example of a plasma CVD apparatus which is applicable for forming the semiconductor layer of the photoelectric conversion device of Embodiment 1.

A plasma CVD apparatus 621 illustrated in FIG. 3 is connected to a gas supply means 610 and an exhaust means 611.

The plasma CVD apparatus 621 illustrated in FIG. 3 includes a reaction chamber 601, a stage 602, a gas supply portion 603, a shower plate 604, an exhaust port 605, an upper electrode 606, a lower electrode 607, an AC power source 608, and a temperature control portion 609.

The reaction chamber 601 is formed from a material having rigidity and can be evacuated to vacuum. The reaction chamber 601 is provided with the upper electrode 606 and the lower electrode 607. Although FIG. 3 illustrates a capacitively coupled (parallel flat plate) type structure, another structure such as an inductively coupled type may be employed as long as plasma can be generated in the reaction chamber 601.

When treatment is performed with the plasma CVD apparatus illustrated in FIG. 3, a predetermined gas is supplied through the gas supply portion 603. The supplied gas is introduced to the reaction chamber 601 through the shower plate 604. High-frequency power is applied with the AC power source 608 connected to the upper electrode 606 and the lower electrode 607 to induce the gas in the reaction chamber 601, whereby plasma is generated. Further, the gas in the reaction chamber 601 is exhausted through the exhaust port 605 connected to a vacuum pump. Moreover, with the use of the temperature control portion 609, plasma process can be performed while the object to be processed is heated.

The gas supply means 610 includes a cylinder 612 which is filled with a reaction gas, a pressure adjusting valve 613, a stop valve 614, a mass flow controller 615, and the like. In the reaction chamber 601, the shower plate 604 which has a plate-like shape and is provided with a plurality of small openings is provided between the upper electrode 606 and the lower electrode 607. A reaction gas that is supplied to the upper electrode 606 passes through a hollow portion in the upper electrode 606, and is supplied into the reaction chamber 601 through the openings.

The exhaust means 611 that is connected to the reaction chamber 601 has a function of vacuum evacuation and a function of controlling the pressure inside the reaction chamber 601 to be maintained at a predetermined level when a reaction gas is introduced. The exhaust means 611 includes a butterfly valve 616, a conductance valve 617, a turbomolecular pump 618, a dry pump 619, and the like. When the butterfly valve 616 and the conductance valve 617 are provided in parallel, the exhaust velocity of a reaction gas can be controlled to keep the pressure in the reaction chamber 601 in a predetermined range by closing the butterfly valve 616 to operate the conductance valve 617. Moreover, to open the butterfly valve 616 having higher conductance makes it possible to perform high-vacuum evacuation.

In the case of evacuating the reaction chamber 601 to ultrahigh vacuum of a pressure lower than 10⁻⁵ Pa, a cryopump 620 is preferably used in combination. Alternatively, in the case where the reaction chamber 601 is evacuated to ultrahigh vacuum as ultimate vacuum, the inner wall of the reaction chamber 601 may be polished into a mirror surface and the reaction chamber 601 may be provided with a heater for baking in order to reduce degassing from the inner wall.

Note that by precoating treatment performed so that a film is formed covering the entire inner wall of the reaction chamber 601 illustrated in FIG. 3, it is possible to prevent an impurity element attached to or included in the inner wall of the reaction chamber from mixing into a film which is to be formed or the like.

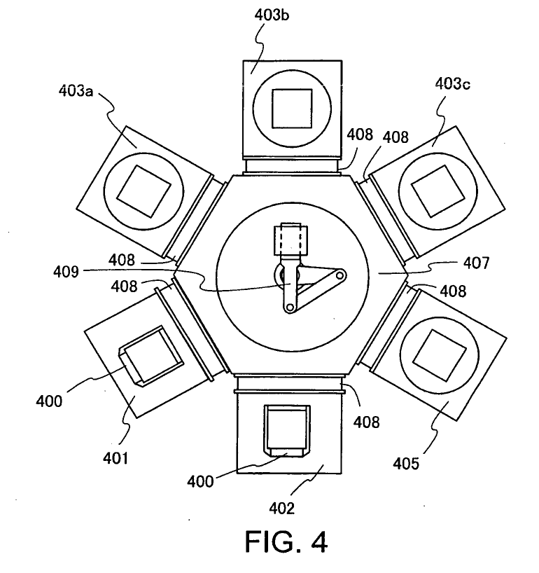

The plasma CVD apparatus illustrated in FIG. 3 can have a multi-chamber structure as illustrated in FIG. 4. This apparatus illustrated in FIG. 4 includes a load chamber 401, an unload chamber 402, a reaction chamber (1) 403a, a reaction chamber (2) 403b, a reaction chamber (3) 403c, and a spare chamber 405 around a common chamber 407. For example, an n-type semiconductor layer is formed in the reaction chamber (1) 403a, an i-type semiconductor layer is formed in the reaction chamber (2) 403b, and a p-type semiconductor layer is formed in the reaction chamber (3) 403c. An object to be processed is transferred in and out of each reaction chamber through the common chamber 407. A gate valve 408 is provided between the common chamber 407 and each chamber such that treatments performed in different reaction chambers do not interfere with each other. The substrate is disposed at a cassette 400 in the load chamber 401 and in the unload chamber 402 and transferred to the reaction chamber (1) 403a, the reaction chamber (2) 403b, and the reaction chamber (3) 403c by a transfer means 409 of the common chamber 407. In this apparatus, a reaction chamber can be provided for each kind of films to be deposited, and a plurality of different kinds of films can be formed in succession without being exposed to the air.

The first impurity semiconductor layer 11p to the sixth impurity semiconductor layer 31n can be formed with use of plasma generated by introducing a reaction gas in a reaction chamber (reaction space) of a plasma CVD apparatus with the structure as shown in FIG. 3 and FIG. 4.

In the case of forming a photoelectric conversion device having a pin junction, the plasma CVD apparatus is preferably provided with reaction chambers each corresponding to a p-type semiconductor layer, an i-type semiconductor layer, and an n-type semiconductor layer.

First, a first reaction gas is introduced into a reaction chamber (1) where the substrate 2 provided with the first electrode 4 has been transferred as the object to be processed, and plasma is generated. With the use of the plasma, the first impurity semiconductor layer 11p (p-type impurity semiconductor layer) is formed over the first electrode 4 provided over the substrate 2. Next, the substrate 2 provided with the first impurity semiconductor layer 11p is transferred from the reaction chamber (1) to a reaction chamber (2) without exposure to the air. A second reaction gas is introduced to the reaction chamber (2) to generate plasma with which the first semiconductor layer 13i (i-type semiconductor layer) is formed over the first impurity semiconductor layer 11p. Then, the substrate 2 provided with the first semiconductor layer 13i is transferred from the reaction chamber (2) to a reaction chamber (3) without exposure to the air. A third reaction gas is introduced to the reaction chamber (3) to generate plasma with which the second impurity semiconductor layer 11n (n-type impurity semiconductor layer) is formed over the first semiconductor layer 13i. In this manner, the first unit cell 10 is completed over the substrate 2.

In a manner similar to the formation of the first unit cell 10, the third impurity semiconductor layer 21p is formed in the reaction chamber (1), the second semiconductor layer 23i is formed in the reaction chamber (2), and the fourth impurity semiconductor layer 21n is formed in the reaction chamber (3), whereby the second unit cell 20 is completed. Furthermore, the fifth impurity semiconductor layer 31p is formed in the reaction chamber (1), the third semiconductor layer 33i is formed in the reaction chamber (2), and the sixth impurity semiconductor layer 31n is formed in the reaction chamber (3), whereby the third unit cell 30 is completed. By the control of the mixture ratio of the reaction gases used for forming the second semiconductor layer 23i and the third semiconductor layer 33i, or the like, the proportion of crystals and the like can be changed.

In FIG. 4, the number of reaction chambers is three in accordance with the number of kinds of films which are stacked (p-type impurity semiconductor layer, i-type semiconductor layer, and n-type impurity semiconductor layer).

For example, in the case of forming a pi junction, a pn junction, an ni junction, or the like for the photoelectric conversion layer, the number of reaction chambers used for forming the semiconductor layers may be two. Alternatively, when layers having the same conductivity type but having different concentrations are stacked like in the case of a pp⁻n junction or p⁺pp⁻n junction, the number of reaction chambers may be four. However, in some cases, two chambers may be sufficient as long as the concentration of the gas including the impurity element to be introduced to the reaction chamber is controlled.

Note that Embodiment 1 can be combined with any of the other embodiments as appropriate.

### Embodiment 2

Embodiment 2 describes a photoelectric conversion device having a different structure from that described in Embodiment 1. Specifically, the number of stacked unit cells in the photoelectric conversion device of this example is different from that illustrated in FIG. 2.

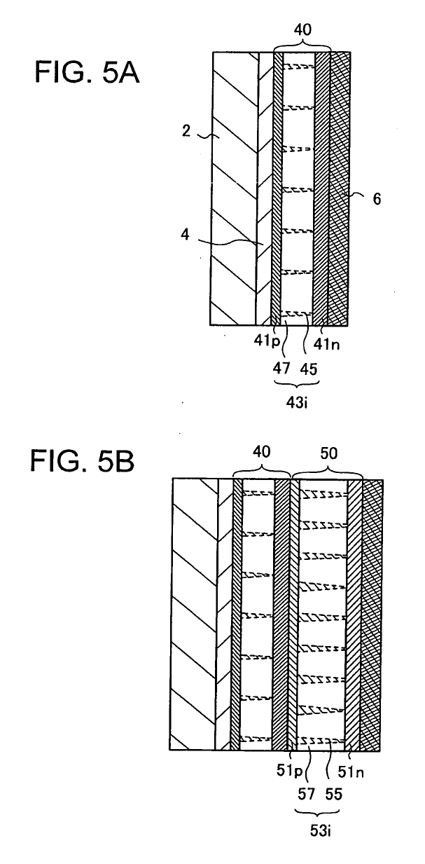

FIG. 5A illustrates a single junction photoelectric conversion device including one unit cell. In this photoelectric conversion device which includes at least one semiconductor junction, a unit cell 40 is formed over a substrate 2 provided with a first electrode 4 and a second electrode 6 is formed over the unit cell 40. The unit cell 40 includes a stack of an impurity semiconductor layer 41p, which is a p-type semiconductor, a semiconductor layer 43i, which is an i-type semiconductor, and an impurity semiconductor layer 41n, which is an n-type semiconductor. In the semiconductor layer 43i, crystals 45 are provided discretely in an amorphous structure 47. The crystals 45 penetrate through the semiconductor layer 43i between the impurity semiconductor layer 41p and the impurity semiconductor layer 41n. The proportion of the crystals 45 and the like can be controlled by setting the dilution rate of a dilution gas to a semiconductor source gas in a reaction gas for forming the semiconductor layer 43i. As the unit cell 40, the unit cell 9 in Embodiment 1 can be used. The impurity semiconductor layer 41p, the semiconductor layer 43i, and the impurity semiconductor layer 41n correspond to the impurity semiconductor layer 1p, the semiconductor layer 3i, and the impurity semiconductor layer 1n, respectively. In this manner, even the device having one unit cell between the pair of electrodes can serves as a photoelectric conversion device. When the unit cell includes the semiconductor layer according to an embodiment of the present invention which has, in an amorphous structure, crystals penetrating between the pair of impurity semiconductor layers bonded for forming an internal electric field, the increase in both efficiency and productivity can be achieved.

FIG. 5B illustrates a tandem photoelectric conversion device in which two unit cells are stacked. In this photoelectric conversion device, the unit cell 40 is formed over the substrate 2 provided with the first electrode 4, a unit cell 50 is formed over the unit cell 40, and the second electrode 6 is formed over the unit cell 50. The unit cell 50 includes a stack of an impurity semiconductor layer 51p, which is a p-type semiconductor, a semiconductor layer 53i, which is an i-type semiconductor, and an impurity semiconductor layer 51n, which is an n-type semiconductor. In the case of applying an embodiment of the present invention to a tandem photoelectric conversion device, at least one of the stacked unit cells needs to include a semiconductor layer including crystals penetrating between a pair of impurity semiconductor layers bonded for forming an internal electric field. Here, in this example, each of the two unit cells includes a semiconductor layer including crystals penetrating between a pair of impurity semiconductor layers bonded for forming an internal electric field. The semiconductor layer 43i of the unit cell 40 has the crystals 45 provided discretely in the amorphous structure 47 and the crystals 45 penetrate between the impurity semiconductor layer 41p and the impurity semiconductor layer 41n. The semiconductor layer 53i of the unit cell 50 has crystals 55 provided discretely in an amorphous structure 57 and the crystals 55 penetrate between the impurity semiconductor layer 51p and the impurity semiconductor layer 51n. It is preferable that the proportions of the crystals increase in order from the unit cell on the light incidence side. Further, it is preferable that the thicknesses of the semiconductor layers including crystals increase in order from the unit cell on the light incidence side. In this manner, an embodiment of the present invention can be applied to the photoelectric conversion device having two unit cells between a pair of electrodes. When the unit cell includes the semiconductor layer according to an embodiment of the present invention which has, in an amorphous structure, crystals penetrating between the pair of impurity semiconductor layers bonded for forming an internal electric field, the increase in both efficiency and productivity can be achieved.

Note that Embodiment 2 can be combined with any of the other embodiments as appropriate.

### Embodiment 3

Embodiment 3 describes a photoelectric conversion device with a different structure from that in Embodiment 1 or 2. Specifically, an example is shown in which a junction portion between an impurity semiconductor layer having one conductivity type and an intrinsic semiconductor layer is provided with an impurity semiconductor layer having the same conductivity type as the one conductivity type and having lower impurity concentration than the impurity semiconductor layer having the one conductivity type.

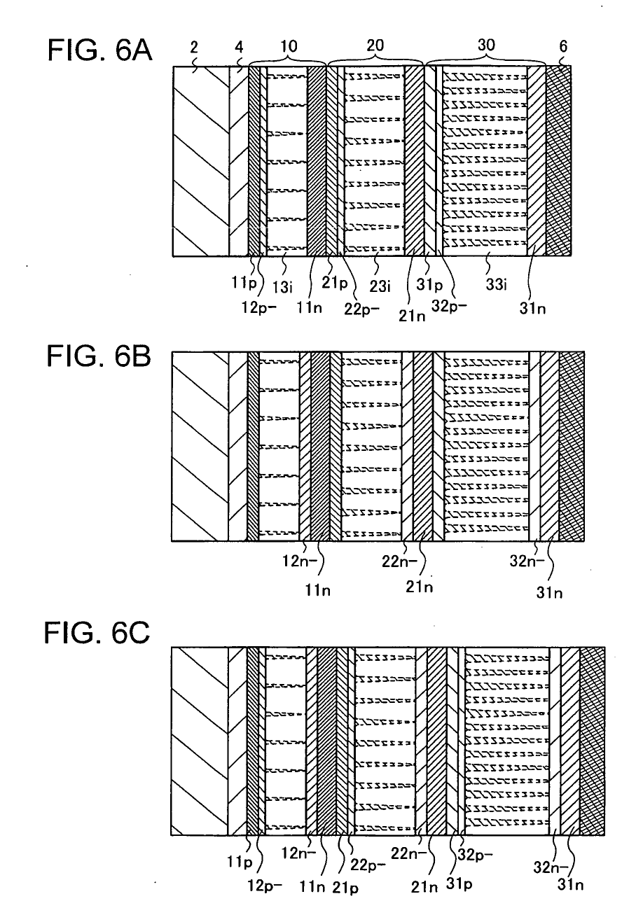

Each of FIGS. 6A to 6C illustrates a stacked photoelectric conversion device in which three unit cells are formed. In FIG. 6A, a first unit cell 10, a second unit cell 20, a third unit cell 30, and a second electrode 6 are provided in that order over a substrate 2 provided with a first electrode 4. In the first unit cell 10, a first impurity semiconductor layer 11p, a first low-concentration impurity semiconductor layer 12p⁻, a first semiconductor layer 13i, and a second impurity semiconductor layer 11n are stacked in that order from the substrate 2 side. In the second unit cell 20, a third impurity semiconductor layer 21p, a third low-concentration impurity semiconductor layer 22p⁻, a second semiconductor layer 23i, and a fourth impurity semiconductor layer 21n are stacked in that order from the substrate 2 side. In the third unit cell 30, a fifth impurity semiconductor layer 31p, a fifth low-concentration impurity semiconductor layer 32p⁻, a third semiconductor layer 33i, and a sixth impurity semiconductor layer 31n are stacked in that order from the substrate 2 side.

The first low-concentration impurity semiconductor layer 12p is provided between the first impurity semiconductor layer 11p and the first semiconductor layer 13i in the first unit cell 10. The first low-concentration impurity semiconductor layer 12p includes an impurity element imparting the same conductivity type as that of the first impurity semiconductor layer 11p and has lower impurity concentration than the first impurity semiconductor layer 11p. In a similar manner, the third low-concentration impurity semiconductor layer 22p⁻ is provided between the third impurity semiconductor layer 21p and the second semiconductor layer 23i in the second unit cell 20. The fifth low-concentration impurity semiconductor layer 32p⁻ is provided between the fifth impurity semiconductor layer 31p and the third semiconductor layer 33i in the third unit cell 30. The third low-concentration impurity semiconductor layer 22p⁻ has the same conductivity type as that of the third impurity semiconductor layer 21p and has lower impurity concentration than the third impurity semiconductor layer 21p. Further, the fifth low-concentration impurity semiconductor layer 32p has the same conductivity type as that of the fifth impurity semiconductor layer 31p and has lower impurity concentration than the fifth impurity semiconductor layer 31p.

When the junction portion between the impurity semiconductor layer having one conductivity type and the i-type semiconductor layer is provided with the impurity semiconductor layer having the same conductivity type as the one conductivity type and has lower impurity concentration than the impurity semiconductor layer having the one conductivity type, the carrier transporting property at the semiconductor junction interface can be improved. For example, in FIG. 6A, the arrangement of pp⁻inpp⁻inpp⁻in from the first electrode 4 side is employed. The p⁻ in each unit cell improves the carrier transporting property and contributes higher efficiency. The carrier transporting property is further improved when the impurity concentration of the low-concentration impurity semiconductor layer is decreased in a stepwise manner or continuous manner from the impurity semiconductor layer having one conductivity type toward the i-type semiconductor layer. Further, the interface state density is reduced and the diffusion potential is improved by the provision of the low-concentration impurity semiconductor layer, whereby an open circuit voltage of the photoelectric conversion device is increased. Note that the low-concentration impurity semiconductor layer may be formed from a microcrystalline semiconductor, typically microcrystalline silicon.

In FIG. 6B, the first unit cell 10, the second unit cell 20, the third unit cell 30, and the second electrode 6 are provided in that order over the substrate 2 provided with the first electrode 4. In the first unit cell 10, the first impurity semiconductor layer 11p, the first semiconductor layer 13i, a second low-concentration impurity semiconductor layer 12n⁻, and the second impurity semiconductor layer 11n are stacked in that order from the substrate 2 side. In the second unit cell 20, the third impurity semiconductor layer 21p, the second semiconductor layer 23i, a fourth low-concentration impurity semiconductor layer 22n⁻, and the fourth impurity semiconductor layer 21n are stacked in that order from the substrate 2 side. In the third unit cell 30, the fifth impurity semiconductor layer 31p, the third semiconductor layer 33i, a sixth low-concentration impurity semiconductor layer 32n⁻, and the sixth impurity semiconductor layer 31n are stacked in that order from the substrate 2 side. The second low-concentration impurity semiconductor layer 12n includes an impurity element imparting the same conductivity type as that of the second impurity semiconductor layer 31n and has lower impurity concentration than the second impurity semiconductor layer 11n. In a similar manner, the fourth low-concentration impurity semiconductor layer 22n⁻ has the same conductivity type as that of the fourth impurity semiconductor layer 21n and has lower impurity concentration than the fourth impurity semiconductor layer 21n. Further, the sixth low-concentration impurity semiconductor layer 32n⁻ has the same conductivity type as that of the sixth impurity semiconductor layer 31n and has lower impurity concentration than the sixth impurity semiconductor layer 31n. For example, in FIG. 6B, the arrangement of pin⁻npin⁻npin⁻n from the first electrode 4 side is employed. The n⁻ in each unit cell improves the carrier transporting property.

In FIG. 6C, the first unit cell 10, the second unit cell 20, the third unit cell 30, and the second electrode 6 are provided in that order over the substrate 2 provided with the first electrode 4. In the first unit cell 10, the first impurity semiconductor layer 11p, the first low-concentration impurity semiconductor layer 12p⁻, the first semiconductor layer 13i, the second low-concentration impurity semiconductor layer 12n⁻, and the second impurity semiconductor layer 11n are stacked in that order from the substrate 2 side. In the second unit cell 20, the third impurity semiconductor layer 21p, the third impurity semiconductor layer 22p⁻, the second semiconductor layer 23i, the fourth low-concentration impurity semiconductor layer 22n, and the fourth impurity semiconductor layer 21n are stacked in that order from the substrate 2 side. In the third unit cell 30, the fifth impurity semiconductor layer 31p, the fifth low-concentration impurity semiconductor layer 32p⁻, the third semiconductor layer 33i, the sixth low-concentration impurity semiconductor layer 32n, and the sixth impurity semiconductor layer 31n are stacked in that order from the substrate 2 side. For example, in FIG. 6C, the arrangement of pp⁻in⁻npp⁻in⁻npp⁻in⁻n from the first electrode 4 side is employed. The p⁻ and n⁻ in each unit cell improve the carrier transporting property.

Note that the example in which the low-concentration impurity semiconductor layer is provided in each unit cell is described with reference to FIGS. 6A to 6C; however, the low-concentration impurity semiconductor layer may be provided only in the unit cell that needs the low-concentration impurity semiconductor layer, as appropriate. The positions of the p-type impurity semiconductor layer and the n-type impurity semiconductor layer may be exchanged and the second electrode 6 side may be the light incidence plane.

At least one of the first semiconductor layer 13i, the second semiconductor layer 23i, and the third semiconductor layer 33i is a semiconductor layer including crystals in an amorphous structure. The crystals penetrate through the semiconductor layer (amorphous structure) between the pair of impurity semiconductor layers which form an internal electric field. In the case where the low-concentration impurity semiconductor layer is disposed between the semiconductor layer including the crystals and one of the pair of impurity semiconductor layers, the crystals may penetrate between the low-concentration impurity semiconductor layer and the other impurity semiconductor layer (or the other low-concentration impurity semiconductor layer).

The stacked photoelectric conversion device is described in Embodiment 3; however, the single junction photoelectric conversion device or the tandem photoelectric conversion device which is shown in the above embodiments can be fabricated as well.

Note that Embodiment 3 can be combined with any of the other embodiments as appropriate.

### Embodiment 4

Embodiment 4 describes an example of an integrated photoelectric conversion device in which a plurality of photoelectric conversion cells is formed over one substrate and the photoelectric conversion cells are connected in series so that a photoelectric conversion device is integrated. Specifically, Embodiment 4 describes an example of integrating a stacked photoelectric conversion device in which three unit cells are stacked in a vertical direction. A process for manufacturing an integrated photoelectric conversion device and the schematic structure thereof are described below.

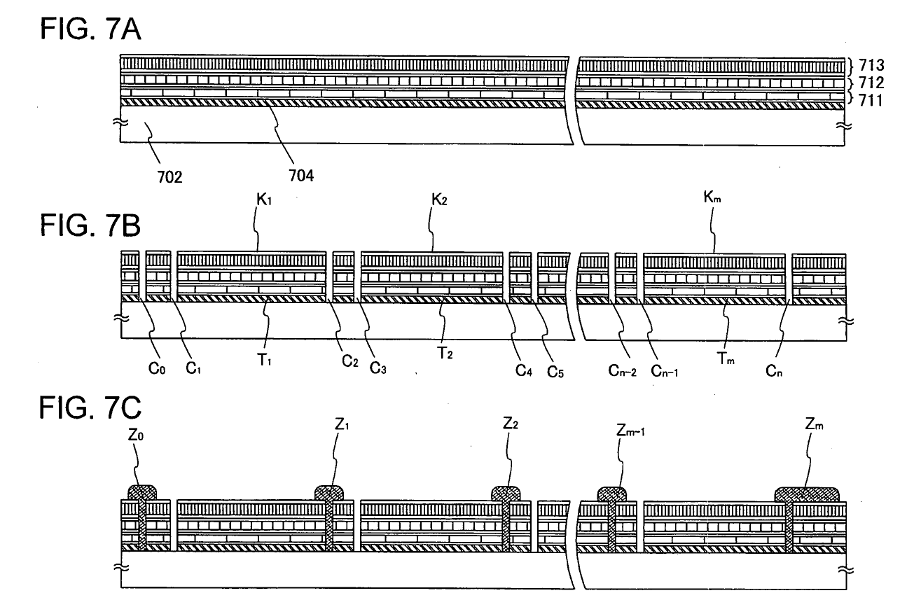

In FIG. 7A, a first electrode layer 704 is provided over a substrate 702. Alternatively, the substrate 702 provided with the first electrode layer 704 is prepared. The first electrode layer 704 is formed to a thickness of 40 nm to 200 nm (preferably 50 nm to 100 nm) from a transparent conductive material such as indium oxide, indium tin oxide alloy, zinc oxide, tin oxide, or alloy of indium tin oxide and zinc oxide. The sheet resistance of the first electrode layer 704 may be about 20 Ω/square to 200 Ω/square.

The first electrode layer 704 can be formed from a conductive high molecular material. When a thin film of a conductive high molecular material is formed as the first electrode layer 704, the thin film preferably has a sheet resistance of less than or equal to 10000 Ω/square and a light transmittance of greater than or equal to 70% with respect to light with a wavelength of 550 nm. Note that the resistivity of a conductive high molecule included in the first electrode layer 704 is preferably lower than or equal to 0.1 Ω·cm. As the conductive high molecule, a so-called π-electron conjugated conductive high molecule can be used. For example, polyaniline and/or a derivative thereof, polypyrrole and/or a derivative thereof, polythiophene and/or a derivative thereof, and a copolymer of two or more kinds of those materials can be given.

Specific examples of a conjugated conductive high molecule are given below: polypyrrole, poly(3-methylpyrrole), poly(3-butylpyrrole), poly(3-octylpyrrole), poly(3-decylpyrrole), poly(3,4-dimethylpyrrole), poly(3,4-dibutylpyrrole), poly(3-hydroxypyrrole), poly(3-methyl-4-hydroxypyrrole), poly(3-methoxypyrrole), poly(3-ethoxypyrrole), poly(3-octoxypyrrole), poly(3-carboxylpyrrole), poly(3-methyl-4-carboxylpyrrole), polyN-methylpyrrole, polythiophene, poly(3-methylthiophene), poly(3-butylthiophene), poly(3-octylthiophene), poly(3-decylthiophene), poly(3-dodecylthiophene), poly(3-methoxythiophene), poly(3-ethoxythiophene), poly(3-octoxythiophene), poly(3-carboxylthiophene), poly(3-methyl-4-carboxylthiophene), poly(3,4-ethylenedioxythiophene), polyaniline, poly(2-methylaniline), poly(2-octylaniline), poly(2-isobutylaniline), poly(3-isobutylaniline), poly(2-anilinesulfonic acid), poly(3-anilinesulfonic acid), or the like.

The aforementioned conductive high molecule may be used alone to form the first electrode layer 704. An organic resin may be added in order to adjust the property of the conductive high molecular material.

As for the organic resin added to adjust the property of the conductive high molecular material, any of a thermosetting resin, a thermoplastic resin, or a photocurable resin may be used as long as the resin is compatible to a conductive high molecule or the resin can be mixed and dispersed into a conductive high molecule. For example, a polyester-based resin such as polyethylene terephthalate, polybutylene terephthalate, or polyethylene naphthalate; a polyimide-based resin such as polyimide or polyamide-imide; a polyamide resin such as polyamide 6, polyamide 66, polyamide 12, or polyamide 11; a fluorine resin such as polyvinylidene fluoride, polyvinyl fluoride, polytetrafluoroethylene, ethylene tetrafluoroethylene copolymer, or polychlorotrifluoroethylene; a vinyl resin such as polyvinyl alcohol, polyvinyl ether, polyvinyl butyral, polyvinyl acetate, or polyvinyl chloride; an epoxy resin; a xylene resin; an aramid resin; a polyurethane-based resin; a polyurea-based resin, a melamine resin; a phenol-based resin; polyether; an acrylic-based resin, or a copolymer of any of those resins can be used.

Further, the oxidation reduction potentials of a conjugated electron of a conjugated conductive high molecule may be changed by adding an impurity serving as an acceptor or a donor to the conductive high molecular material, so that the electric conductivity of the first electrode layer 704 can be adjusted.

As the impurity serving as an acceptor, a halogen compound, Lewis acid, proton acid, an organic cyano compound, an organometallic compound, or the like can be used. As examples of the halogen compound, chlorine, bromine, iodine, iodine chloride, iodine bromide, iodine fluoride, and the like can be given. As examples of the Lewis acid, phosphorus pentafluoride, arsenic pentafluoride, antimony pentafluoride, boron trifluoride, boron trichloride, boron tribromide, and the like can be given. As examples of the proton acid, inorganic acid such as hydrochloric acid, sulfuric acid, nitric acid, phosphoric acid, fluoroboric acid, hydrofluoric acid, and perchloric acid and organic acid such as organic carboxylic acid and organic sulfonic acid can be given. As the organic carboxylic acid and the organic sulfonic acid, the above-described carboxylic acid compounds or sufonic acid compounds can be used. As the organic cyano compound, a compound in which two or more cyano groups are included in a conjugated bond can be used. As an organic cyano compound, a compound having two or more cyano groups in a conjugated bonding, for example, tetracyanoethylene, tetracyanoethylene oxide, tetracyanobenzene, tetracyanoquinodimethane, and tetracyanoazanaphthalene are given.

As the impurity serving as a donor, alkali metal, alkaline-earth metal, a tertiary amine compound, or the like can be used.

Further, a thin film used for the first electrode layer 704 can be formed by a wet process using a solution in which a conductive high molecule is dissolved in water or an organic solvent (e.g., an alcohol solvent, a ketone solvent, an ester solvent, a hydrocarbon solvent, or an aromatic solvent). There is no particular limitation on the solvent for dissolving the conductive high molecule and a solvent that can dissolve a high molecular resin compound such as the aforementioned conductive high molecule or organic resins can be used. For example any one of or a mixture of water, methanol, ethanol, propylene carbonate, N-methylpyrrolidone, N,N-dimethylformamide, N,N-dimethylacetamide, cyclohexanone, acetone, methyl ethyl ketone, methyl isobutyl ketone, toluene, or the like may be used as the solvent.

A film of a conductive high molecular material can be formed by a wet process such as a coating method, a droplet discharge method (also referred to as an inkjet method), or a printing method. The solvent that dissolves the conductive high molecular material may be vaporized by thermal treatment or thermal treatment under reduced pressure. In the case where the organic resin added to the conductive high molecular material is a thermosetting resin, thermal treatment may be performed further. In the case where the organic resin is a photocurable resin, light irradiation treatment may be performed.

Alternatively, the first electrode layer 704 can be formed from a transparent conductive material, which is a composite material including an organic compound and an inorganic compound having an electron-accepting property to the organic compound. With the composite material including a first organic compound and a second inorganic compound having an electron-accepting property to the first organic compound, the resistivity can be set less than or equal to 1×10⁶ Ω·cm. Note that the “composition” refers to not only a state where a plurality of materials is simply mixed but also a state where charges are transported between materials by the mixture.

As the organic compound used for the composite material, a variety of compounds are given such as an aromatic amine compound, a carbazole derivative, aromatic hydrocarbon, and a high molecular compound (oligomer, dendrimer, polymer, or the like). The organic compound used for the composite material is preferably an organic compound having a high hole transporting property. Specifically, a substance having a hole mobility of 10⁶ cm²/Vsec or higher is preferably used. Another substance may be employed as long as the hole-transporting property is higher than the electron-transporting property.

Specifically, as the organic compound used for the composite material, the following compounds are given, for example: 4,4′-bis[N-(1-naphthyl)-N-phenylamino]biphenyl (abbreviation: NPB); 4,4′-bis[N-(3-methylphenyl)-N-phenylamino]biphenyl (abbreviation: TPD); 4,4′,4″-tris(N,N-diphenylamino)triphenylamine (abbreviation: TDATA); 4,4′,4″-tris[N-(3-methylphenyl)-N-phenylamino]triphenylamine (abbreviation: MTDATA); and the like.

When any of the organic compounds shown below is used, a composite material that does not have an absorption peak in a wavelength region of 450 nm to 800 nm can be obtained. At the same time, the resistivity can be set less than or equal to 1×10⁶ Ω·cm, typically, 5×10⁴ Ω·cm to 1×10⁶ Ω·cm.

As the composite material that does not have an absorption peak in a wavelength region of 450 nm to 800 nm, the following aromatic amine compounds can be given: N,N′-di(p-tolyl)-N,N′-diphenyl-p-phenylenediamine (abbreviation: DTDPPA); 4,4′-bis[N-(4-diphenylaminophenyl)-N-phenylamino]biphenyl (abbreviation: DPAB); 4,4′-bis(N-{4-[N-(3-methylphenyl)-N-phenylamino]phenyl}-N-phenylamino)biphenyl (abbreviation: DNTPD); 1,3,5-tris[N-(4-diphenylaminophenyl)-N-phenylamino]benzene (abbreviation: DPA3B); and the like.

As the composite material that does not have an absorption peak in a wavelength region of 450 nm to 800 nm, the following carbazole derivatives can be given specifically: 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); 3-[N-(1-naphtyl)-N-(9-phenylcarbazol-3-yl)amino]-9-phenylcarbazole (abbreviation: PCzPCN1); and the like. Alternatively, another carbazole derivative such as 4,4′-di(N-carbazolyt)biphenyl (abbreviation: CBP); 1,3,5-tris[4-(N-carbazolyl)phenyl]benzene (abbreviation: TCPB); 9-[4-(N-carbazolyl)]phenyl-10-phenylanthracene (abbreviation: CzPA); or 2,3,5,6-triphenyl-1,4-bis[4-(N-carbazolyl)phenyl]benzene can be used.

As the composite material that does not have an absorption peak in a wavelength region of 450 nm to 800 nm, the following aromatic hydrocarbon is given, for example: 9,10-di(naphthalen-2-yl)-2-tert-butylanthracene (abbreviation: t-BuDNA); 9,10-di(naphthalen-1-yl)-2-tert-butylanthracene; 9,10-bis(3,5-diphenylphenyl)anthracene (abbreviation: DPPA); 9,10-di(4-phenylphenyl)-2-tert-butylanthracene (abbreviation: t-BuDBA); 9,10-di(naphthalen-2-yl)anthracene (abbreviation: DNA); 9,10-diphenylanthracene (abbreviation: DPAnth); 2-tert-butylanthracene (abbreviation: t-BuAnth); 9,10-di(4-methylnaphthalen-1-yl)anthracene (abbreviation: DMNA); 2-tert-butyl-9,10-bis[2-(naphthalen-1-yl)phenyl]anthracene; 9,10-bis[2-(naphthalen-1-yl)phenyl]anthracene; 2,3,6,7-tetramethyl-9,10-di(naphthalen-1-yl)anthracene; 2,3,6,7-tetramethyl-9,10-di(naphthalen-2-yl)anthracene; 9,9′-bianthryl; 10,10′-diphenyl-9,9′-bianthryl; 10,10′-di(2-phenylphenyl)-9,9′-bianthryl; 10,10′-bis[(2,3,4,5,6-pentaphenyl)phenyl]-9,9′-bianthryl; anthracene; tetracene; rubrene; perylene; 2,5,8,11-tetra(tert-butyl)perylene; or the like. As alternatives to these compounds, pentacene, coronene, or the like can be given. It is particularly preferable to use aromatic hydrocarbon which has a hole mobility of greater than or equal to 1×10⁻⁶ cm²/Vsec and which has 14 to 42 carbon atoms.

An aromatic hydrocarbon that can be used for the composite material that does not have an absorption peak in a wavelength region of 450 nm to 800 nm may have a vinyl skeleton. As the aromatic hydrocarbon having a vinyl skeleton, the following can be given for example: 4,4′-bis(2,2-diphenylvinyl)biphenyl (abbreviation: DPVBi); 9,10-bis[4-(2,2-diphenylvinyl)phenyl]anthracene (abbreviation: DPVPA); and the like.

Alternatively, a high molecular compound such as poly{4-[N-(4-diphenylaminophenyl)-N-phenyl]aminostyrene} (abbreviation: PStDPA); poly{4-[N-(9-carbazol-3-yl)-N-phenylamino]styrene} (abbreviation: PStPCA); poly(N-vinylcarbazole) (abbreviation: PVK); or poly(4-vinyltriphenylamine) (abbreviation: PVTPA) can be used.

As the inorganic compound used for the composite material, an oxide of a transition metal is preferably used. Moreover, an oxide of a metal belonging to any of Group 4, Group 5, Group 6, Group 7, or Group 8 in the periodic table is preferably used. Specifically, vanadium oxide, niobium oxide, tantalum oxide, chromium oxide, molybdenum oxide, tungsten oxide, manganese oxide, and rhenium oxide are preferable because of their high electron accepting property. Above all, molybdenum oxide is particularly preferable since it is stable in the air, has a low moisture absorption property, and is easily treated.

In a method for manufacturing the first electrode layer 704 with use of the composite material, any process may be employed whether it is a dry process or a wet process. For example, the first electrode layer 704 including the composite material can be manufactured by co-evaporation of the aforementioned organic compound and inorganic compound. In the case of forming the first electrode layer 704 from molybdenum oxide, an evaporation method is preferably employed from the point of the manufacturing process, because molybdenum oxide is easy to evaporate in vacuum. Further, the first electrode layer 704 can also be obtained in such a way that a solution including the above organic compound and metal alkoxide is coated and baked. As a method for coating, an ink-jet method, a spin-coating method, or the like can be used.

By selecting the kind of the organic compound in the composite material used for the first electrode layer 704, a composite material that does not have an absorption peak in a wavelength region of 450 nm to 800 nm can be obtained. Accordingly, light such as solar light can be efficiently transmitted without absorption, so that light collection efficiency can be improved. The first electrode layer 704 formed from the composite material is resistant to bending. Therefore, in the case of manufacturing the photoelectric conversion device with use of a flexible substrate, the use of the composite material for the first electrode layer 704 is effective.

From the point of decrease in resistance of the first electrode layer 704, the use of ITO is suitable. In this case, in order to prevent deterioration of an ITO film, it is effective to form a SnO₂ film or a ZnO film over the ITO film. A ZnO (ZnO:Ga) film containing gallium (Ga) by 1 wt % to 10 wt % has a high transmittance and is suitable to be stacked over the ITO film. As an example of a combination thereof, when the first electrode layer 704 is formed using an ITO film with a thickness of 50 nm to 60 nm and a ZnO:Ga film with a thickness of 25 nm provided over the ITO film, favorable light transmittance can be obtained. The sheet resistance of the stack of the ITO film and the ZnO:Ga film is 120 Ω/square to 150 Ω/square.

A first unit cell 711, a second unit cell 712, and a third unit cell 713 are stacked in that order over the first electrode layer 704. A photoelectric conversion layer in each of the first unit cell 711, the second unit cell 712, and the third unit cell 713 is formed from a semiconductor, specifically from a microcrystalline semiconductor or an amorphous semiconductor, by a plasma CVD method. A typical example of a microcrystalline semiconductor is microcrystalline silicon manufactured using a reaction gas in which SiH₄ gas is diluted with hydrogen gas. Alternatively, microcrystalline silicon-germanium or microcrystalline silicon-carbide can be used. A typical example of an amorphous semiconductor is amorphous silicon manufactured using SiH₄ gas as a reaction gas. Alternatively, amorphous silicon-carbide or amorphous germanium can be used. Each of the first unit cell 711 to the third unit cell 713 includes any semiconductor junction of a pin junction, a pi junction, an in junction, or a pn junction.

In the photoelectric conversion device of Embodiment 4, the first unit cell 711 includes a stack of the first impurity semiconductor layer 11p, the first semiconductor layer 13i, and the second impurity semiconductor layer 11n which are illustrated in FIG. 2. In a similar manner, the second unit cell 712 includes a stack of the third impurity semiconductor layer 21p, the second semiconductor layer 23i, and the fourth impurity semiconductor layer 21n. Further, the third unit cell 713 includes a stack of the fifth impurity semiconductor layer 31p, the third semiconductor layer 33i, and the sixth impurity semiconductor layer 31n. The thickness of each of the first unit cell 711, the second unit cell 712, and the third unit cell 713 is in the range of 0.5 μm to 10 μm, preferably 1 μm to 5 μm. The thicknesses of the unit cells are preferably as follows: the first unit cell 711<the second unit cell 712<the third unit cell 713.

The main part of the first unit cell 711 which performs photoelectric conversion is formed from a semiconductor layer including crystals in an amorphous structure. The crystals penetrate between a pair of impurity semiconductor layers bonded for forming an internal electric field. The semiconductor layer including crystals in an amorphous structure can be formed over the first impurity semiconductor layer 11p formed from a microcrystalline semiconductor in such a manner that a semiconductor source gas and a dilution gas are introduced to a reaction space. The flow rate of the dilution gas to the semiconductor source gas is greater than or equal to 1 time and less than 10 times, preferably greater than or equal to 1 time and less than or equal to 6 times. By the control of the dilution amount in forming the semiconductor layer, the crystals can be grown from the interface between the semiconductor layer and the first impurity semiconductor layer 11p toward the deposition direction of the first semiconductor layer 13i to reach the second impurity semiconductor layer 11n which is formed later.

In a similar manner, the main part of the second unit cell 712 which performs photoelectric conversion is a semiconductor layer including crystals in an amorphous structure and the crystals penetrate between a pair of impurity semiconductor layers bonded for forming an internal electric field. The semiconductor layer including the crystals can be formed over the third impurity semiconductor layer 21p formed from a microcrystalline semiconductor in such a manner that a semiconductor source gas and a dilution gas are introduced to a reaction space. The flow rate of the dilution gas to the semiconductor source gas is greater than or equal to 1 time and less than 10 times, preferably greater than or equal to 1 time and less than or equal to 6 times. The main part of the third unit cell 713 which performs photoelectric conversion includes crystals in an amorphous structure and the crystals penetrate between a pair of impurity semiconductor layers bonded for forming an internal electric field. The semiconductor layer i including crystals can be formed over the fifth impurity semiconductor layer 31p formed from a microcrystalline semiconductor in such a manner that a semiconductor source gas and a dilution gas are introduced to a reaction space. The flow rate of the dilution gas to the semiconductor source gas is greater than or equal to 1 time and less than 10 times, preferably greater than or equal to 1 time and less than or equal to 6 times. The proportion of the crystals with respect to the amorphous structure in the semiconductor layer as the main part which performs photoelectric conversion is preferably in the following order: the first unit cell 711<the second unit cell 712<the third unit cell 713.

Note that each of the first unit cell 711 to the third unit cell 713 has the semiconductor layer including the crystals in the amorphous structure is described in this example; however, at least one cell may have the semiconductor layer including the crystals in the amorphous structure.

As illustrated in FIG. 7B, in order to form a plurality of photoelectric conversion cells over one substrate, openings C₀ to Cₙ are formed by laser processing to penetrate through the stack of the first unit cell 711 to the third unit cell 713 and the first electrode layer 704. The openings C₀, C₂, C₄, . . . Cₙ₋₂, and Cₙ are provided for insulation, by which a plurality of photoelectric conversion cells is separated for each element. The openings C₁, C₃, C₅, Cₙ₋₁ are provided for connection between the separated first electrode and second electrode which is later formed over the stack of the first unit cell 711 to the third unit cell 713. By the formation of the openings C₀ to Cₙ, the first electrode layer 704 is divided into first electrodes T₁ to Tₘ and the stack of the first unit cell 711 to the third unit cell 713 is divided into multifunction cells K₁ to Kₘ. There is no limitation on the kind of lasers used in the laser processing for forming the openings; however, a Nd-YAG laser, an excimer laser, or the like is preferably used. In any case, when the laser processing is performed on the stack of the first electrode layer 704 and the first unit cell 711 to the third unit cell 713, it is possible to prevent the first electrode layer 704 from separating from the substrate 702 during the processing.

As illustrated in FIG. 7C, insulating resin layers Z₀ to Zₘ are formed so as to fill the openings C₀, C₂, C₄ . . . Cₙ₋₂, and Cₙ and cover upper end portions of the openings C₀, C₂, C₄ . . . Cₙ₋₂, and Cₙ. The insulating resin layers Z₀ to Zₘ may be formed using a resin material having an insulating property such as an acrylic-based resin, a phenol-based resin, an epoxy-based resin, or a polyimide-based resin by a screen printing method. For example, an insulating resin pattern is formed by a screen printing method so that the openings C₀, C₂, C₄ . . . Cₙ₋₂, and Cₙ are filled with a resin composition in which cyclohexane, isophorone, high-resistance carbon black, aerosil, a dispersing agent, a defoaming agent, and a leveling agent are mixed with a phenoxy resin. After the insulating resin pattern is formed, the pattern is thermally hardened in an oven for 20 minutes at 160° C. to obtain the insulating resin layers Z₀ to Zₘ.

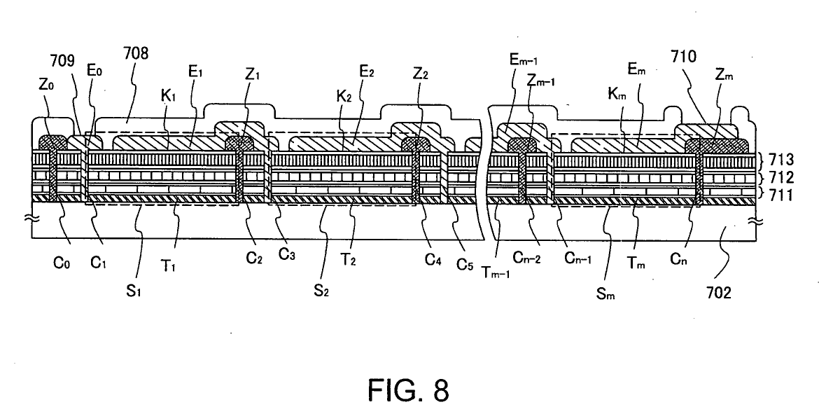

Next, second electrodes E₀ to Eₘ illustrated in FIG. 8 are formed. The second electrodes E₀ to Eₘ are formed from a conductive material. The second electrodes E₀ to Eₘ can be formed using a conductive layer of aluminum, silver, molybdenum, titanium, chromium, or the like by a sputtering method or a vacuum evaporation method or can be formed from a conductive material by a discharging method. In the case where the second electrodes E₀ to Eₘ, are formed using a conductive material by a discharging method, s predetermined pattern is directly formed by a screen printing method, an ink-jet method, a dispenser method, or the like. For example, the second electrodes E₀ to Eₘ can be formed from a conductive material including conductive particles of metal such as Ag, Au, Cu, W, or Al as the main component. In the case of manufacturing the photoelectric conversion device with a large-area substrate, the second electrodes E₀ to Eₘ preferably have lower resistance. A conductive material in which a metal particle of gold, silver, or copper, which has low resistivity, is dissolved or dispersed in a solvent is preferably used as a main material of the conductive composition. More preferably, silver or copper, which has low resistance, is used. In order to sufficiently fill the laser-processed openings C₁, C₃, C₅ . . . Cₙ₋₁ with the conductive material, nanopaste including conductive particles with an average diameter of 5 nm to 10 nm is preferably used.

Alternatively, the second electrodes E₀ to Eₘ may be formed by discharging a conductive material including a conductive particle whose periphery is covered with another conductive material. For example, a conductive particle of Cu whose periphery is covered with Ag, which has a buffer layer formed of Ni or NiB (nickel boron) between Cu and Ag, may be used. As the solvent, esters such as butyl acetate, alcohols such as isopropyl alcohol, an organic solvent such as acetone, or the like can be given. The surface tension and viscosity of the conductive material which is discharged are adjusted as appropriate by controlling the concentration of the solution and adding a surface active agent or the like.

The diameter of a nozzle used in an inkjet method is preferably set to be 0.02 μm to 100 μm (more preferably, 30 μm or less), and the amount of the conductive material to be discharged from the nozzle is preferably set to be 0.001 pl to 100 pl (more preferably, 10 pl or less). Although the ink-jet method has two types, an on-demand type and a continuous type, either type may be used. Further, as for a nozzle used in an ink-jet method, there are a piezoelectric type utilizing a property of a piezoelectric substance that the shape of the substance changes by voltage application and a heating type in which a material to be discharged (here the conductive material) is boiled by a heater provided in the nozzle and then discharged, and either of them may be used. It is preferable that the distance between an object to be processed and an outlet of the nozzle be as short as possible in order to drop a droplet on a desired place. The distance is preferably set to be approximately 0.1 mm to 3 mm (more preferably 1 mm or less). Either the nozzle or the object to be processed is moved while the distance therebetween is kept, so that a desired pattern can be drawn.

In addition, the step of discharging the conductive material may be performed under reduced pressure. This is because the discharge of the conductive material under reduced pressure makes the solvent in the conductive material vaporize before the discharged conductive material reaches the object to be processed, so that later steps of drying and baking can be eliminated or shortened. In addition, when a gas in which 10% to 30% of oxygen in a partial pressure ratio is mixed is used in a baking step of the composition containing the conductive material, the resistivity of the conductive layer which forms the second electrodes E₀ to Eₘ can be reduced and the conductive layer can be thinned and smoothened.

After the composition which forms the second electrodes E₀ to Eₘ, is discharged, either one of or both a drying step and a baking step are performed under an atmospheric pressure or a reduced pressure by laser irradiation, rapid thermal annealing (RTA), heating in a furnace, or the like. Both the drying and baking steps are heat treatment steps, and for example, the drying is performed at 100° C. for 3 minutes and the baking is performed at 200° C. to 350° C. for 15 to 120 minutes. Through this process, fusion and welding are accelerated by hardening and shrinking a peripheral resin, after the solvent in the composition is volatilized or the dispersant in the composition is chemically removed. The drying and baking are performed in an oxygen atmosphere or a nitrogen atmosphere, or in the air atmosphere. Note that an oxygen atmosphere is preferable because the solvent in which conductive particles are dissolved or dispersed is easily removed.

Nanopaste has conductive particles each having a diameter of 5 nm to 10 nm, typified by nanoparticles, dispersed or dissolved in an organic solvent, and dispersant and a thermal hardening resin which is referred to as a binder are also included. A binder has a function of preventing crack or uneven baking during the baking. By the drying or baking step, vaporization of the organic solvent, decomposition removal of the dispersant, and the hardening and shrinking by the binder concurrently proceed; accordingly, the nanoparticles are fused and/or welded to each other to be hardened. Through the drying or baking step, the nanoparticle is grown to a size of several tens of nanometers to a hundred and several tens of nanometers. Adjacent growing nanoparticles are fused and/or welded to each other to be linked, thereby forming a metal hormogone. On the other hand, most of the remaining organic constituents (about 80% to 90%) are pushed out of the metal hormogone; consequently, a conductive layer containing the metal hormogone and a film including an organic constituent that covers an outer side thereof are formed. The film including an organic constituent can be removed in baking the nanopaste in an atmosphere containing nitrogen and oxygen by reaction of oxygen contained in the atmospheric air and carbon, hydrogen, or the like contained in the film including an organic constituent. In addition, in a case where oxygen is not contained in the baking atmosphere, the film including an organic constituent can be removed by separately performing oxygen plasma treatment or the like. Specifically, the film including an organic constituent is removed by performing oxygen plasma treatment on the nanopaste in an atmosphere including nitrogen and oxygen after the drying or baking. As a result, the remaining conductive layer including the metal hormogone can be smoothened, thinned, and made low resistant. Note that, since the solvent in the composition is volatilized by discharging the composition containing a conductive material under reduced pressure, time of subsequent heat treatment (drying or baking) can be shortened.

The second electrodes E₀ to Eₘ are in contact with the sixth impurity semiconductor layer 31n of the third unit cell 713, which is the uppermost layer of the multifunction cells K₁ to Kₘ. The contact resistance between the second electrodes E₀ to Eₘ and the sixth impurity semiconductor layer 31n can be decreased when the contact therebetween is ohmic contact. The contact resistance can be further decreased when the sixth impurity semiconductor layer 31n is formed from a microcrystalline semiconductor to a thickness of 30 nm to 80 nm.

The second electrodes E₀ to Eₘ₋₁ are connected to the first electrodes T₁ to Tₘ through the openings C₁, C₃, C₅ . . . Cₙ₋₁, respectively. That is, the openings C₁, C₃, C₅ . . . Cₙ₋₁ are filled with the same material as that of the second electrodes E₀ to Eₘ. In such a manner, for example, the second electrode E₁ can be electrically connected to the first electrode T₂ and the second electrode Eₘ₋₁ can be electrically connected to the first electrode Tₘ. In other words, each of the second electrodes can be electrically connected to the first electrode adjacent to the corresponding second electrode, and the multijunction cells K₁ to Kₘ are electrically connected in series.

A sealing resin layer 708 is formed from an epoxy resin, an acrylic resin, or a silicone resin. The sealing resin layer 708 is provided with openings 709 and 710 over the second electrode E₀ and the second electrode Eₘ, respectively, so that connection with external wirings at the openings 709 and 710 can be achieved.

In this manner, a photoelectric conversion cell S₁ including the first electrode T₁, the multijunction cell K₁, and the second electrode E₁ . . . a photoelectric conversion cell Sₘ including the first electrode Tₘ, the multijunction cell Kₘ, and the second electrode Eₘ are formed over the substrate 702. The first electrode Tₘ is connected to the adjacent second electrode Eₘ₋₁ at the opening Cₙ₋₁ and m number of photoelectric conversion cells are electrically connected to each other in series in the completed photoelectric conversion device. Note that the second electrode E₀ serves as an extraction electrode of the first electrode T₁ in the photoelectric conversion cell S₁.

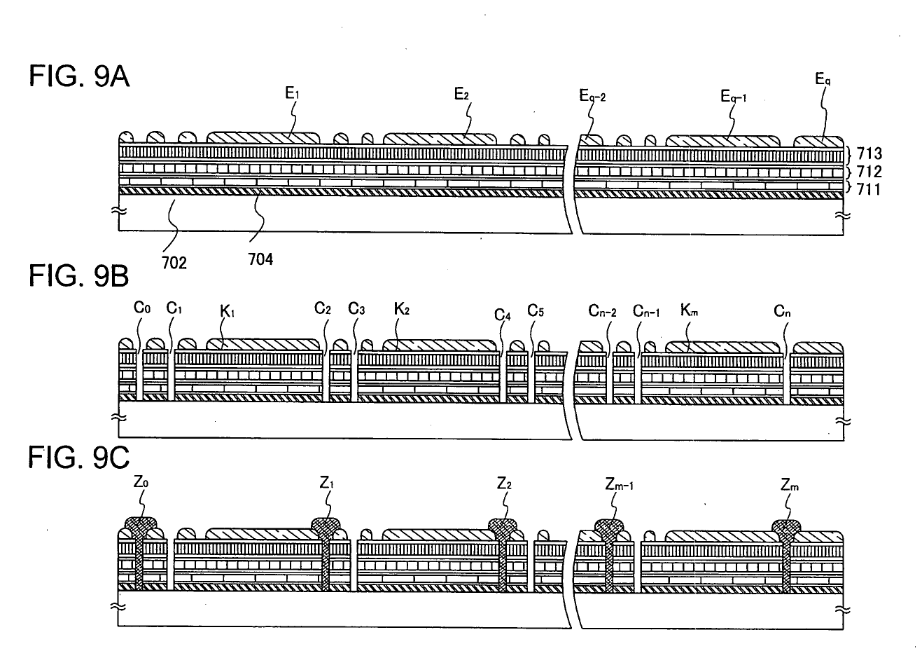

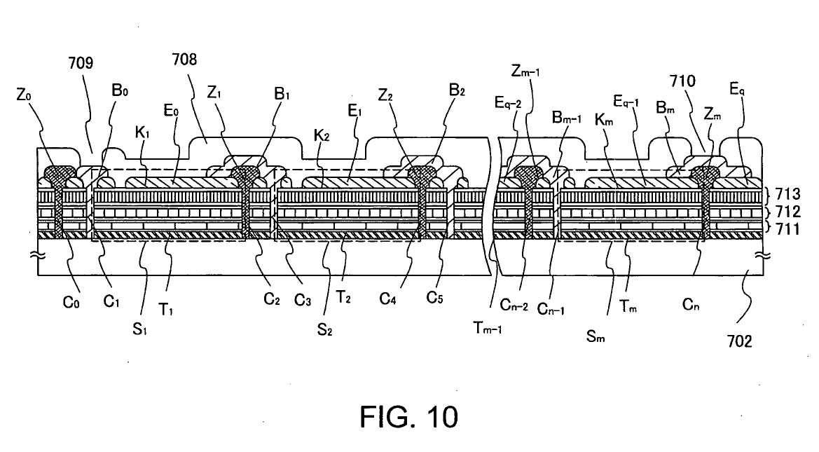

FIGS. 9A to 9C and FIG. 10 illustrate another embodiment of the photoelectric conversion device of Embodiment 4. In FIG. 9A, the substrate 702, the first electrode layer 704, and the first unit cell 711 to the third unit cell 713 are fabricated in a manner similar to the above. Then, second electrodes E₁ to E_{q} are formed by a printing method over the first unit cell 711 to the third unit cell 713.

As illustrated in FIG. 9B, openings C₀ to Cₙ are formed through the first unit cell 711 to the third unit cell 713 and the first electrode layer 704 by a laser processing method. The openings C₀, C₂, C₄ . . . Cₙ₋₂, and Cₙ are provided for insulation in forming photoelectric conversion cells, whereas the openings C₁, C₃, C₅ . . . Cₙ₋₁ are provided for connection between the first electrodes T₁ to Tₘ and the second electrodes E₁ to E_{q} which have the first unit cell 711 to the third unit cell 713 interposed therebetween. By the openings C₀ to Cₘ, the first electrode layer 704 is divided into the first electrodes T₁ to Tₘ and the first unit cell 711 to the third unit cell 713 are divided into the multijunction cells K₁ to Kₘ. After the laser processing, a residue remains at the periphery of the opening, in some cases. This residue is formed by a spray of a material subjected to processing and is actually undesirable because when the spray heated up to high temperatures by a laser beam touches the surfaces of the first unit cell 711 to the third unit cell 713, the film is damaged. In order to prevent the spray from touching the surfaces etc., the second electrodes are formed in accordance with patterns of the openings and then the laser processing is performed; accordingly, damage at least to the stack of the first unit cell 711 to the third unit cell 713 can be prevented.

As illustrated in FIG. 9C, insulating resin layers Z₀ to Zₘ which fill the openings C₀, C₂, C₄ . . . Cₙ₋₂, and Cₙ and which cover upper end portions of the openings C₀, C₂, C₄ . Cₙ₋₂, and Cₙ are formed by a printing method, for example, a screen printing method.

Next, as illustrated in FIG. 10, wirings B₀ to Bₘ which fill the openings C₁, C₃, C₅ . . . Cₙ₋₁, and which are connected to the first electrodes T₁ to Tₘ are formed by a screen printing method. The wirings B₀ to Bₘ are formed from the same material as the second electrodes, and a thermosetting carbon paste is used here. Note that the wiring Bₘ is formed over the insulating resin layer Zₘ and serves as an extraction wiring. In such a manner, for example, the second electrode E₁ can be electrically connected to the first electrode T₂ and the second electrode E_{q-1}, can be electrically connected to the first electrode Tₘ. In other words, the second electrode can be electrically connected to the adjacent first electrode, so that the multijunction cells K₁ to Kₘ can be electrically connected to each other in series.

Lastly, the sealing resin layer 708 is formed by a printing method. In the sealing resin layer 708, the openings 709 and 710 are formed over the wirings B₀ and Bₘ, respectively, and the wirings are connected to an external circuit at these openings. In this manner, a photoelectric conversion cell S₁ including the first electrode T₁, the multifunction cell K₁, and the second electrode E₁, . . . , and a photoelectric conversion cell Sₘ including the first electrode Tₘ, the multifunction cell Kₘ, and the second electrode E_{q-1} are formed over the substrate 702. The first electrode Tₘ is connected to the adjacent second electrode E_{q-2} at the opening Cₙ₋₁ and m number of photoelectric conversion cells are electrically connected to each other in series in the completed photoelectric conversion device. Note that the wiring B₀ serves as an extraction electrode of the first electrode T₁ in the photoelectric conversion cell S₁.

The integrated photoelectric conversion device according to an embodiment of the present invention includes the semiconductor layer including in an amorphous structure, crystals penetrating in the deposition direction of the semiconductor layer. This semiconductor layer serves as the main layer which performs photoelectric conversion. Therefore, variation in characteristics due to photodegradation can be suppressed to improve the photoelectric conversion characteristic. Further, the main layer which performs photoelectric conversion is formed using an amorphous structure, the light absorption coefficient can be maintained and the thickness of the layer can be set to be the same or substantially the same as that of a photoelectric conversion layer of a photoelectric conversion device including an amorphous silicon thin film; therefore, the productivity can also be improved.

A stacked (a multijunction type such as a tandem type or a stacked type) photoelectric conversion device can be completed in which a plurality of unit cells is stacked so that the proportion of the crystals or the thickness of the photoelectric conversion layer increases from the light incidence side. In this photoelectric conversion device, light in a short wavelength range is easily absorbed on the side closer to the light incidence side and light in a long wavelength range is easily absorbed on the side far from the light incidence side. Accordingly, light in a wide wavelength range can be absorbed effectively to achieve high efficiency.

### Embodiment 5

Embodiment 5 describes an example of a photosensor device as another embodiment of the photoelectric conversion device.

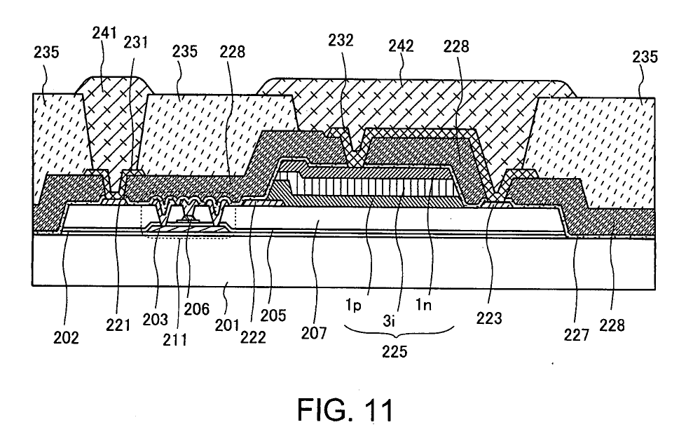

FIG. 11 illustrates an example of the photosensor device of Embodiment 5. The photosensor device illustrated in FIG. 11 has a photoelectric conversion layer 225 in a light-receiving portion and is provided with a function in which an output from the photoelectric conversion layer 225 is amplified by an amplifier circuit including a thin film transistor 211 and then outputted. The photoelectric conversion layer 225 and the thin film transistor 211 are provided over a substrate 201. As the substrate 201, a light-transmitting substrate, for example, any of a glass substrate, a quartz substrate, a ceramic substrate, or the like can be used.

An insulating layer 202 is formed using a single layer or plural layers selected from silicon oxide, silicon nitride oxide, silicon nitride, and silicon oxynitirde over the substrate 201 by a sputtering method or a plasma CVD method. The insulating layer 202 is provided for relieving film stress and preventing impurity contamination. A crystalline semiconductor layer 203 of the thin film transistor 211 is provided over the insulating layer 202. A gate insulating layer 205 and a gate electrode 206 are provided over the crystalline semiconductor layer 203 of the thin film transistor 211.

An interlayer insulating layer 207 is provided over the thin film transistor 211. The interlayer insulating layer 207 may be a single insulating layer or a stack of insulating layers of different materials. A wiring electrically connected to a source region and a drain region of the thin film transistor 211 is formed over the interlayer insulating layer 207. In addition, over the interlayer insulating layer 207, an electrode 221, an electrode 222, and an electrode 223, each of which is formed using the same material and the same steps with those of the wiring, are formed. The electrodes 221 to 223 are formed using a metal film, e.g., a low resistance metal film. Such a low resistance metal film can be formed using an aluminum alloy, pure aluminum, or the like. Alternatively, the electrodes 221 to 223 may have a stacked structure of such a low resistance metal film and a refractory metal film; for example, a three-layer structure of a titanium layer, an aluminum layer, and a titanium layer which are stacked in that order may be employed. Instead of the stacked structure of the refractory metal film and the low resistance metal film, a single conductive layer can be used. Such a single conductive layer may be formed using an element selected from titanium, tungsten, tantalum, molybdenum, neodymium, cobalt, zirconium, zinc, ruthenium, rhodium, palladium, osmium, iridium, or platinum; a single film using an alloy material or a compound material containing the aforementioned element as its main component; or a single film using nitride of the aforementioned element, e.g., titanium nitride, tungsten nitride, tantalum nitride, or molybdenum nitride.

The interlayer insulating layer 207, the gate insulating layer 205, and the insulating layer 202 are etched so as to have tapered end portions. With the interlayer insulating layer 207, the gate insulating layer 205, and the insulating layer 202 processed to have the tapered end portions, coverage with a protective layer 227 formed over these insulating layers is improved and an effect that moisture, impurities, and the like hardly intrude is obtained.

The photoelectric conversion layer 225 is formed over the interlayer insulating layer 207. As the photoelectric conversion layer 225, the stack of the impurity semiconductor layer 1p, the semiconductor layer 3i, and the impurity semiconductor layer 1n which are illustrated in FIG. 1 can be used. Note that the impurity semiconductor layer 1p is provided so that at least a part thereof is in contact with the electrode 222. The impurity semiconductor layer 1p is formed from a microcrystalline semiconductor and the semiconductor layer 3i including crystals in an amorphous structure is formed over the impurity semiconductor layer 1p. The impurity semiconductor layer 1n is formed over the semiconductor layer 3i.

The semiconductor layer 3i is formed using a semiconductor source gas (typically silane) and a dilution gas (typically hydrogen) with the flow rate of the dilution gas to the semiconductor source gas being greater than or equal to 1 time and less than 10 times, preferably greater than or equal to 1 time and less than or equal to 6 times. Through this step, the crystals grow from the interface between the semiconductor layer 3i and the impurity semiconductor layer 1p in the deposition direction of the semiconductor layer to reach the impurity semiconductor layer 1n which is to be formed over the semiconductor layer 3i. The crystals which are grown in this manner can serve as a carrier path to improve a photocurrent characteristic.

The protective layer 227 is formed from, for example, silicon nitride over the photoelectric conversion layer 225. The protective layer 227 can prevent moisture and impurities such as organic substances from being mixed into the thin film transistor 211 and the photoelectric conversion layer 225. An interlayer insulating layer 228 formed using an organic resin material such as polyimide or acrylic is provided over the protective layer 227. An electrode 231 and an electrode 232 are provided over the interlayer insulating layer 228. The electrode 231 is electrically connected to the electrode 221. The electrode 232 is electrically connected to an upper layer of the photoelectric conversion layer 225 (the impurity semiconductor layer 1n) and the electrode 223 through contact holes in the interlayer insulating layer 228 and the protective layer 227. For the electrodes 231 and 232, tungsten, titanium, tantalum, silver, or the like can be used.

An interlayer insulating layer 235 is provided over the interlayer insulating layer 228 by a screen printing method or an ink-jet method, using an organic resin material such as an epoxy resin, polyimide, acrylic, or a phenol resin. The interlayer insulating layer 235 is provided with openings over the electrode 231 and the electrode 232. Over the interlayer insulating layer 235, an electrode 241 that is electrically connected to the electrode 231 and an electrode 242 that is electrically connected to the electrode 232 are provided by a printing method, for example, using a nickel paste.

In the photoelectric conversion device functioning as the photosensor device illustrated in FIG. 11, the layer forming a main part of the photoelectric conversion layer has a structure in which crystals penetrating in the deposition direction of the layer exist in an amorphous structure. Therefore, the photoelectric conversion characteristic of this photoelectric conversion device is superior to that of a conventional photoelectric conversion device including an amorphous silicon thin film, when the both devices have the photoelectric conversion layers with the same or substantially the same thickness. FIG. 11 illustrates the photosensor device in which the photoelectric conversion layer 225 is provided in the light-receiving portion and an output of the photoelectric conversion layer 225 is amplified by the amplifier circuit including the thin film transistor 211 and then outputted. However, if the structure according to the amplifier circuit is eliminated, the device can be used as a photosensor.

### Embodiment 6

Another embodiment of the present invention is a photoelectric conversion device provided with a cell including a single crystal semiconductor layer as a layer that performs photoelectric conversion and a cell including as a layer which performs photoelectric conversion, a semiconductor layer which includes crystals successively penetrating in a deposition direction in an amorphous structure. Embodiment 6 describes an example of a tandem photoelectric conversion device in which a cell including a single crystal semiconductor layer and a cell including a semiconductor layer including crystals penetrating in the deposition direction are stacked.

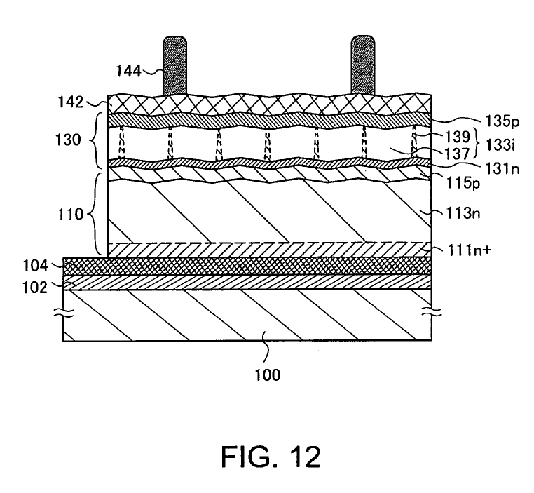

In the photoelectric conversion device illustrated in FIG. 12, a first unit cell 110, a second unit cell 130, and a second electrode 142 are arranged in that order from a substrate 100 side. The substrate 100 is provided with a first electrode 104. The first unit cell 110 and the second unit cell 130 are interposed between a pair of electrodes: the first electrode 104 and the second electrode 142. An auxiliary electrode 144 is provided over the second electrode 142. In this example, the second electrode 142 side is a light incidence plane.

The first unit cell 110 has a stacked structure of a single crystal semiconductor layer 113n including a first impurity semiconductor layer 111n⁺ having one conductivity type, and a second impurity semiconductor layer 115p having a conductivity type opposite to the one conductivity type. The thickness of the single crystal semiconductor layer 113n of the first unit cell 110 is set at greater than or equal to 1 μm and less than or equal to 10 μm, preferably greater than or equal to 2 μm and less than or equal to 8 μm.

The single crystal semiconductor layer 113n is a single crystal semiconductor layer obtained by slicing a single crystal semiconductor substrate. Typically, a single crystal silicon substrate is sliced into a single crystal silicon layer which serves as the single crystal semiconductor layer 113n. Alternatively, a polycrystalline semiconductor substrate (typically, a polycrystalline silicon substrate) can be used instead of a single crystal semiconductor substrate. In the latter case, a polycrystalline semiconductor layer (typically, a polycrystalline silicon layer) is formed as the single crystal semiconductor layer 113n.

Since a single crystal semiconductor typified by single crystal silicon has no crystal grain boundaries, the conversion efficiency thereof is higher than that of a polycrystalline, microcrystalline, or amorphous semiconductor. Therefore, an excellent photoelectric conversion characteristic can be obtained.

The second unit cell 130 has a stacked structure of a third impurity semiconductor layer 131n having one conductivity type, a non-single-crystal semiconductor layer 133i including crystals 139 in an amorphous structure 137, and a fourth impurity semiconductor layer 135p having a conductivity type opposite to the one conductivity type. The thickness of the non-single-crystal semiconductor layer 133i in the second unit cell 130 is set at greater than or equal to 0.1 μm and less than or equal to 0.5 μm, preferably greater than or equal to 0.2 μm and less than or equal to 0.3 μm.

The second impurity semiconductor layer 115p having one conductivity type and the third impurity semiconductor layer 131n having a conductivity type opposite to the one conductivity type are in contact with each other at a junction portion between the first unit cell 110 and the second unit cell 130, whereby a pn junction is formed.

In the non-single-crystal semiconductor layer 133i, the crystals 139 are provided discretely in the amorphous structure 137. The crystals 139 are grown so as to successively penetrate between the pair of impurity semiconductor layers bonded for forming an internal electric field, specifically grown in the deposition direction of the non-single-crystal semiconductor layer 133i from the third impurity semiconductor layer 131n to reach the fourth impurity semiconductor layer 135p. The crystals 139 each preferably have a needle-like shape. The needle-like shape refers to a shape similar to those described in Embodiment 1.

The crystals 139 include a crystalline semiconductor such as a microcrystalline semiconductor, a polycrystalline semiconductor, or a single crystal semiconductor, typically includes crystalline silicon. The amorphous structure 137 includes an amorphous semiconductor, typically amorphous silicon. An amorphous semiconductor typified by amorphous silicon is of direct transition type and has a high light absorption coefficient. Therefore, in the non-single-crystal semiconductor layer 133i where the crystals 139 exist in the amorphous structure 137, photogenerated carriers are easily produced in the amorphous structure 137 rather than in the crystals 139. Moreover, while the amorphous structure including amorphous silicon has a band gap of 1.6 eV to 1.8 eV, a crystal including crystalline silicon has a band gap of about 1.1 eV to 1.4 eV Because of the relationship between these, the photogenerated carriers produced in the non-single-crystal semiconductor layer 133i including the crystals 139 in the amorphous structure 137 diffuse or drift to move to the crystals 139. The crystals 139 serve as a carrier path for the photogenerated carriers. In such a structure, the photogenerated carriers flow more easily through the crystals 139 even though a light-induced defect is formed. Therefore, the photogenerated carriers are less likely to be trapped in the defect level of the non-single-crystal semiconductor layer 133i. The crystals 139 are formed so as to penetrate between the third impurity semiconductor layer 131p and the fourth impurity semiconductor layer 135p, whereby electrons and holes, both of which are photogenerated carriers, easily flow because they are less likely to be trapped in the defect level. In view of the above, variation in characteristics due to photodegradation which have been a problem can be reduced.

With the use of the non-single-crystal semiconductor layer 133i in which the crystals 139 exist in the amorphous structure 137, the layer can have regions divided for functions: for example, a region where photoelectric conversion is mainly performed by producing photogenerated carriers and a region which mainly serve as a carrier path for the produced photogenerated carriers. In an amorphous or microcrystalline semiconductor layer for forming a conventional photoelectric conversion layer, photoelectric conversion and a carrier path are both achieved without being separated from each other and when one function is put in priority to the other function, the other is degraded in some cases. However, by the use of regions divided for functions as above, the both functions can be improved and the photoelectric conversion characteristic can be improved.

Owing to the amorphous structure 137 in which the non-single-crystal semiconductor layer 133i includes the crystals 139 in the amorphous structure 137, the light absorption coefficient can be maintained. Accordingly, the thickness of the photoelectric conversion layer including the non-single-crystal semiconductor layer 133i can be the same or substantially the same as the photoelectric conversion layer including an amorphous silicon thin film and the productivity can be improved as compared with a photoelectric conversion device including a microcrystalline silicon thin film.

For the single crystal semiconductor layer 113n of the first unit cell 110, typically single crystal silicon with a band gap of 1.1 eV is used. The non-single-crystal semiconductor layer 133i of the second unit cell 130 includes the crystals (typically, crystalline silicon) in the amorphous structure (typically, amorphous silicon). While the amorphous structure (typically, amorphous silicon) has a band gap of 1.6 eV to 1.8 eV, a crystal (typically, crystalline silicon) has a band gap of about 1.1 eV to 1.4 eV The second unit cell 130 has a region where the band gap is larger than that of the single crystal semiconductor layer 113n. Therefore, power can be generated from light in a long wavelength range by the first unit cell 110 and light in a short wavelength range by the second unit cell 130. Solar light has a wide wavelength range; therefore, power can be effectively generated using the structure according to an embodiment of the present invention. That is to say, an excellent photoelectric conversion characteristic can be achieved with the top cell having the structure in which variation in characteristics due to photodegradation or the like is prevented and the bottom cell including the single crystal semiconductor layer. Moreover, the unit cells having a sensitivity at different wavelength ranges are stacked and the unit cell which is sensitive to light in a short wavelength range is provided on the light incidence side; therefore, the power generation efficiency can be improved.

Out of the first impurity semiconductor layer 111n⁺ having one conductivity type and the second impurity semiconductor layer 115p having a conductivity type opposite to the one conductivity type in the first unit cell 110, one serves as an n-type semiconductor layer and the other serves as a p-type semiconductor layer. The single crystal semiconductor layer 113n is formed from an n-type semiconductor, a p-type semiconductor, a stack of an n-type semiconductor and an i-type semiconductor, a stack of a p-type semiconductor and an i-type semiconductor, or the like. In Embodiment 6, the single crystal semiconductor layer 113n including the first impurity semiconductor layer 111n⁺ is formed from an n-type semiconductor, and the second impurity semiconductor layer 115p is formed from a p-type semiconductor, whereby a pn junction is formed. Out of the third impurity semiconductor layer 131n having one conductivity type and the fourth impurity semiconductor layer 135p having a conductivity type opposite to the one conductivity type in the second unit cell 130, one serves as an n-type semiconductor layer and the other serves as a p-type semiconductor layer. The amorphous structure of the non-single-crystal semiconductor layer 133i is an i-type semiconductor. In Embodiment 6, the third impurity semiconductor layer 131n is formed from an n-type semiconductor and the fourth impurity semiconductor layer 135p is formed from a p-type semiconductor, whereby a pn junction is formed.

In the first unit cell 110 and the second unit cell 130, a recombination center is formed at the junction interface between the second impurity semiconductor layer 115p having p-type conductivity and the third impurity semiconductor layer 131n having n-type conductivity, and recombination current flows.

In the first unit cell 110, the single crystal semiconductor layer 113n is formed by slicing a single crystal semiconductor substrate to separate a superficial portion thereof and being fixed onto a supporting substrate and the second impurity semiconductor layer 115p is formed over the single crystal semiconductor layer 113n. The first impurity semiconductor layer 111n⁺ is formed over a surface of the single crystal semiconductor layer 113n which is opposite the surface thereof provided with the second impurity semiconductor layer 115p.

For the single crystal semiconductor layer 113n, single crystal silicon is typically used. In this case, a single crystal silicon layer is used as the single crystal semiconductor layer 113n. For example, the single crystal semiconductor layer 113n can be formed by irradiating a single crystal semiconductor substrate with ions accelerated by voltage by an ion implantation method or an ion doping method and by performing thermal treatment thereon so that a part of the single crystal semiconductor substrate is divided. Alternatively, a single crystal semiconductor substrate may be irradiated with a laser beam that causes multiphoton absorption so that a part of a single crystal semiconductor substrate is divided.

In this specification, ion implantation refers to a method in which ions produced from a source gas are mass-separated and delivered to an object, so that an element of the ion is added to the object. Further, ion doping refers to a method in which ions produced from a source gas are delivered to an object without mass separation, so that an element of the ion is added to the object.

The first impurity semiconductor layer 111n⁺ is a semiconductor layer including an impurity element imparting one conductivity type, and is formed by introducing the impurity element imparting one conductivity type to the single crystal semiconductor layer 113n or to the single crystal semiconductor substrate before being sliced. As the impurity element imparting one conductivity type, an impurity element imparting n-type conductivity or an impurity element imparting p-type conductivity is used. As the impurity element imparting n-type conductivity, phosphorus, arsenic, antimony, and the like, which are Group 15 elements in the periodic table, are typically given. As the impurity element imparting p-type conductivity, boron, aluminum, and the like, which are Group 13 elements in the periodic table, are typically given. In Embodiment 6, phosphorus, which is an impurity element imparting n-type conductivity, is introduced to form the first impurity semiconductor layer 111n⁺ having n-type conductivity.

The second impurity semiconductor layer 115p formed over the single crystal semiconductor layer 113n is a semiconductor layer including an impurity element imparting a conductivity type opposite to that of the first impurity semiconductor layer 111n⁺. The second impurity semiconductor layer 115p is formed by a CVD method or the like using a microcrystalline or amorphous semiconductor layer including an impurity element imparting one conductivity type. Alternatively, the second impurity semiconductor layer 115p is formed by introducing an impurity element imparting one conductivity type to a surface of the single crystal semiconductor layer 113n, which is opposite to the surface thereof provided with the first impurity semiconductor layer 111n⁺.

In the second unit cell 130, the non-single-crystal semiconductor layer 133i including the crystals 139 in the amorphous structure 137 is formed over the third impurity semiconductor layer 131n formed from a microcrystalline semiconductor and the fourth impurity semiconductor layer 135p is formed over the non-single-crystal semiconductor layer 133i.

The non-single-crystal semiconductor layer 133i is formed with use of plasma, typically glow discharge plasma, generated by introducing a semiconductor source gas and a dilution gas into a reaction space while a predetermined pressure is kept. The flow rate of the dilution gas to the semiconductor source gas is greater than or equal to 1 time and less than 10 times, preferably greater than or equal to 1 time and less than or equal to 6 times. Accordingly, a film (the non-single-crystal semiconductor layer 133i) is formed over the object to be processed (the third impurity semiconductor layer 131n) placed in the reaction space. By the control of the dilution rate of the semiconductor source gas and the control of the crystal structure of the lower layer (the third impurity semiconductor layer 131n), the third impurity semiconductor layer 131n serves as seed crystals so that crystal growth proceeds in the deposition direction of the semiconductor layer. Thus, the non-single-crystal semiconductor layer 133i can be formed in which the crystals 139 are grown from the third impurity semiconductor layer 131n in the amorphous structure 137. In an embodiment of the present invention, since the crystals 139 are grown so as to penetrate through the non-single-crystal semiconductor layer 133i, complicated adjustment of the flow rate between the semiconductor source gas and the dilution gas is not necessary from the initial stage to the completion of the film formation; thus, the fabrication is easy. The non-single-crystal semiconductor layer 133i is formed under the condition similar to that of an amorphous semiconductor film; therefore, the deposition rate is not extremely decreased so that the productivity is not largely decreased. Needless to say, the deposition rate is higher than that in the case of forming a normal microcrystalline semiconductor layer; therefore, the productivity is improved.

The non-single-crystal semiconductor layer 133i can be formed in a plasma CVD apparatus using a reaction gas in which a semiconductor source gas is diluted with a dilution gas. As the semiconductor source gas, silicon hydride typified by silane or disilane can be used. Note that instead of silicon hydride, silicon chloride such as SiH₂Cl₂, SiHCl₃, or SiCl₄, or silicon fluoride such as SiF₄ can be used. The dilution gas is typified by hydrogen. For example, silicon hydride is diluted with hydrogen and one or more rare gas elements selected from helium, argon, krypton, and neon, with which the non-single-crystal semiconductor layer 133i can be formed. The flow rate of the dilution gas (for example, hydrogen) to the semiconductor source gas (for example, silane) is greater than or equal to 1 time and less than 10 times, preferably greater than or equal to 1 time and less than or equal to 6 times.

The non-single-crystal semiconductor layer 133i is formed from an i-type semiconductor. The i-type semiconductor is as described in Embodiment 1.

The third impurity semiconductor layer 131n below the non-single-crystal semiconductor layer 133i is a semiconductor layer including an impurity element imparting one conductivity type, and is formed from a microcrystalline semiconductor, specifically, microcrystalline silicon, microcrystalline germanium, microcrystalline silicon carbide, or the like. The third impurity semiconductor layer 131n has a conductivity type opposite to that of the second impurity semiconductor layer 115p of the first unit cell 110. In Embodiment 6, the third impurity semiconductor layer 131n is formed from microcrystalline silicon including phosphorus, which is an impurity element imparting n-type conductivity. Note that the microcrystalline semiconductor in Embodiment 6 is formed as described in Embodiment 1.

The fourth impurity semiconductor layer 135p formed over the non-single-crystal semiconductor layer 133i is a semiconductor layer including an impurity element imparting a conductivity type opposite to that of the third impurity semiconductor layer 131n, and is formed from a microcrystalline semiconductor (for example, microcrystalline silicon, microcrystalline germanium, microcrystalline silicon carbide, or the like) or an amorphous semiconductor (such as amorphous silicon, amorphous germanium, or amorphous silicon carbide). In Embodiment 6, the fourth impurity semiconductor layer 135p is formed from microcrystalline silicon including boron, which is an impurity element imparting p-type conductivity.

In this manner, the first unit cell 110 including the single crystal semiconductor layer 113n and the second unit cell 130 having the non-single-crystal semiconductor layer 133i in which the crystals penetrating between the pair of impurity semiconductor layers are included in the amorphous structure can be provided.

The first electrode 104 is provided over the substrate 100. An insulating layer 102 is provided between the substrate 100 and the first electrode 104. The second electrode 142 is provided over the uppermost unit cell, here, over the fourth impurity semiconductor layer 135p of the second unit cell 130. The auxiliary electrode 144 is provided over the second electrode 142. Note that the second electrode 142 side is the light incidence plane in Embodiment 6. Therefore, the auxiliary electrode 144 has a comb-like shape, a pectinate shape, or a grating shape when seen from above.

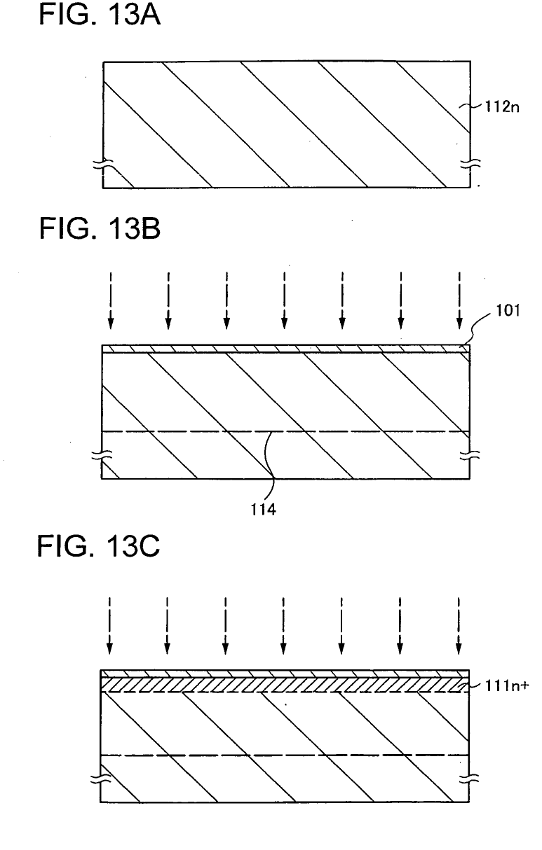

Next, a method for manufacturing the photoelectric conversion device illustrated in FIG. 12 is described with reference to FIGS. 13A to 13C, FIGS. 14A to 14C, FIGS. 15A to 15C, and FIGS. 16A and 16B. In the method for manufacturing the photoelectric conversion device according to an embodiment of the present invention, a single crystal semiconductor substrate may be sliced by a means which can provide a single crystal semiconductor layer with desired thickness. Embodiment 6 employs a means by which a fragile layer, which is a locally-weakened region, is formed at a predetermined depth in a single crystal semiconductor substrate and the single crystal semiconductor substrate is sliced by dividing the substrate at the fragile layer.

A single crystal semiconductor substrate 112n is prepared (see FIG. 13A).

As the single crystal semiconductor substrate 112n, a single crystal silicon substrate is typically employed. Alternatively, a known single crystal semiconductor substrate can be used; for example, a single crystal germanium substrate, a single crystal silicon-germanium substrate, or the like can be used. As an alternative to the single crystal semiconductor substrate 112n, a polycrystalline semiconductor substrate can be used; typically, a polycrystalline silicon substrate can be used. Therefore, in the case of using a polycrystalline semiconductor substrate instead of the single crystal semiconductor substrate, the single crystal semiconductor in the description below can be replaced by a polycrystalline semiconductor.

The single crystal semiconductor substrate 112n may have a size (an area, a planar shape, thickness, and the like) corresponding to the specifics of an apparatus and the like used in steps of manufacturing the photoelectric conversion device. For example, as for the shape of the single crystal semiconductor substrate 112n, a widely distributed circular substrate or a substrate processed into a desired shape can be used. The thickness of the single crystal semiconductor substrate 112n may be based on the SEMI specification which is recognized in general or may be adjusted as appropriate when being cut out from an ingot. When the single crystal semiconductor substrate is cut out from an ingot so as to have large thickness, a cutting margin, that is, a waste of a raw material can be reduced.

The single crystal semiconductor substrate 112n preferably has a large area. As for single crystal silicon substrates, large substrates with a diameter of 100 mm (4 inches), a diameter of 150 mm (6 inches), a diameter of 200 mm (8 inches), a diameter of 300 mm (12 inches), and the like are widely distributed. In recent years, a large substrate with a diameter of 400 mm (16 inches) has appeared in the market. For the future, substrates of 16 inches or more are expected and a substrate with a diameter of 450 mm (18 inches) is anticipated as a next-generation substrate. As the single crystal semiconductor substrate 112n, a substrate with a diameter of greater than or equal to 300 mm is preferably used; for example, a substrate with a diameter of 400 mm or 450 mm is preferably used. By the increase in diameter or area of the single crystal semiconductor substrate 112n, the productivity can be improved. Further, the area of a space (a region that does not generate power) which is formed due to the arrangement of a plurality of unit cells in the fabrication of a photovoltaic module can be decreased.

In Embodiment 6, an n-type single crystal silicon substrate is used as the single crystal semiconductor substrate 112n.

A fragile layer 114 is formed in a region at a predetermined depth from one surface of the single crystal semiconductor substrate 112n (see FIG. 13B).

At or near the fragile layer 114, the single crystal semiconductor substrate 112n is divided into a single crystal semiconductor layer and a single crystal semiconductor substrate in a later-described dividing step. The depth at which the fragile layer 114 is formed depends on the thickness of the single crystal semiconductor layer which is later obtained by the division.

For example, the fragile layer 114 can be formed by an ion implantation method or an ion doping method, that is, a method in which irradiation with ions (typified by hydrogen ions) accelerated by voltage is performed, or a method which utilizes multiphoton absorption.

In the example illustrated in FIG. 13B, one surface of the single crystal semiconductor substrate 112n is irradiated with ions accelerated by voltage to form the fragile layer 114 in a region at a predetermined depth of the single crystal semiconductor substrate 112n. The fragile layer 114 is formed in such a manner that the crystalline structure of a local region in the single crystal semiconductor substrate 112n is distorted to weaken the region by irradiating the single crystal semiconductor substrate 112n with ions (typically hydrogen ions) accelerated by voltage so that the ions or an element of the ions (hydrogen in the case of using hydrogen ions) is introduced into the single crystal semiconductor substrate 112n.

Note that the fragile layer 114 can be formed using an ion implantation apparatus in which mass separation is performed or an ion doping apparatus in which mass separation is not performed.

The depth at which the fragile layer 114 is formed in the single crystal semiconductor substrate 112n (here, the depth from the irradiated surface of the single crystal semiconductor substrate 112n to the fragile layer 114 in the film thickness direction) is determined by the control of the voltage for accelerating irradiation ions and/or the tilt angle (the tilt angle of the substrate). Therefore, in consideration of the desired thickness of the single crystal semiconductor layer after the slice, the voltage for accelerating the irradiation ions and/or the tilt angle is determined.

As the irradiation ions, the use of hydrogen ions generated from a source gas including hydrogen is preferable. When the single crystal semiconductor substrate 112n is irradiated with hydrogen ions, hydrogen is introduced thereto, so that the fragile layer 114 is formed in a region at a predetermined depth of the single crystal semiconductor substrate 112n. For example, hydrogen plasma is generated from a source gas including hydrogen and the ions generated in the hydrogen plasma are accelerated and delivered; thus, the fragile layer 114 can be formed. Instead of hydrogen or in addition to hydrogen, ions generated from a source gas including a rare gas typified by helium may be used to form the fragile layer 114. Note that the irradiation with particular ions is preferable because the region at the same depth in the single crystal semiconductor substrate 112n is weakened in a concentrated manner.

For example, the single crystal semiconductor substrate 112n is irradiated with ions generated from hydrogen, so that the fragile layer 114 is formed. By adjusting the acceleration voltage, the tilt angle, and the dosage of the irradiation ions, the fragile layer 114, which is the region doped with hydrogen at high concentration, can be formed at a predetermined depth of the single crystal semiconductor substrate 112n. The hydrogen doping concentration of the fragile layer 114 is controlled by the voltage for accelerating the ions, the tilt angle, the dosage, or the like. In the case of using the ions generated from hydrogen, the fragile layer 114 preferably includes hydrogen so that the peak value in hydrogen atoms is greater than or equal to 1×10¹⁹ atoms/cm³. The fragile layer 114, which is the region locally doped with hydrogen at high concentration, no longer has a crystalline structure but has a porous structure including microvoids. When thermal treatment is performed at relatively low temperatures (about 700° C. or less), there is a change in the volume of the microvoids in the fragile layer 114, so that the single crystal semiconductor substrate 112n can be divided at or near the fragile layer 114.

Note that a protective layer is preferably formed on the surface of the single crystal semiconductor substrate 112n which is irradiated with the ions, in order to prevent damage to the single crystal semiconductor substrate 112n. In the example illustrated in FIG. 13B, an insulating layer 101 which can function as a protective layer is formed on at least one surface of the single crystal semiconductor substrate 112n and the surface of the substrate where the insulating layer 101 is formed is irradiated with the ions accelerated by voltage. The insulating layer 101 is irradiated with the ions and the ions or an element of the ions that transmits through the insulating layer 101 is introduced to the single crystal semiconductor substrate 112n. Thus, the fragile layer 114 is formed in a region at a predetermined depth of the single crystal semiconductor substrate 112n.

As the insulating layer 101, an insulating layer such as a silicon oxide layer, a silicon nitride layer, a silicon nitride oxide layer, or a silicon oxynitride layer may be formed. For example, the insulating layer 101 can be formed in such a manner that the substrate is oxidized by exposure to ozone water, hydrogen peroxide water, or an ozone atmosphere so that a chemical oxide is formed to a thickness of about 2 nm to 5 nm on the surface of the single crystal semiconductor substrate 112n. Alternatively, the insulating layer 101 may be formed to a thickness of about 2 nm to 10 nm on the surface of the single crystal semiconductor substrate 112n by oxygen radical treatment or nitrogen radical treatment. Further alternatively, the insulating layer 101 may be formed to a thickness of about 2 nm to 50 nm by a plasma CVD method.

Note that a silicon oxynitride layer means a layer that includes more oxygen than nitrogen and specifically includes oxygen, nitrogen, silicon, and hydrogen at concentrations ranging from 50 at. % to 70 at. %, 0.5 at. % to 15 at. %, 25 at. % to 35 at. %, and 0.1 at. % to 10 at. %, respectively in the case where measurements are performed using Rutherford backscattering spectrometry (RBS) and hydrogen forward scattering (HFS). Further, a silicon nitride oxide layer means a layer that includes more nitrogen than oxygen and specifically includes oxygen, nitrogen, silicon, and hydrogen at concentrations ranging from 5 at. % to 30 at. %, 20 at. % to 55 at. %, 25 at. % to 35 at. %, and 10 at. % to 30 at. %, respectively in the case where measurements are performed using RBS and HFS. Note that percentages of nitrogen, oxygen, silicon, and hydrogen fall within the ranges given above, where the total number of atoms contained in the silicon oxynitride film or the silicon nitride oxide film is defined as 100 at. %.

An impurity element imparting one conductivity type is introduced to the single crystal semiconductor substrate 112n, so that the first impurity semiconductor layer 111n⁺ is formed on the one surface side of the single crystal semiconductor substrate 112n (see FIG. 13C).

The first impurity semiconductor layer 111n⁺ is formed in such a manner that an impurity element imparting one conductivity type is introduced by an ion doping method, an ion implantation method, a thermal diffusion method, or a laser doping method. Note that the first impurity semiconductor layer 111n⁺ is formed on the surface side of the substrate which serves as the single crystal semiconductor layer after the division of the single crystal semiconductor substrate 112n (on the surface side which is opposite the surface side where the single crystal semiconductor layer is divided).

In Embodiment 6, an impurity element imparting n-type conductivity (such as phosphorus) is introduced to form the first impurity semiconductor layer 111n⁺ having n-type conductivity. For example, an ion doping apparatus is used by which the substrate is irradiated with an ion flow formed by accelerating the generated ions by voltage without mass separation, and phosphine (PH₃) is used as a source gas so that phosphorus is introduced. At this time, hydrogen or helium may be added to the source gas that includes the impurity element imparting one conductivity type, such as phosphorus. By the use of an ion doping apparatus, the area to be irradiated with the ion beam can be enlarged. Even the single crystal semiconductor substrate 112n with a diagonal length of 300 mm can be processed efficiently. For example, a linear ion beam whose long side has a length of more than 300 mm is formed and delivered from one end to the other end of the single crystal semiconductor substrate 112n; thus, the first impurity semiconductor layer 111n⁺ can be formed at a uniform depth.

An impurity element imparting n-type conductivity (such as phosphorus) is introduced to the single crystal semiconductor substrate 112n through the surface side thereof provided with the insulating layer 101, so that the first impurity semiconductor layer 111n⁺ having n-type conductivity is formed on the one surface side of the single crystal semiconductor substrate 112n. The impurity element imparting n-type conductivity is introduced to the single crystal semiconductor substrate 112n through the insulating layer 101; thus, the first impurity semiconductor layer 111n⁺ is formed on the surface side of the single crystal semiconductor substrate 112n which is in contact with the insulating layer 101. After the formation of the first impurity semiconductor layer 111n⁺, the insulating layer 101 which has rendered unnecessary is removed. In the case of forming the first impurity semiconductor layer 111n⁺ by a thermal diffusion method or the like, the insulating layer 101 may be removed after the formation of the fragile layer 114.

Note that, in the case where the single crystal semiconductor substrate 112n has n-type conductivity, the first impurity semiconductor layer 111n⁺ which is an n-type region with a concentration higher than that of the single crystal semiconductor substrate 112n is formed by introduction of the impurity element imparting n-type conductivity. In order to distinguish from the terms of n-type, n-region, and the like, the high-concentration n-type region is also referred to as an n⁺ type or an n⁺ region. In a similar manner, in the case where the single crystal semiconductor substrate 112n is a p-type semiconductor substrate and the first impurity semiconductor layer 111n⁺ is formed by introduction of an impurity element imparting p-type conductivity, the first impurity semiconductor layer 111n⁺ is also referred to as a p⁺ type or a p⁺ region.

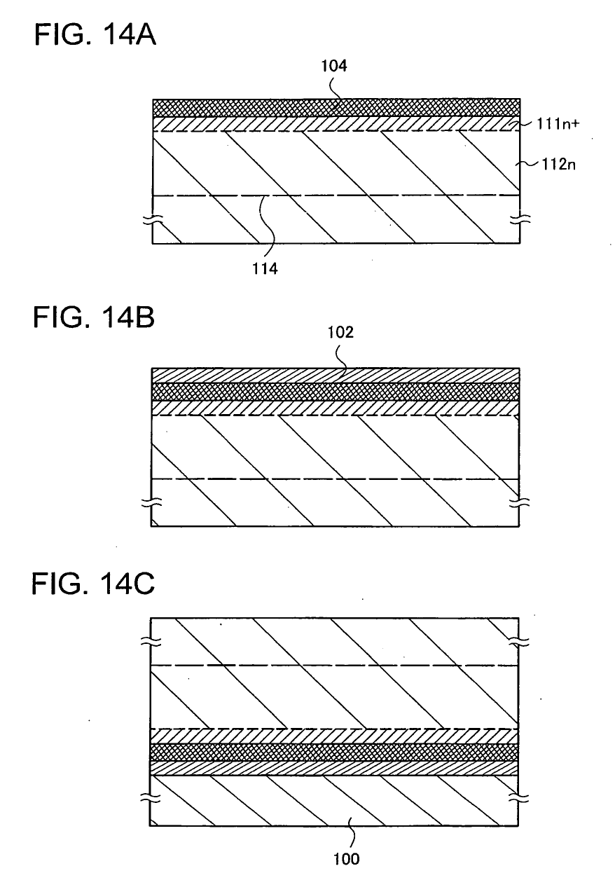

The first electrode 104 is formed on the surface of the single crystal semiconductor substrate 112n where the first impurity semiconductor layer 111n⁺ is formed (see FIG. 14A).

The first electrode 104 is formed from, for example, a metal material such as copper, aluminum, titanium, molybdenum, tungsten, tantalum, chromium, or nickel. With use of such a metal material, the first electrode 104 is formed to a thickness of greater than or equal to 100 nm by an evaporation method or a sputtering method. Note that, in the case where a native oxide layer or the like is formed on the surface of the single crystal semiconductor substrate 112n where the first impurity semiconductor layer 111n⁺ is formed, such a native oxide layer or the like is removed and then the first electrode 104 is formed. As described later in Embodiment 6, in the case of slicing the single crystal semiconductor substrate 112n through thermal treatment, the first electrode 104 is formed from a material having heat resistance that can withstand the thermal treatment. For example, the heat resistance to the temperatures of about the strain point of the substrate 100 which is later fixed is necessary.

The first electrode 104 can have a stacked structure of a metal material and a nitride of a metal material. For example, the first electrode 104 can have a stacked structure of a tantalum nitride layer and a copper layer, a tantalum nitride layer and an aluminum layer, a tantalum nitride layer and a tungsten layer, a titanium nitride layer and a titanium layer, a tungsten nitride layer and a tungsten layer, or the like. Note that the first electrode is formed preferably by stacking a nitride layer and a metal material layer from the surface side that is in contact with the single crystal semiconductor substrate 112n (the first impurity semiconductor layer 111n⁺). By the formation of the nitride layer, the metal material layer and the single crystal semiconductor substrate 112n has better contact with each other; as a result, the first electrode 104 and the single crystal semiconductor substrate 112n can have favorable contact with each other.

The surface of the first electrode 104 preferably has an average surface roughness (Ra) of 0.5 nm or less, more preferably 0.3 nm or less. Needless to say, the Ra is preferably smaller. When the smoothness of the surface of the first electrode 104 is favorable, it is possible to attach favorably the first electrode 104 to the substrate 100 later. Note that the average surface roughness (Ra) in this specification refers to centerline average roughness defined according to JIS B0601 which is expanded three dimensionally so as to correspond to a plane.

The insulating layer 102 is formed over the first electrode 104 (see FIG. 14B).

The insulating layer 102 can have a single-layer structure or a stacked structure including two or more layers. In any case, the plane which forms a bonding (the bonding plane) by attachment to the substrate 100 later preferably has favorable smoothness, and more preferably the surface has hydrophilicity. Specifically, when the insulating layer 102 is formed so that the average surface roughness Ra of the bonding plane is 0.5 nm or less, preferably 0.3 nm or less, the attachment with the substrate 100 can be performed favorably. Needless to say, the average surface roughness (Ra) is preferably small.

For example, as a layer that forms the bonding plane of the insulating layer 102, a silicon oxide layer, a silicon nitride layer, a silicon oxynitride layer, a silicon nitride oxide layer, or the like is formed by a CVD method such as a plasma CVD method, a photo CVD method, or a thermal CVD method (the category of the thermal CVD method includes a reduced-pressure CVD method and an atmospheric pressure CVD method). A plasma CVD method is preferable in the formation of the insulating layer 102 because a layer with favorable smoothness can be formed.

Specifically, as for a layer which has a smooth surface and which can form a hydrophilic surface, a silicon oxide layer formed by a plasma CVD method using organosilane is preferable. The bonding with the substrate can be strengthened by the use of such a silicon oxide layer. As the organosilane gas, any of the following silicon-containing compounds may be used: tetraethoxysilane (TEOS: chemical formula: Si(OC₂H₅)₄), tetramethylsilane (TMS: chemical formula: Si(CH₃)₄), tetramethylcyclotetrasiloxane (TMCTS), octamethylcyclotetrasiloxane (OMCTS), hexamethyldisilazane (HMDS), triethoxysilane (SiH(OC₂H₅)₃), and trisdimethylaminosilane (SiH(N(CH₃)₂)₃).

Further, for the layer which has a smooth surface and which can form a hydrophilic surface, a layer of silicon oxide, silicon oxynitride, silicon nitride, or silicon nitride oxide which is formed by a plasma CVD method using a silane-based gas such as silane, disilane, or trisilane can be used. For example, as the layer that forms the bonding plane of the insulating layer 102, a silicon nitride layer formed by a plasma CVD method using silane and ammonia as a source gas can be used. Note that hydrogen may be added to the source gas including silane and ammonia; alternatively, dinitrogen monoxide may be added to the source gas so that a silicon nitride oxide layer is formed.

In any case, the insulating layer 102 is not limited to an insulating layer containing silicon, as long as the insulating layer 102 has a smooth bonding plane, specifically, the insulating layer 102 has a smooth bonding plane with an average surface roughness (Ra) of 0.5 nm or less, preferably 0.3 nm or less. Note that in the case where the insulating layer 102 has a stacked structure, the layers except the layer which forms the bonding plane are not limited thereto. In Embodiment 6, moreover, the insulating layer 102 needs to be formed at a temperature at which the fragile layer 114 formed in the single crystal semiconductor substrate 112n does not change, preferably at less than or equal to 350° C.

For example, the insulating layer 102 is formed using a stack of a 50-nm-thick silicon oxynitride layer, a 50-nm-thick silicon nitride oxide layer, and a 50-nm-thick silicon oxide layer arranged from the first electrode 104 side. The stacked structure of the insulating layer 102 can be formed by a plasma CVD method. The silicon oxide layer, which forms the bonding plane in the above case, has an Ra of 0.4 nm or less, preferably 0.3 nm or less; for example, the silicon oxide layer is formed by a plasma CVD method using TEOS for a source gas. When the insulating layer 102 includes a silicon insulating layer containing nitrogen, specifically a silicon nitride layer or a silicon nitride oxide layer, diffusion of impurities from the substrate 100 which is later attached can be prevented.

The single crystal semiconductor substrate 112n and the substrate 100 are attached to each other in a manner that the one surface of the single crystal semiconductor substrate 112n and the one surface of the substrate 100 face each other (see FIG. 14C).

There are no particular limitations on the kind of the substrate 100 as long as the substrate can withstand the process for manufacturing the photoelectric conversion device according to an embodiment of the present invention; for example, a substrate having an insulating surface or an insulating substrate is used. Specifically, a variety of glass substrates used in the electronics industry, such as aluminosilicate glass, aluminoborosilicate glass, or barium borosilicate glass; a quartz substrate; a ceramic substrate; a sapphire substrate; and the like are given as examples. A glass substrate, which can increase in area and is inexpensive, is preferably used because a cost reduction and productivity improvement can be achieved.

Prior to the attachment of the single crystal semiconductor substrate 112n and the substrate 100, the bonding plane of each of the single crystal semiconductor substrate 112n and the substrate 100 is preferably cleaned sufficiently in advance. This prevents particles such as microscopic dust on the bonding plane from causing a defect in attachment. For example, the bonding planes are cleaned preferably by ultrasonic cleaning using pure water and ultrasonic wave with a frequency of 100 kHz to 2 MHz, megasonic cleaning, or two fluid cleaning with pure water, nitrogen, and dry air. Further, carbon dioxide or the like may be added to pure water which is used for the cleaning so that the resistivity is reduced to be 5 MΩcm or less to prevent generation of static electricity.

The bonding plane of the single crystal semiconductor substrate 112n and the bonding plane of the substrate 100 are brought into contact with each other and the bonding is formed by van der Waals forces or hydrogen bonding. In FIG. 14C, a surface of the insulating layer 102 formed over the single crystal semiconductor substrate 112n and one surface of the substrate 100 are brought into contact with each other and bonded. For example, the substrate 100 and the single crystal semiconductor substrate 112n which are superimposed are pressed at one place, whereby van der Waals forces or hydrogen bonding can be spread over the entire area of the bonding planes. When one or both of the bonding planes have hydrophilic surfaces, hydroxyl groups or water molecules serve as an adhesive and water molecules diffuse in later thermal treatment; then, the remaining composition forms silanol groups (Si—OH) and the bonding is formed by hydrogen bonding. Further, this bonding portion forms a siloxane bonding (O—Si—O) by release of hydrogen to become a covalent bond, which forms firmer bonding.

The bonding plane of the single crystal semiconductor substrate 112n and the bonding plane of the substrate 100 each preferably have an average surface roughness (Ra) of 0.5 nm or less, more preferably 0.3 nm or less. Further, the sum of the average surface roughness (Ra) of the bonding plane of the single crystal semiconductor substrate 112n and the bonding plane of the substrate 100 is 0.7 nm or less, preferably 0.6 nm or less, more preferably 0.4 nm or less. The bonding plane of the single crystal semiconductor substrate 112n and the bonding plane of the substrate 100 each have a contact angle to pure water of 20° or less, preferably 10° or less, more preferably 5° or less. The total contact angle to pure water of the bonding plane of the single crystal semiconductor substrate 112n and the bonding plane of the substrate 100 is 30° or less, preferably 20° or less, more preferably 10° or less. If the bonding planes are attached under the above conditions, they are attached in a favorable manner, whereby the bonding can be further strengthened.

Note that the attachment may be performed after the bonding planes are irradiated with an atomic beam or an ionic beam or the bonding planes are subjected to plasma treatment or radical treatment. Through the treatment as above, the bonding planes can be activated so that the attachment can be performed favorably. For example, the bonding plane can be activated by being irradiated with an inert gas neutral atomic beam of argon or an inert gas ion beam of argon or the like or activated by being exposed to oxygen plasma, nitrogen plasma, oxygen radicals, or nitrogen radicals. By the activation of the bonding planes, the bonding can be formed at low temperatures (for example, 400° C. or less) even between bases that contain different materials, such as an insulating layer and a glass substrate. Further, the bonding can be strengthened when the bonding plane is processed using ozone-added water, oxygen-added water, hydrogen-added water, pure water, or the like so that the bonding surface is hydrophilic and the number of hydroxyls on the bonding plane is increased.

After the single crystal semiconductor substrate 112n and the substrate 100 are superposed on each other, thermal treatment and/or pressure treatment is preferably performed. Thermal treatment and/or pressure treatment can increase the bonding strength. When the thermal treatment is performed, the temperature of the thermal treatment is set at less than or equal to the strain point of the substrate 100 and at a temperature at which the volume of the fragile layer 114 formed in the single crystal semiconductor substrate 112n does not change, preferably at a temperature higher than or equal to 200° C. and lower than 410° C. This thermal treatment is preferably performed in succession in the apparatus or at the place where the attachment is performed. In the case of performing the pressure treatment pressure is applied to the bonding planes in a vertical direction in consideration of the pressure resistance of the substrate 100 and the single crystal semiconductor substrate 112n. In succession to the thermal treatment for increasing the bonding strength, another thermal treatment for dividing the single crystal semiconductor substrate 112n at the fragile layer 114, which is described later, may be performed.

Alternatively, an insulating layer such as a silicon oxide layer, a silicon nitride layer, a silicon oxynitride layer, or a silicon nitride oxide layer may be formed on the substrate 100 side, so that the substrate 100 is attached to the single crystal semiconductor substrate 112n with the insulating layer interposed therebetween. For example, the insulating layer formed on the substrate 100 side and the insulating layer 102 formed on the single crystal semiconductor substrate 112n side can serve as the bonding planes which are attached to each other.

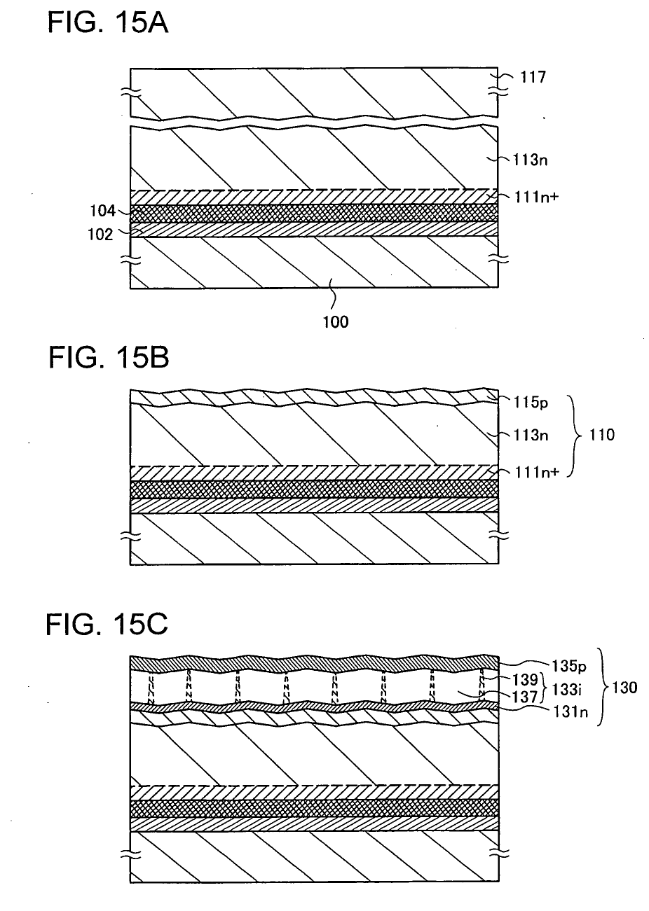

The single crystal semiconductor substrate 112n is sliced so that the superficial layer thereof is separated; thus, the single crystal semiconductor layer 113n fixed to the substrate 100 is formed (see FIG. 15A).

In the case where the fragile layer 114 is formed as in Embodiment 6, the single crystal semiconductor substrate 112n can be divided by thermal treatment. The thermal treatment can be performed by, for example, dielectric heating with use of a high frequency wave such as a microwave generated in a high-frequency generator or a heating furnace. The favorable temperature in the thermal treatment for dividing the single crystal semiconductor substrate 112n is higher than or equal to 410° C. and lower than the strain point of the single crystal semiconductor substrate 112n and lower than the strain point of the substrate 100. By the thermal treatment performed at 410° C. or more, there is a change in the volume of the microvoids in the fragile layer 114 so that the single crystal semiconductor substrate 112n can be divided at or near the fragile layer 114.

The thermal treatment can be performed by rapid thermal annealing (RTA) typified by lamp irradiation or laser beam irradiation. By the rapid thermal annealing, heating up to the temperature that is slightly higher than the strain points of the single crystal semiconductor substrate 112n and the substrate 100 can be performed.

The single crystal semiconductor layer 113n after the division is provided with the first impurity semiconductor layer 111n⁺ on the surface that is in contact with the first electrode 104. In the thermal treatment for the division, the impurity element in the first impurity semiconductor layer 111n⁺can be activated.

The single crystal semiconductor substrate 112n is divided at the fragile layer 114, whereby the single crystal semiconductor layer 113n can be separated from the single crystal semiconductor substrate 112n. Thus, a single crystal semiconductor substrate 117, that is, the single crystal semiconductor substrate 112n from which the single crystal semiconductor layer 113n is separated, is obtained. The single crystal semiconductor substrate 117 after the division can be reused after reprocessing. The single crystal semiconductor substrate 117 may be reused as a single crystal semiconductor substrate for forming a photoelectric conversion device, or may be used for other purposes. By repeating the cycle of using the single crystal semiconductor substrate 117 as the single crystal semiconductor substrate from which the single crystal semiconductor layer 113n is separated, it is possible to manufacture a plurality of photoelectric conversion devices out of one single crystal semiconductor substrate which serves as a material.

Due to the division of the single crystal semiconductor substrate 112n at the fragile layer 114, the division plane (separation plane) of the single crystal semiconductor layer 113n after the slice is uneven in some cases. The unevenness of the division plane has an influence on layers that are stacked over the single crystal semiconductor layer 113n, so that the light incidence plane of a completed photoelectric conversion device can have an uneven structure. The unevenness on the light incidence plane side can serve as a surface texture, which can improve the light absorptance. By the irradiation with the ions accelerated by voltage and the division through the thermal treatment as above, the surface texture structure can be formed without chemical etching and the like. As a result, an improvement in photoelectric conversion efficiency can be achieved while the cost is reduced and the process is shortened.

Further, after the formation of the single crystal semiconductor layer 113n fixed onto the substrate 100, the recovery of crystallinity of the single crystal semiconductor layer 113n and the recovery from damage to the single crystal semiconductor layer 113n may be achieved by thermal treatment or laser processing. The thermal treatment is preferably performed in a heating furnace, by RTA, or the like at higher temperatures or for a longer time than in the thermal treatment for the division. Needless to say, the thermal treatment is performed at a temperature that does not exceed the strain point of the substrate 100. In the laser processing, a solid-state laser typified by a YAG laser or a YVO₄ laser, or an excimer laser (XeCl (308 nm), KrF (248 nm), ArF (193 nm)) is used as a light source (a laser oscillator). In the case of using the solid-state laser, a second harmonic (532 nm), a third harmonic (355 nm), or a fourth harmonic (266 nm) is used. For example, the crystallinity of the single crystal semiconductor layer 113n is recovered when the single crystal semiconductor layer 113n is irradiated with a laser beam with a wavelength of 532 nm, which is the second harmonic of a YAG laser. By the thermal treatment or laser processing performed on the single crystal semiconductor layer 113n, the recovery of the crystallinity, which has been deteriorated due to the formation of the fragile layer 114 or the division of the single crystal semiconductor substrate 112n, or the recovery from the damage can be achieved.

After the single crystal semiconductor substrate is sliced, the thickness of the single crystal semiconductor layer 113n may be increased by utilizing an epitaxial growth technique such as solid phase growth (solid phase epitaxial growth) or vapor phase growth (vapor phase epitaxial growth). By the epitaxial growth technique, the thickness of the single crystal semiconductor layer formed by the slice can be decreased. As a result, the single crystal semiconductor substrate from which the single crystal semiconductor layer is separated can remain thick, so that the number of times of reuse can be increased. Therefore, the efficient utilization of the semiconductor substrate can be achieved to contribute to resource saving.

For example, after formation of a non-single-crystal semiconductor layer over the single crystal semiconductor layer formed by the slice, solid phase growth is performed through thermal treatment so that the thickness of the single crystal semiconductor layer 113n can be increased. Alternatively, over the single crystal semiconductor layer formed by the slice, a semiconductor layer is formed by a plasma CVD method using a reaction gas in which a semiconductor source gas is diluted with a dilution gas such as hydrogen, whereby vapor phase growth is performed at the same time as the deposition of the semiconductor layer to increase the thickness of the single crystal semiconductor layer 113n. Further alternatively, a first semiconductor layer (for example, a semiconductor layer formed under the conditions of forming a microcrystalline semiconductor) with high crystallinity is formed thin over the single crystal semiconductor layer formed by the slice, a second semiconductor layer (for example, a semiconductor layer formed at higher deposition rate than that of the first semiconductor layer) with lower crystallinity than the first semiconductor layer is formed thick, and then thermal treatment is performed, whereby solid phase growth is performed to increase the thickness of the single crystal semiconductor layer 113n. In some cases, the first semiconductor layer with high crystallinity undergoes vapor phase growth due to the influence of the crystallinity of the single crystal semiconductor layer formed by the slice. However, the crystallinity is not limited to that of single crystal as long as the crystallinity is higher than that of the second semiconductor layer with low crystallinity which is formed later.

In many cases, a region whose thickness is increased through epitaxial growth on the single crystal semiconductor layer formed by the slice is not affected by the conductivity type of a region serving as seed crystals, unless the impurity element imparting one conductivity type is added to the reaction gas used for increasing the film thickness. In this case, the single crystal semiconductor layer 113n in FIG. 15A has a structure in which an i-type single crystal semiconductor region is stacked over the n-type single crystal semiconductor region. Further, with the use of the reaction gas to which the impurity element imparting one conductivity type is added, the epitaxially grown region can serve as an n-type or p-type semiconductor. For example, the single crystal semiconductor layer 113n in FIG. 15A has a structure in which a p-type single crystal semiconductor region is stacked over the n-type single crystal semiconductor region.

The second impurity semiconductor layer 115p is formed over the single crystal semiconductor layer 113n (see FIG. 15B).

As the second impurity semiconductor layer 115p, a semiconductor layer including an impurity element having a conductivity type opposite to that of the first impurity semiconductor layer 111n⁺ is formed by a CVD method or the like. Alternatively, the second impurity semiconductor layer 115p can be formed by introduction of an impurity element imparting one conductivity type (an impurity element imparting a conductivity type opposite to that of the first impurity semiconductor layer 111n⁺) to the surface side of the single crystal semiconductor layer 113n (the division plane side of the single crystal semiconductor layer 113n) by an ion doping method, an ion implantation method, or a laser doping method.

In Embodiment 6, the second impurity semiconductor layer 115p having p-type conductivity is formed in such a manner that a semiconductor layer including an impurity element imparting p-type conductivity (such as boron) is formed by a plasma CVD method because the first impurity semiconductor layer 111n⁺ has n-type conductivity. For example, the second impurity semiconductor layer 115p is formed using a reaction gas including a semiconductor source gas (such as silane) and a dilution gas (such as hydrogen), to which a doping gas including an impurity element imparting p-type conductivity (such as diborane) is added.

In a reaction chamber of a plasma CVD apparatus, a doping gas including boron (such as diborane) is added to the reaction gas including silane and hydrogen and glow discharge plasma is used, whereby the second impurity semiconductor layer 115p is formed. The glow discharge plasma is generated by applying high-frequency power with a frequency of greater than or equal to 1 MHz and less than or equal to 20 MHz, typically 13.56 MHz, or high-frequency power with a frequency in the VHF band of greater than 30 MHz up to about 300 MHz, typically 27.12 MHz or 60 MHz. The substrate is heated at a temperature greater than or equal to 100° C. and less than or equal to 300° C., preferably greater than or equal to 120° C. and less than or equal to 220° C. By changing the flow rate of each gas, the applied electric power, and other conditions, a microcrystalline semiconductor or an amorphous semiconductor can be formed. When a doping gas including an impurity element imparting n-type conductivity is used instead of the doping gas including boron, an n-type semiconductor layer can be formed.

Note that a material layer which is different from a semiconductor, such as a native oxide layer formed over the single crystal semiconductor layer 113n, is removed prior to the formation of the second impurity semiconductor layer 115p. The native oxide layer can be removed by dry etching or wet etching in which hydrofluoric acid is used. Before the semiconductor source gas used for forming the second impurity semiconductor layer 115p is introduced, plasma treatment is performed using a mixed gas of hydrogen and a rare gas, for example a mixed gas of hydrogen and helium or a mixed gas of hydrogen, helium, and argon, whereby a native oxide layer and an air atmospheric element (oxygen, nitrogen, or carbon) can be removed.

In this manner, the first unit cell 110 is formed. The main part of the first unit cell 110 which performs photoelectric conversion is formed using the single crystal semiconductor layer.

Over the second impurity semiconductor layer 115p, the third impurity semiconductor layer 131n, the non-single-crystal semiconductor layer 133i, and the fourth impurity semiconductor layer 135p are formed (see FIG. 15C).

As the third impurity semiconductor layer 131n, a semiconductor layer including an impurity element having a conductivity type opposite to that of the second impurity semiconductor layer 115p is formed by a CVD method or the like. In Embodiment 6, a microcrystalline semiconductor layer including an impurity element imparting n-type conductivity (such as phosphorus) is formed by a plasma CVD method as the third impurity semiconductor layer 13 In having n-type conductivity.

The non-single-crystal semiconductor layer 133i is formed over the third impurity semiconductor layer 131n in such a manner that the flow rate of the dilution gas to the semiconductor source gas is set greater than or equal to 1 time and less than 10 times, preferably greater than or equal to 1 time and less than or equal to 6 times, the reaction gas is introduced to a reaction space, and plasma typified by glow discharge plasma is generated while predetermined pressure is kept. By the deposition while the dilution amount of the semiconductor source gas is controlled, the non-single-crystal semiconductor layer 133i where the crystals 139 are grown from the third impurity semiconductor layer 131n in the amorphous structure 137 can be formed.

As the fourth impurity semiconductor layer 135p, a semiconductor layer including an impurity element imparting a conductivity type opposite to that of the third impurity semiconductor layer 131n is formed by a CVD method or the like. In Embodiment 6, a microcrystalline semiconductor layer including an impurity element imparting p-type conductivity (such as boron) is formed by a plasma CVD method as the fourth impurity semiconductor layer 135p having p-type conductivity.

In this manner, the second unit cell 130 is formed. The main part of the second unit cell 130 which performs photoelectric conversion is formed using the non-single-crystal semiconductor layer where the crystals penetrating successively in the film thickness direction are included in the amorphous structure.

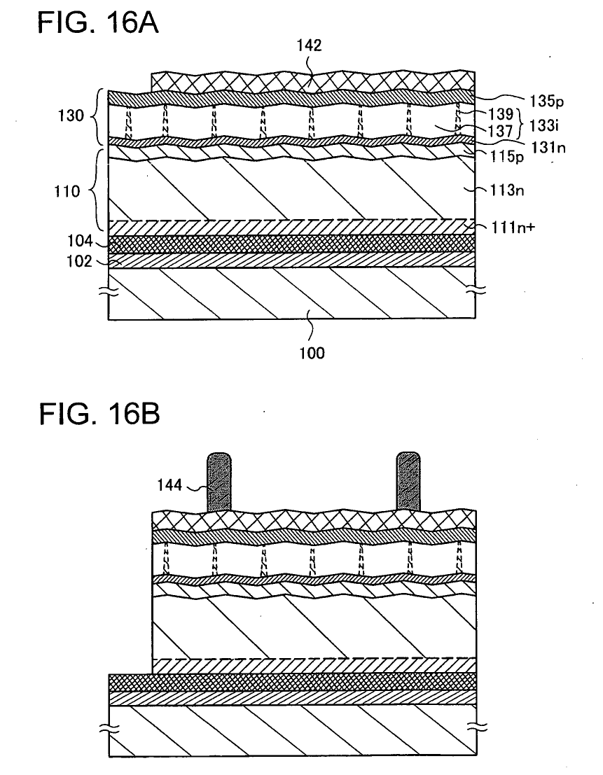

The second electrode 142 is formed over the fourth impurity semiconductor layer 135p (see FIG. 16A).

In Embodiment 6, the second electrode 142 side is the light incidence plane; therefore, the second electrode 142 is formed from a transparent conductive material by a sputtering method or a vacuum evaporation method. As the transparent conductive material, metal oxide such as indium tin oxide alloy, zinc oxide, tin oxide, an alloy of indium oxide and zinc oxide, or the like is used. As an alternative to the transparent conductive material such as metal oxide, a conductive high molecular material can be used. As the conductive high molecular material, a π electron conjugated conductive high molecule can be used. For example, polyaniline and/or a derivative thereof, polypyrrole and/or a derivative thereof, polythiophene and/or a derivative thereof, a copolymer of two or more kinds of those materials, and the like are given. In the case of using a conductive high molecular material, the conductive high molecule is dissolved in a solvent and formed into the second electrode 142 by a wet process such as a coating method, a droplet discharging method, or a printing method.

The second electrode 142 is preferably formed as selected by the use of a shadow mask or the like so that the second electrode 142 can be used as an etching mask for exposing part of the first electrode 104.

The first unit cell 110 and the second unit cell 130 provided over the first electrode 104 are etched as selected, whereby part of the first electrode 104 is exposed. Then, the auxiliary electrode 144 which connects to the second electrode 142 is formed (see FIG. 16B).

In Embodiment 6, the first unit cell 110 and the second unit cell 130 are etched using the second electrode 142 as a mask, whereby part of the first electrode 104 is exposed. The etching may be performed under the condition where the etching selectivity of the first electrode 104 to the layers formed over the first electrode 104 (which are the single crystal semiconductor layer 113n, the second impurity semiconductor layer 115p, the third impurity semiconductor layer 131n, the non-single-crystal semiconductor layer 133i, and the fourth impurity semiconductor layer 135p) is sufficiently high. For example, the first unit cell 110 and the second unit cell 130 can be dry-etched using a fluorinated gas such as NF₃ or SF₆. Note that since the second electrode 142 is used as a mask in Embodiment 6, a new mask for etching is not necessary. Needless to say, a mask can be formed using a resist or an insulating layer.

In order to make the second electrode 142 side serve as a light incidence plane, the auxiliary electrode 144 is formed as selected so that light can enter the second electrode 142 side. There is no limitation on the shape of the auxiliary electrode 144; however, the area thereof which covers the light incidence plane is preferably as small as possible. For example, the auxiliary electrode 144 preferably has a grating shape, a comb-like shape, a pectinate shape, or the like when seen from above. The auxiliary electrode 144 is formed using nickel, aluminum, silver, lead-tin (solder), or the like by a printing method or the like. For example, a nickel paste or a silver paste is used to form the auxiliary electrode 144 by a screen printing method.

In the case of forming the electrode by a screen printing method using a conductive paste, the thickness of the electrode can be about several micrometers to several hundreds of micrometers. However, FIG. 16B and FIG. 12 are schematic views and do not necessarily show the actual size.

In this manner, the stacked photoelectric conversion device illustrated in FIG. 12 can be completed.

Note that by the step of forming the auxiliary electrode 144, an auxiliary electrode which is in contact with the first electrode 104 can also be formed. Whether or not the auxiliary electrode 144 connected to the second electrode 142 and the auxiliary electrode connected to the first electrode 104 are formed, and the shape of each auxiliary electrode can be determined as appropriate. By the formation of the auxiliary electrode, the electrodes can be connected more freely, so that it becomes easy to manufacture a serially-connected integrated photoelectric conversion device module or the like.

Further, a passivation layer serving as an antireflection layer may be formed over the second electrode 142. For example, a silicon nitride layer, a silicon nitride oxide layer, a magnesium fluoride layer, or the like may be formed. By the formation of the passivation layer serving as an antireflection layer, the reflection at the light incidence plane can be decreased.

In Embodiment 6, each of the first impurity semiconductor layer 111n⁺, the single crystal semiconductor layer 113n, and the third impurity semiconductor layer 131n is formed from an n-type semiconductor and each of the second impurity semiconductor layer 115p and the fourth impurity semiconductor layer 135p is formed from a p-type semiconductor. However, the former may be a p-type semiconductor and the latter may be an n-type semiconductor.

Moreover, in Embodiment 6, the second unit cell 130 formed over the first unit cell has the non-single-crystal semiconductor layer in which the crystals penetrating in the film thickness direction exist in the amorphous structure. However, another unit cell having a non-single-crystal semiconductor layer may be further stacked over the second unit cell 130. In the latter case, it is preferable that the proportion of the crystals decreases toward the light incidence side. This is because the amorphous structure becomes dominant as the proportion of the crystals decreases, which is suitable for the absorption of light in a short wavelength range.

The semiconductor layer of Embodiment 6 can be formed in the plasma CVD apparatus illustrated in FIG. 3 and FIG. 4. The specific description thereof is seen in Embodiment 1. In Embodiment 6, a reaction gas is introduced to a reaction chamber (a reaction space) in a plasma CVD apparatus with the structure as shown in FIG. 3 and FIG. 4 to generate plasma with which the second impurity semiconductor layer 115p to the fourth impurity semiconductor layer 135p can be formed.

An example of forming the second impurity semiconductor layer 115p to the fourth impurity semiconductor layer 135p is shown. First, plasma is generated by introducing a first reaction gas to a reaction chamber (1) where the substrate 100 on which the steps up to the step of forming the single crystal semiconductor layer 113n are completed is delivered, so that the second impurity semiconductor layer 115p (p-type semiconductor layer) is formed over the single crystal semiconductor layer 113n. Next, the substrate 100 is transferred from the reaction chamber (1) to a reaction chamber (2) without exposure to the air. A second reaction gas is introduced to the reaction chamber (2) to generate plasma, so that the third impurity semiconductor layer 131n (n-type semiconductor layer) is formed over the second impurity semiconductor layer 115p. Next, the substrate 100 is transferred from the reaction chamber (2) to a reaction chamber (3) without exposure to the air. A third reaction gas is introduced to the reaction chamber (3) to generate plasma, so that the non-single-crystal semiconductor layer 133i (i-type semiconductor layer) is formed over the third impurity semiconductor layer 131n. Then, the substrate 100 is transferred from the reaction chamber (3) to the reaction chamber (1) without exposure to the air. A fourth reaction gas is introduced to the reaction chamber (1) to generate plasma, so that the fourth impurity semiconductor layer 135p (p-type semiconductor layer) is formed over the non-single-crystal semiconductor layer 133i.

Note that Embodiment 6 can be combined with any of the other embodiments as appropriate.

### Embodiment 7

Embodiment 7 describes a method for manufacturing a photoelectric conversion device that is different from those described in the above embodiments.

In Embodiment 6 described with reference to FIG. 13B and FIGS. 14A and 14B, (1) the insulating layer 101 is formed on one surface of the single crystal semiconductor substrate 112n, the fragile layer 114 is formed in a region at a predetermined depth of the single crystal semiconductor substrate 112n, the first impurity semiconductor layer 111n′ is formed by introducing an impurity element imparting one conductivity type through the insulating layer 101, and then the insulating layer 101 is removed and the first electrode 104 and the insulating layer 102 are stacked.

There is no limitation on the order and method for forming the fragile layer 114, the first impurity semiconductor layer 111n⁺, the first electrode 104, and the insulating layer 102; at least the following (2) to (4) are given.

(2) The insulating layer is formed on one surface of the single crystal semiconductor substrate, the first impurity semiconductor layer 111n⁺ is formed by introducing an impurity element imparting one conductivity type through the insulating layer, and the fragile layer is formed in a region at a predetermined depth of the single crystal semiconductor substrate. The first electrode and the insulating layer are formed on the surface of the single crystal semiconductor substrate where the insulating layer is removed.

(3) The first electrode is formed on one surface of the single crystal semiconductor substrate, and the fragile layer is formed in a region at a predetermined depth of the single crystal semiconductor substrate. The first impurity semiconductor layer is formed by introducing an impurity element imparting one conductivity type through the first electrode, and the insulating layer is formed over the first electrode.

(4) The first electrode is formed on one surface of the single crystal semiconductor substrate, the first impurity semiconductor layer is formed by introducing the impurity element imparting one conductivity type through the first electrode, and the fragile layer is formed in a region at a predetermined depth of the single crystal semiconductor substrate. The insulating layer is formed over the first electrode.

In this manner, there is no limitation on the order of steps in manufacturing a photoelectric conversion device according to an embodiment of the present invention and the order can be determined as appropriate.

Note that Embodiment 7 can be combined with any of the other embodiments as appropriate.

### Embodiment 8

Embodiment 8 describes a photoelectric conversion device having a different structure from those described in the above embodiments. Specifically, an example is shown in which the junction portion between the impurity semiconductor layer having one conductivity type and the non-single-crystal semiconductor layer is provided with an impurity semiconductor layer having the one conductivity type and lower impurity concentration than the impurity semiconductor layer having the one conductivity type.

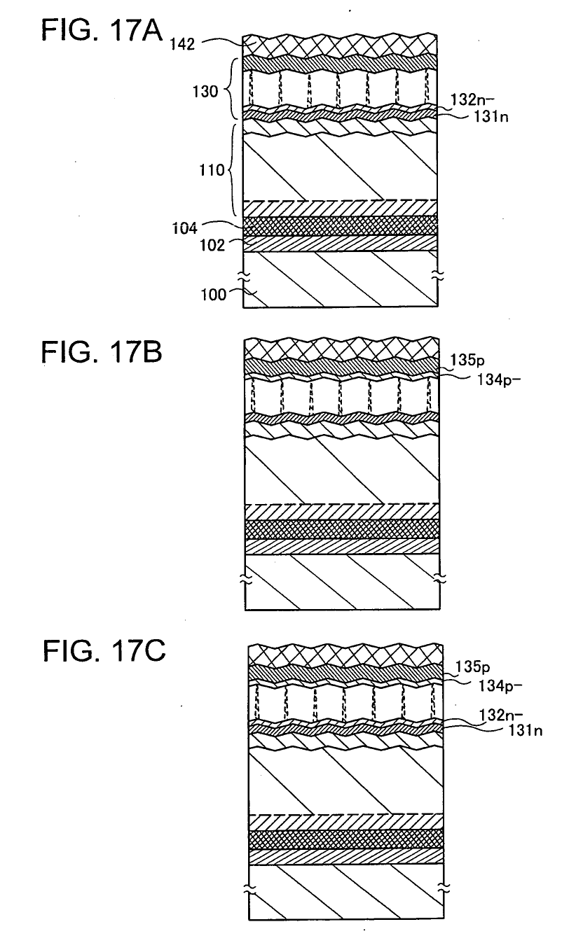

Each of FIGS. 17A to 17C illustrates a tandem photoelectric conversion device in which two unit cells are stacked. In FIG. 17A, the first unit cell 110, a second unit cell 130, and the second electrode 142 are arranged from the substrate 100 side. The substrate 100 is provided with the first electrode 104 with the insulating layer 102 interposed therebetween. In the first unit cell 110, the single crystal semiconductor layer 113n including the first impurity semiconductor layer 111n, and the second impurity semiconductor layer 115p are arranged in that order so that the single crystal semiconductor layer 113n is in contact with the first electrode 104. In the second unit cell 130, the third impurity semiconductor layer 131n, a low-concentration impurity semiconductor layer 132n, the non-single-crystal semiconductor layer 133i including crystals penetrating in the deposition direction of the layer, and the fourth impurity semiconductor layer 135p are arranged in that order so that the third impurity semiconductor layer 131n is in contact with the second impurity semiconductor layer 115p of the first unit cell 110. The auxiliary electrode 144 is not illustrated here.

The low-concentration impurity semiconductor layer 132n is provided between the third impurity semiconductor layer 131n and the non-single-crystal semiconductor layer 133i of the second unit cell 130. The low-concentration impurity semiconductor layer 132n⁻ includes an impurity element imparting the same conductivity type as that of the third impurity semiconductor layer 131n and has lower impurity concentration than the third impurity semiconductor layer 131n.

When the junction portion between the impurity semiconductor layer having one conductivity type and the i-type semiconductor layer is provided with the impurity semiconductor layer having the one conductivity type and lower impurity concentration than the impurity semiconductor layer having the one conductivity type, the carrier transporting property at the semiconductor junction interface is improved. For example, in FIG. 17A, the arrangement of n⁺nipnn⁻ip (or n⁺nipnn⁻ip) from the first electrode 104 side is employed. By the n⁻ in the main portion which performs photoelectric conversion in the non-single-crystal semiconductor layer of the second unit cell 130, the carrier transporting property is improved, which contributes to higher efficiency. The carrier transporting property is further improved when the low-concentration impurity semiconductor layer has impurity concentration that decreases in a stepwise manner or a continuous manner from the impurity semiconductor layer having one conductivity type toward the i-type semiconductor layer. Further, the interface state density is reduced and the diffusion potential is improved by the provision of the low-concentration impurity semiconductor layer, whereby an open circuit voltage of the photoelectric conversion device is increased. Note that the low-concentration impurity semiconductor layer may be formed from a microcrystalline semiconductor, typically microcrystalline silicon.

In FIG. 17B, the first unit cell 110, the second unit cell 130, and the second electrode 142 are arranged in that order from the substrate 100 side. The substrate 100 is provided with the first electrode 104 with the insulating layer 102 interposed therebetween. In the first unit cell 110, the single crystal semiconductor layer 113n including the first impurity semiconductor layer 111n⁺, and the second impurity semiconductor layer 115p are stacked. In the second unit cell 130, the third impurity semiconductor layer 131n, the non-single-crystal semiconductor layer 133i, a low-concentration impurity semiconductor layer 134p⁻, and the fourth impurity semiconductor layer 135p are stacked. Note that the auxiliary electrode 144 is not illustrated here.

The low-concentration impurity semiconductor layer 134p⁻ includes an impurity element imparting the same conductivity type as that of the fourth impurity semiconductor layer 135p and has lower impurity concentration than the fourth impurity semiconductor layer 135p. For example, in FIG. 17B, the arrangement of n⁺npnip⁻p (or n⁺nipnip⁻p) from the first electrode 104 side is employed. By the provision of p⁻ in the second unit cell 130, the carrier transporting property is improved.

In FIG. 17C, the first unit cell 110, the second unit cell 130, and the second electrode 142 are arranged in that order from the substrate 100 side. The substrate 100 is provided with the first electrode 104 with the insulating layer 102 interposed therebetween. In the first unit cell 110, the single crystal semiconductor layer 113n including the first impurity semiconductor layer 111n⁺, and the second impurity semiconductor layer 115p are stacked. In the second unit cell 130, the third impurity semiconductor layer 131n, the low-concentration impurity semiconductor layer 132n⁻, the non-single-crystal semiconductor layer 133i, the low-concentration impurity semiconductor layer 134p⁻, and the fourth impurity semiconductor layer 135p are stacked. For example, in FIG. 17C, the arrangement of n⁺npnn⁻ip⁻p (n⁺nipnn⁻ip⁻p) from the first electrode 104 side is employed. By the provision of n⁻ and p⁻ in the second unit cell 130, the carrier transporting property is improved.

Although the tandem photoelectric conversion device is described in Embodiment 8, the present invention can also be applied to a stacked photoelectric conversion device in which a cell whose main portion for photoelectric conversion has smaller energy gap than that of the second unit cell 130 is stacked over the second unit cell 130.

Note that Embodiment 8 can be combined with any of the other embodiments as appropriate.

### Embodiment 9

Embodiment 9 describes an example of an integrated photoelectric conversion device in which a plurality of photoelectric conversion cells is formed over one substrate and the photoelectric conversion cells are serially connected to each other to achieve integration in a photoelectric conversion device. The description is made below with reference to top views and cross-sectional views.

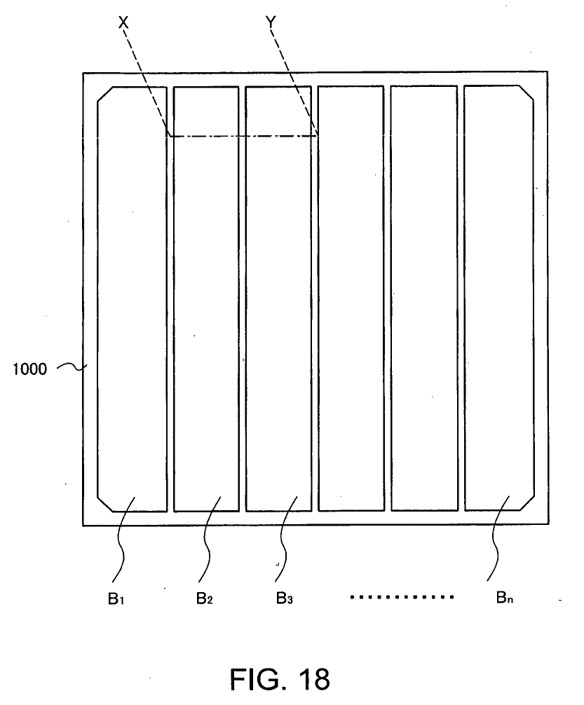

In the top view of FIG. 18, a plurality of bottom cells B₁ . . . Bₙ which is separated for each element is provided over one substrate 1000. The bottom cells B₁ . . . Bₙ have a single crystal semiconductor layer obtained by fixing a sliced single crystal semiconductor substrate to the substrate 1000.

FIG. 18 is a top view of an example in which strip-shaped bottom cells are provided in stripes. Such bottom cells B₁ . . . Bₙ can be formed by slicing a single crystal semiconductor substrate, which has been processed in advance so as be separated into layers with desired shapes and desired numbers, and fixing the single crystal semiconductor layers onto the substrate 1000. Electrodes are provided between the substrate 1000 and the bottom cells B₁ . . . Bₙ.

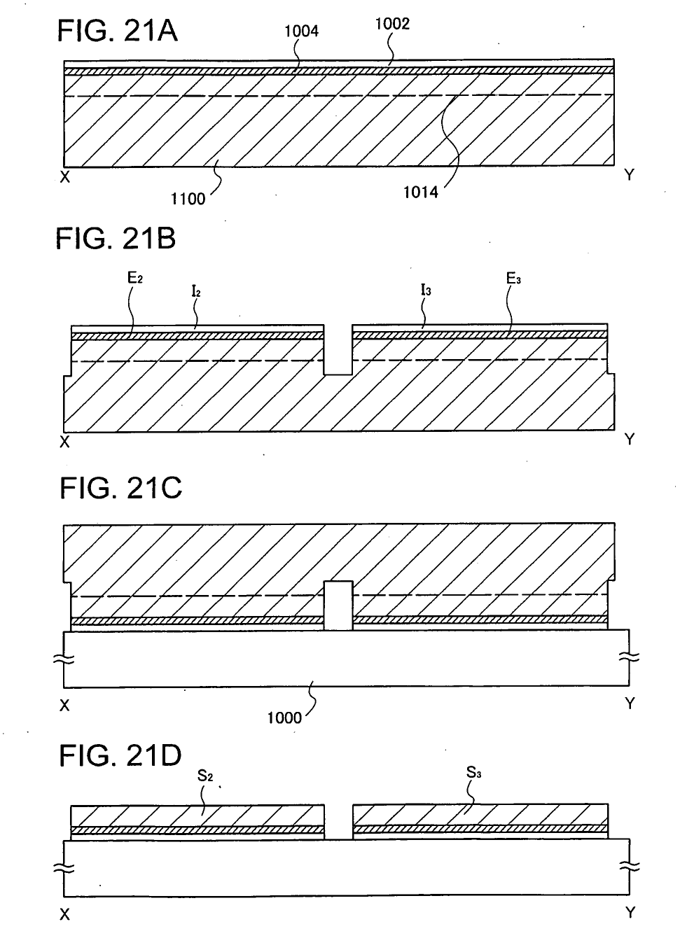

FIGS. 21A to 21D are cross-sectional views showing an example of forming plural bottom cells which are separated for each element. FIGS. 21A to 21D correspond to a cross section taken along dotted line X-Y in FIG. 18. Among the bottom cells B₁ . . . Bₙ provided over the substrate 1000, the adjacent bottom cells B₂ and B₃ are described here.

A stack of a first electrode layer 1004 and an insulating layer 1002 is formed over a single crystal semiconductor substrate 1100 and a fragile layer 1014 is formed at a predetermined depth of the single crystal semiconductor substrate 1100 (see FIG. 21A). The insulating layer 1002 provided over the first electrode layer 1004 has a purpose of facilitating the attachment with the substrate by improving the smoothness of a bonding plane. Although not illustrated, the first impurity semiconductor layer having one conductivity type is formed on the side that is in contact with the first electrode layer 1004 in the single crystal semiconductor substrate 1100.

The single crystal semiconductor substrate 1100 is etched as selected from the side where the first electrode layer 1004 and the insulating layer 1002 are stacked, so that the single crystal semiconductor substrate 1100 is processed into a desired shape (see FIG. 21B). By forming a groove by the etching of the single crystal semiconductor substrate 1100, a projected portion having a desired shape and a desired area is formed. Here, strip-shaped projected portions are formed as shown in FIG. 18. The formation of the groove by etching an object that is to be processed, as selected, is also referred to as “groove processing” below.

The groove processing is performed by etching while a region that is desirably left is covered with a mask as selected. The etching is preferably performed from the insulating layer 1002 side to the depth that is larger than the depth at which the fragile layer 1014 is formed. By the groove processing due to the etching performed deeper than the fragile layer 1014, the projected portion can be thinned so that the single crystal semiconductor layers which are divided can be attached easily to the substrate 1000.

The groove processing may be performed by a photolithography process and an etching method. A resist mask is formed through a photolithography process and the single crystal semiconductor substrate 1100 below the resist mask is dry-etched or wet-etched. By the groove processing, the insulating layer 1002 and the first electrode layer 1004 below the resist mask are etched so that separated insulating layers I₁ to Iₙ (an insulating layer 12 and an insulating layer 13 are illustrated in FIG. 21) and separated first electrodes E₁ to Eₙ (a first electrode E₂ and a first electrode E₃ are illustrated in FIG. 21) are formed.

The single crystal semiconductor substrate 1100 and the substrate 1000 are attached to each other in a manner that the insulating layers 12 and 13 face the substrate 1000 (see FIG. 21C). The groove processing has been performed on the single crystal semiconductor substrate 1100, and the projected portions where the insulating layer and the first electrode are formed are attached to the substrate 1000.

The single crystal semiconductor substrate 1100 is sliced so that the superficial portion thereof provided with the insulating layers I₁ to Iₙ and the first electrodes E₁ to Eₙ is separated from the single crystal semiconductor substrate 1100; thus, single crystal semiconductor layers S₁ to Sₙ are formed over the substrate 1000. Here, the projected portions formed by the groove processing are attached to the substrate 1000. As a result, stacks of the single crystal semiconductor layers S₁ to Sₙ, the first electrodes E₁ to Eₙ, and the insulating layers I₁ to Iₙ, which are divided, are formed over the substrate 1000. In FIG. 21D, the projected portion of the single crystal semiconductor substrate 1100 which is provided with the first electrode E₂ and the insulating layer I₂ and the projected portion of the single crystal semiconductor substrate 1100 which is provided with the first electrode E₃ and the insulating layer I₃ are attached to the substrate 1000 and the single crystal semiconductor substrate 1100 is sliced; thus, the stack of the single crystal semiconductor layer S₂, the first electrode E₂, and the insulating layer I₂ and the stack of the single crystal semiconductor layer S₃, the first electrode E₃, and the insulating layer I₃ are provided over the substrate 1000. If the thickness of the single crystal semiconductor layer is smaller than the desired thickness, the thickness may be increased by an epitaxial growth technique.

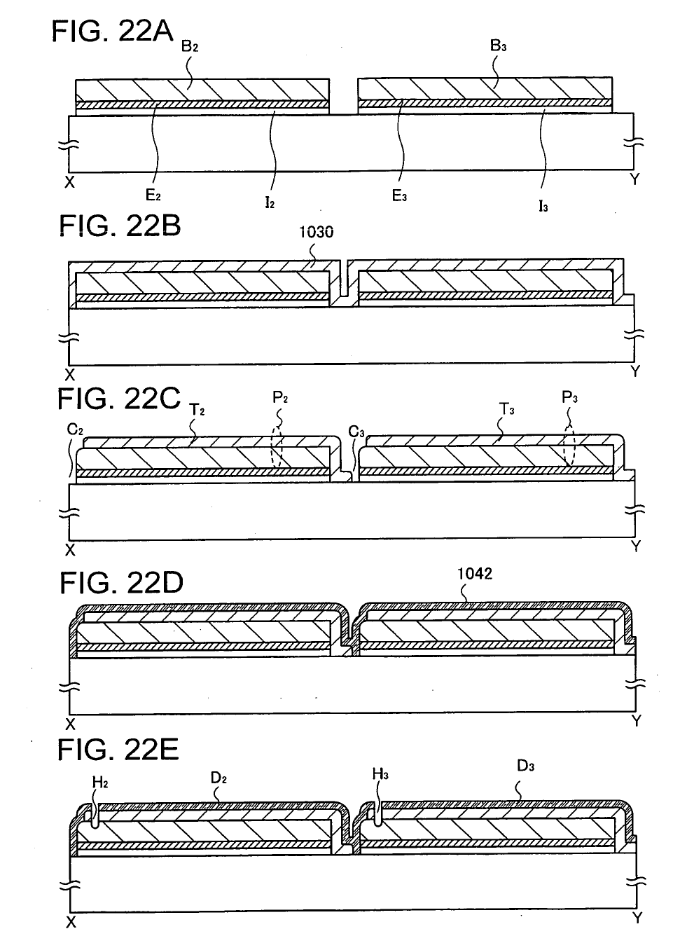

When the second impurity semiconductor layer is formed by introducing the impurity element having a conductivity type opposite to that of the first impurity semiconductor layer to the surface side of the single crystal semiconductor layer formed over the substrate 1000 in the aforementioned manner, the bottom cells B₁ . . . Bₙ which are separated for each element can be formed as illustrated in FIG. 18. In FIG. 22A, the adjacent bottom cells B₂ and B₃ are provided over the substrate 1000.

In FIG. 22A, the bottom cells B₂ and B₃ each correspond to the first unit cell 110 illustrated in FIG. 12, and have a structure in which the second impurity semiconductor layer having the conductivity type opposite to that of the first impurity semiconductor layer is stacked over the first impurity semiconductor layer. The single crystal semiconductor layer is formed by slicing a single crystal semiconductor substrate. The second impurity semiconductor layer formed over the single crystal semiconductor layer can be formed by introducing an impurity element imparting one conductivity type to the surface side of the single crystal semiconductor layer or by a plasma CVD method. The thickness of the single crystal semiconductor layer of the bottom cell is greater than or equal to 1 μm and less than or equal to 10 μm, preferably greater than or equal to 2 μm and less than or equal to 8 μm. In the case where the single crystal semiconductor layer formed by slicing the single crystal semiconductor substrate is thin, the thickness of the single crystal semiconductor layer is preferably increased by an epitaxial growth technique.

The first electrode E₂ is provided in contact with the lower surface of the bottom cell B₂ and the first electrode E₃ is provided in contact with the lower surface of the bottom cell B₃. The insulating layer I₂ is provided between the first electrode E₂ and the substrate 1000 and the insulating layer I₃ is provided between the first electrode E₃ and the substrate 1000.

In FIG. 22B, a semiconductor layer 1030 used for a top cell is formed over the entire surface over the substrate 1000 so as to cover the bottom cells B₁ to Bₙ (the bottom cells B₂ and B₃ are illustrated) by a plasma CVD method. The top cell corresponds to the second unit cell 130 illustrated in FIG. 12 and has a structure in which the third impurity semiconductor layer having one conductivity type, the non-single-crystal semiconductor layer, and the fourth impurity semiconductor layer having a conductivity type opposite to that of the third impurity semiconductor layer are stacked. The stacked structure of the third impurity semiconductor layer, the non-single-crystal semiconductor layer, and the fourth impurity semiconductor layer forms an nip junction (or a pin junction). In the non-single-crystal semiconductor layer, plural crystals are provided discretely in an amorphous structure. The pair of impurity semiconductor layers (the third impurity semiconductor layer and the fourth impurity semiconductor layer) is bonded to the non-single-crystal semiconductor layer in order to form an internal electric field, and the crystals penetrate through the non-single-crystal semiconductor layer. The thickness of the non-single-crystal semiconductor layer of the top cell is greater than or equal to 0.1 μm and less than or equal to 0.5 μm, preferably greater than or equal to 0.2 μm and less than or equal to 0.3 μm.

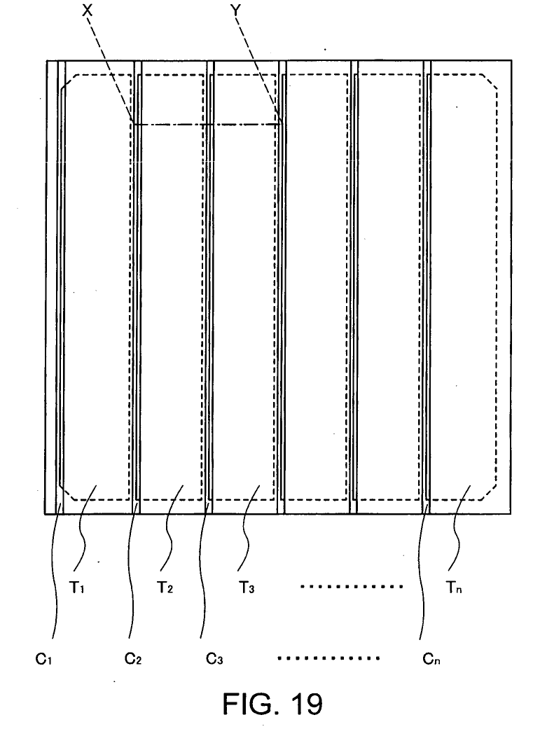

As illustrated in FIG. 19 and FIG. 22C, openings C₁ to Cₙ that penetrate through the semiconductor layer used for the top cell are formed by a laser processing method, whereby a plurality of top cells T₁ . . . Tₙ which are separated for each element is formed. By the laser processing method, the openings C₁ to Cₙ (for example, the opening C₃) that penetrate between the adjacent bottom cells (for example, between the bottom cell B₂ and the bottom cell B₃) are formed, whereby the top cells T₁ . . . Tₙ (for example, the top cell T₂ and the top cell T₃) which are separated for each element are formed. By the formation of the top cells T₁ . . . Tₙ which are separated for each element because of the formation of the openings C₁ to Cₙ so as to penetrate through the adjacent bottom cells, photoelectric conversion cells P₁ to Pₙ which are separated for each element can be formed. Further, the openings C₁ to Cₙ are formed so as to expose an end of each of the bottom cells B₁ to Bₙ which are separated for each element. By the exposure of the end of each of the bottom cells B₁ to Bₙ, the first electrodes E₁ to Eₙ below the bottom cells B₁ to Bₙ are exposed.

Since the semiconductor layer formed for the top cell is as thin as about several hundred of nanometers, the openings can be easily formed by laser processing. Further, since the semiconductor layer for the bottom cell is as thick as several micrometers, the semiconductor layer for the bottom cell is not easily affected by the laser processing. Therefore, the semiconductor layer for the top cell is removed while the end of the bottom cell remains and is exposed.

In FIG. 22D, a transparent electrode layer 1042 is formed over the entire surface over the substrate 1000 so as to cover the top cells T₁ to Tₙ and the openings C₁ to Cₙ. Since the transparent electrode layer 1042 is formed so as to fill the openings C₁ to Cₙ, the transparent electrode layer 1042 is in contact with the ends of the bottom cells B₁ to Bₙ exposed at the openings C₁ to Cₙ. The transparent electrode layer 1042 can be formed using the material which is used for forming the second electrode 142 illustrated in FIG. 12, and can be formed using the transparent conductive material by a sputtering method or a vacuum evaporation method. Alternatively, the transparent electrode layer 1042 may be formed using a conductive high molecular material.

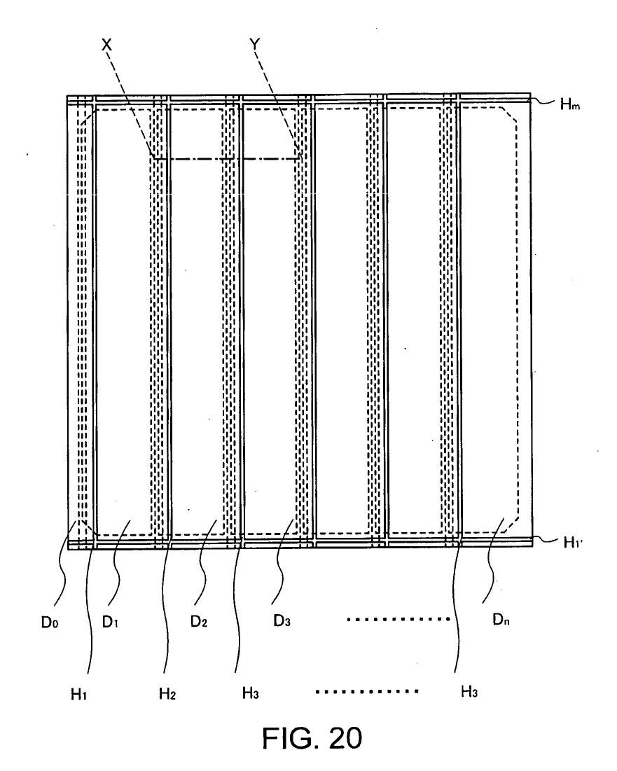

As illustrated in FIG. 20 and FIG. 22E, openings H₁ to Hₙ and openings H_{1′} to Hₘ are formed through the transparent electrode layer 1042 by a laser processing method, thereby forming second electrodes D₁ to Dₙ which are separated for each element. When the openings H₁ to Hₙ are formed displaced from the openings C₁ to Cₙ, the adjacent bottom cells can be electrically connected to each other. In FIG. 22E, the photoelectric conversion cell P₂ and the photoelectric conversion cell P₃ are electrically connected to each other by the second electrode D₂. The second electrode D₂ is formed over the photoelectric conversion cell P₂ and is in contact with the first electrode E₃ below the photoelectric conversion cell P₃ exposed at the opening C₃. The photoelectric conversion cell P₂ and the photoelectric conversion cell P₃ are serially connected to each other. In Embodiment 9, a second electrode D_{q} and a first electrode E₁₊₁ are electrically connected to each other at an opening C_{q+1}.

At the time of forming the openings H₁ to Hₙ, the top cells below the openings H₁ to Hₙ are removed in some cases as illustrated in FIG. 22E. However, such cases are acceptable as long as the transparent electrode layer 1042 is removed as selected and the second electrodes which are separated for each element are formed.

In this manner, the integrated photoelectric conversion device in which the plural photoelectric conversion cells P₁ to Pₙ are serially connected to each other over one substrate can be completed.

The photoelectric conversion device of Embodiment 9 is the integrated photoelectric conversion device in which the plural photoelectric conversion cells are serially connected to each other. As described in Embodiment 9, the integrated photoelectric conversion device where a desired voltage can be obtained can be provided by separating the photoelectric conversion cells and connecting the photoelectric conversion cells serially to each other. The individual photoelectric conversion cell of the photoelectric conversion device of Embodiment 9 has a structure in which the top cell is stacked over the bottom cell. The main part of the bottom cell is formed using a single crystal semiconductor layer while the top cell is formed using a non-single-crystal semiconductor layer including plural crystals in an amorphous structure. Therefore, the integrated photoelectric conversion device with an improved photoelectric conversion characteristic which has a wide absorption wavelength range and which has characteristics that hardly deteriorate due to photodegradation can be provided.

Note that Embodiment 9 can be combined as appropriate with any of other embodiments.

This application is based on Japanese Patent Application serial no. 2008-143277 filed with Japan Patent Office on May 30, 2008 and Japanese Patent Application serial no. 2008-143301 filed with Japan Patent Office on May 30, 2008, the entire contents of which are hereby incorporated by reference.

What is claimed is:

1. A photoelectric conversion device comprising:
a first semiconductor layer including a first impurity element over a substrate;
a second semiconductor layer including an amorphous layer and a crystal over the first semiconductor layer; and
a third semiconductor layer including a second impurity element over the second semiconductor layer,
wherein the crystal penetrates between the first semiconductor layer and the third semiconductor layer.

2. A photoelectric conversion device according to claim 1,
further comprising a first electrode and a second electrode,
wherein the first semiconductor layer, the second semiconductor layer, and the third semiconductor layer are disposed between the first electrode and the second electrode.

3. A photoelectric conversion device according to claim 1,
further comprising a single crystal semiconductor layer disposed between the substrate and the first semiconductor layer.

4. The photoelectric conversion device according to claim 1,
wherein the crystal has a needle-like shape, a conical shape, a cylindrical shape, a polygonal pyramidal shape, or a polygonal prism shape.

5. The photoelectric conversion device according to claim 1,
wherein each of the first semiconductor layer and the third semiconductor layer is a microcrystalline semiconductor layer.

6. The photoelectric conversion device according to claim 1,
wherein one of the first semiconductor layer and the third semiconductor layer is an n-type semiconductor layer, the other of the first semiconductor layer and the third semiconductor layer is a p-type semiconductor layer, and the second semiconductor layer is an i-type semiconductor layer.

7. A photoelectric conversion device comprising:
a first semiconductor layer including a first impurity element over a substrate;
a second semiconductor layer including a first amorphous layer and a first crystal over the first semiconductor layer;
a third semiconductor layer including a second impurity element over the second semiconductor layer;
a fourth semiconductor layer including a third impurity element over the third semiconductor layer;
a fifth semiconductor layer including a second amorphous layer and a second crystal over the fourth semiconductor layer; and
a sixth semiconductor layer including a fourth impurity element over the fifth semiconductor layer,
wherein the first crystal penetrates between the first semiconductor layer and the third semiconductor layer, and
wherein the second crystal penetrates between the fourth semiconductor layer and the sixth semiconductor layer.

8. A photoelectric conversion device according to claim 7,
further comprising a first electrode and a second electrode,
wherein the first semiconductor layer, the second semiconductor layer, the third semiconductor layer, the fourth semiconductor layer, the fifth semiconductor layer and the sixth semiconductor layer are disposed between the first electrode and the second electrode.

9. A photoelectric conversion device according to claim 7,
further comprising a single crystal semiconductor layer disposed between the substrate and the first semiconductor layer.

10. The photoelectric conversion device according to claim 7,
wherein each of the first crystal and the second crystal has a needle-like shape, a conical shape, a cylindrical shape, a polygonal pyramidal shape, or a polygonal prism shape.

11. The photoelectric conversion device according to claim 7,
wherein each of the first semiconductor layer, the third semiconductor layer, the fourth semiconductor layer, and the sixth semiconductor layer is a microcrystalline semiconductor layer.

12. The photoelectric conversion device according to claim 7,
wherein one of the first and third semiconductor layers and one of the fourth and sixth semiconductor layers are n-type semiconductor layers, the other of the first and third semiconductor layers and the other of the fourth and sixth semiconductor layers are p-type semiconductor layers, and the second and fifth semiconductor layers are i-type semiconductor layers.

13. A photoelectric conversion device according to claim 7,
wherein a proportion of a volume of the first crystal to a volume of the second semiconductor layer is smaller than a proportion of a volume of the second crystal to a volume of the fifth semiconductor layer.

14. A photoelectric conversion device according to claim 7,
wherein a thickness of the second semiconductor layer is thinner than a thickness of the fifth semiconductor layer.

15. A method for manufacturing a photoelectric conversion device, comprising:
forming a first semiconductor layer including a first impurity element over a substrate;
forming a second semiconductor layer including an amorphous layer and a crystal over the first semiconductor layer; and
forming a third semiconductor layer including a second impurity element over the second semiconductor layer,
wherein the crystal is formed to penetrate between the first semiconductor layer and the third semiconductor layer.

16. The method for manufacturing a photoelectric conversion device according to claim 15,
wherein the crystal is formed by using plasma generated by introducing a reaction gas including a semiconductor source gas and a dilution gas with a flow rate of the dilution gas to the semiconductor source gas being greater than or equal to 1 time and less than or equal to 6 times into a reaction chamber.

17. The method for manufacturing a photoelectric conversion device according to claim 15,
wherein the crystal is formed by using plasma generated by introducing a reaction gas including a semiconductor source gas and a dilution gas with a flow rate of the dilution gas to the semiconductor source gas being greater than or equal to 1 time and less than or equal to 6 times into a reaction chamber,
wherein the semiconductor source gas is silicon hydride, silicon fluoride, or silicon chloride, and
wherein the dilution gas is hydrogen.

18. The method for manufacturing a photoelectric conversion device according to claim 15, further comprising:
forming a fragile layer in a single crystal semiconductor substrate;
forming a first impurity semiconductor layer in the single crystal semiconductor substrate;
forming a first electrode over the single crystal semiconductor substrate;
forming an insulating layer over the first electrode;
bonding the single crystal semiconductor substrate and a second substrate with the insulating layer and the first electrode therebetween,
separating the single crystal semiconductor substrate with a single crystal semiconductor layer left over the second substrate, and
forming a second impurity semiconductor layer over the single crystal semiconductor layer.

19. The method for manufacturing a photoelectric conversion device according to claim 15, further comprising:
forming a fragile layer in a single crystal semiconductor substrate;
forming a first impurity semiconductor layer in the single crystal semiconductor substrate;
forming a first electrode over the single crystal semiconductor substrate;
forming an insulating layer over the first electrode;
bonding the single crystal semiconductor substrate and a second substrate with the insulating layer and the first electrode therebetween,
separating the single crystal semiconductor substrate with a single crystal semiconductor layer left over the second substrate, and
forming a second impurity semiconductor layer over the single crystal semiconductor layer,
wherein each of a surface of the second substrate and a surface of the insulating layer has an average surface roughness of 0.5 nm or less.
